(19) United States
(12) Patent Application Publication
(10) Pub. No.: US 2022/0382151 A1
(43) Pub. Date: Dec. 1, 2022

(54) METHOD FOR PRODUCING RESIN, METHOD FOR PRODUCING ACTINIC RAY-SENSITIVE OR RADIATION-SENSITIVE RESIN COMPOSITION, PATTERN FORMING METHOD, AND RESIN

(71) Applicant: FUJIFILM Corporation, Tokyo (JP)

(72) Inventors: Tomoaki YOSHIOKA, Haibara-gun (JP); Shuhei Yamaguchi, Haibara-gun (JP); Eiji Fukuzaki, Haibara-gun (JP); Taro Miyoshi, Haibara-gun (JP)

(73) Assignee: FUJIFILM Corporation, Tokyo (JP)

(21) Appl. No.: 17/724,873

(22) Filed: Apr. 20, 2022

(30) Foreign Application Priority Data
May 6, 2021 (JP) 2021-078811

(51) Int. Cl. G03F 7/039; G03F 7/038; C08F 212/14; C08F 8/34

(52) U.S. Cl. CPC G03F 7/039; G03F 7/038; C08F 212/30; C08F 8/34

(57) ABSTRACT

A method for producing a resin having a repeating unit that is decomposed by irradiation of an actinic ray or a radiation to generate acid, the method including polymerizing a specific compound represented by General formula (P-1) and a copolymerizable monomer compound, a method for producing an actinic ray-sensitive or radiation-sensitive resin composition, a pattern forming method, and a resin corresponding to a reaction intermediate of the resin.

### CROSS-REFERENCE TO RELATED APPLICATIONS

The present application is based on and claims priority under 35 U.S.C. § 119 from Japanese Patent Application No. 2021-078811 filed on May 6, 2021, the contents of which are incorporated herein by reference.

### BACKGROUND OF THE INVENTION

### 1. Field of the Invention

The present invention relates to a method for producing a resin usable for an actinic ray-sensitive or radiation-sensitive resin composition, a method for producing an actinic ray-sensitive or radiation-sensitive resin composition, a pattern forming method, and a resin.

### 2. Description of the Related Art

During fabrication processes of semiconductor devices such as ICs (Integrated Circuits) and LSIs (LargeScale Integrated circuits), microprocessing by lithography using photosensitive compositions is performed.

Lithography is performed by a method such as a method of using a photosensitive composition to form a resist film, subsequently exposing the obtained film, and subsequently developing the film. In particular, in recent years, use of, during exposure, in addition to the ArF excimer laser, EB (Electron Beam) and EUV (Extreme ultraviolet) light has been studied, and actinic ray-sensitive or radiation-sensitive resin compositions suitable for EUV exposure have been developed.

As resins used for such compositions, there are known resins having a repeating unit that is decomposed by irradiation with an actinic ray or a radiation to generate acid.

For example, JP2013-1715A discloses a method for producing a polymer compound having a constitutional unit that is decomposed by exposure to generate acid, the method being characterized by polymerizing a water-soluble monomer having an anion group to synthesize a precursor polymer, rinsing the precursor polymer with water, and subsequently subjecting the precursor polymer to salt exchange for an organic cation.

JP2011-168698A discloses a method for producing an actinic ray-sensitive or radiation-sensitive resin, the method including polymerizing, in the presence of a basic compound, a reaction system including a first monomer including a structural moiety that is decomposed by irradiation with an actinic ray or a radiation to generate acid, and a second monomer including a group that is decomposed due to the action of acid to generate an alkali soluble group.

### SUMMARY OF TH E INVENTION

There has been a demand for various performances for actinic ray-sensitive or radiation-sensitive films formed from actinic ray-sensitive or radiation-sensitive resin compositions; for such performances in demand, it is important that high roughness performance and high etching resistance performance are both provided.

There has also been a demand for a production method that enables easier production of an actinic ray-sensitive or radiation-sensitive resin composition satisfying the demand.

Thus, objects of the present invention are to provide a production method that enables easy and highly precise production of a resin useful for producing an actinic ray-sensitive or radiation-sensitive resin composition that enables formation of a pattern having high roughness performance and high etching resistance performance, a method for producing an actinic ray-sensitive or radiation-sensitive resin composition, a pattern forming method, and a resin corresponding to a reaction intermediate of the resin.

The inventors of the present invention have found that the following features address the above-described objects.

[1]

A method for producing a resin having a repeating unit that is decomposed by irradiation with an actinic ray or a radiation to generate acid, the method including polymerizing a compound represented by General formula (P-1) below and a copolymerizable monomer compound.

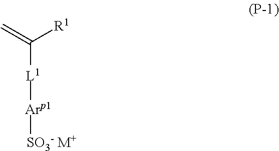

In General formula (P-1),

R¹ represents a hydrogen atom, an alkyl group, an aryl group, or a halogen atom,

L¹ represents a single bond or a divalent linking group,

Ar^{p1} represents an aromatic ring group or an aromatic heterocyclic group, and

M⁺ represents a lithium cation, a potassium cation, or an ammonium cation.

[2]

The method for producing the resin according to [1], wherein at least one of the copolymerizable monomer compound is a compound represented by General formula (A-1) below.

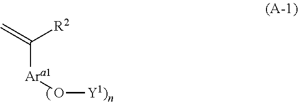

In General formula (A-1),

R² represents a hydrogen atom, an alkyl group, an aryl group, or a halogen atom,

Ar^{a1} represents an (n+1) valent aromatic ring group or an (n+1) valent aromatic heterocyclic group,

n represents an integer of 1 to 4,

Y¹ represents a hydrogen atom or a substituent, and, when n represents an integer of 2 to 4, a plurality of Y¹'s may be the same or different.

[3]

The method for producing the resin according to [1] or [2], wherein the compound represented by General formula (P-1) above is a compound represented by General formula (P-2) below.

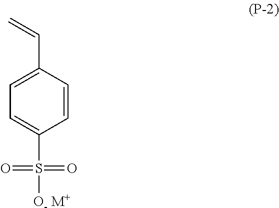

In General formula (P-2),

M⁺ has the same definition as M⁺ in General formula (P-1) above.

[4]

The method for producing the resin according to any one of [1] to [3], wherein,

a solvent is used in the polymerization, and

a content of an alcohol-based solvent is 20 mass % or more with respect to a total amount of the solvent.

[5]

The method for producing the resin according to [4], wherein, the content of the alcohol-based solvent is 50 mass % or more with respect to the total amount of the solvent.

[6]

The method for producing the resin according to [4] or [5], wherein the alcohol-based solvent is at least one selected from the group consisting of methanol, ethanol, 1-propanol, 2-propanol, ethylene glycol, propylene glycol, 2-methoxyethanol, 1-methoxy-2-propanol, methyl lactate, ethyl lactate, and diacetone alcohol.

[7]

The method for producing the resin according to any one of [1] to [6], wherein, a solution containing the compound represented by General formula (P-1) above is passed through a filter having a pore size of 0.05 to 5 μm before the polymerization.

[8]

The method for producing the resin according to any one of [1] to [7], the method including, after the polymerization, exchanging the cation M⁺ in a repeating unit derived from the compound represented by General formula (P-1) above for an organic cation.

[9]

The method for producing the resin according to any one of [1] to [8], wherein the resin further has a repeating unit having an acid decomposable group.

[10]

The method for producing the resin according to any one of [2] to [9], wherein Y¹ in General formula (A-1) above is a hydrogen atom or a group represented by any one of Formulas (AY-1) to (AY-3) below.

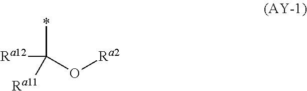

In Formula (AY-1), R^{a11} and R^{a2} each independently represent a hydrogen atom, an alkyl group, an aryl group, or a heteroaryl group, R^{a2} represents an alkyl group, an aryl group, or a heteroaryl group, and

* represents a bonding site.

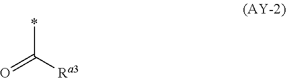

In Formula (AY-2), R^{a3} represents an alkyl group, an alkoxy group, an aryl group, an aryloxy group, or a heteroaryl group, and

* represents a bonding site.

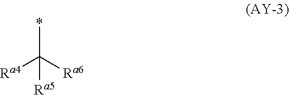

In Formula (AY-3), R^{a1} to R^{a6} each independently represent an alkyl group, an aryl group, or a heteroaryl group, and

* represents a bonding site.

[11]

The method for producing the resin according to any one of [2] to [10], wherein the compound represented by General formula (A-1) above is a compound represented by any one of Formulas (A-2) to (A-5) below.

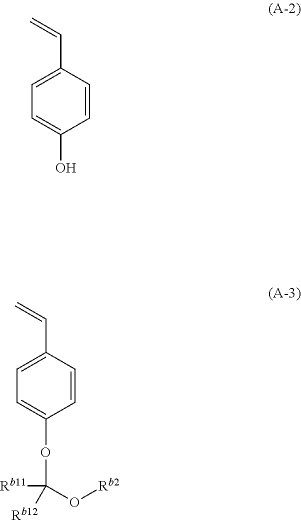

In Formula (A-3), R^{b11} and R^{b12} each independently represent a hydrogen atom, an alkyl group, an aryl group, or a heteroaryl group, R^{b2} represents an alkyl group, an aryl group, or a heteroaryl group.

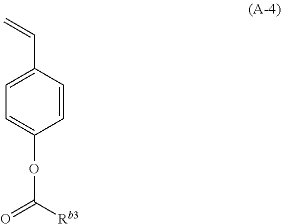

In Formula (A-4), R^{b3} represents an alkyl group, an alkoxy group, an aryl group, an aryloxy group, or a heteroaryl group

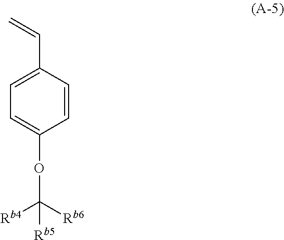

In Formula (A-5), R^{b4} to R^{b6} each independently represent an alkyl group, an aryl group, or a heteroaryl group.

[12]

The method for producing the resin according to [11], wherein the compound represented by General formula (A-1) above is a compound represented by any one of Formulas (A-3) to (A-5) above, and the method includes, after the polymerization, converting a repeating unit derived from the compound represented by General formula (A-1) above to a repeating unit represented by Formula (AP-1) below.

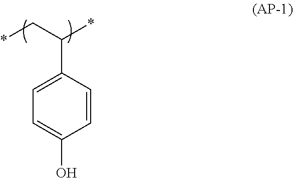

[13]

The method for producing the resin according to [12], the method including converting at least partially the repeating unit represented by Formula (AP-1) above to a repeating unit represented by Formula (AP-2) below.

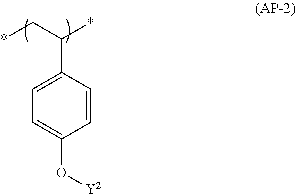

In Formula (AP-2), Y² represents a group that leaves due to an action of acid.

[14]

The method for producing the resin according to [11], wherein the compound represented by General formula (A-1) above is the compound represented by Formula (A-2) above, and the method includes, after the polymerization, converting at least partially a repeating unit derived from the compound represented by formula (A-2) above to a repeating unit represented by Formula (AP-2) below.

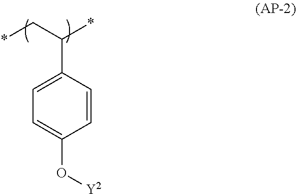

In Formula (AP-2), Y² represents a group that leaves due to an action of acid.

[15]

The method for producing the resin according to [13] or [14], wherein, in Formula (AP-2) above, Y² is a group represented by Formula (AY-4) below.

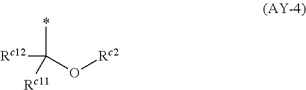

In Formula (AY-4), R^{c11} and R¹² each independently represent a hydrogen atom, an alkyl group, an aryl group, or a heteroaryl group, R^{c2} represents an alkyl group, an aryl group, or a heteroaryl group, and

* represents a bonding site.

[16]A method for producing an actinic ray-sensitive or radiation-sensitive resin composition, the method including the method for producing the resin according to any one of
[1] to [15], and the composition containing the resin.
[17]

A pattern forming method including:

producing a resin by the method for producing the resin according to any one of [1] to

[15];

forming an actinic ray-sensitive or radiation-sensitive film on a substrate by an actinic ray-sensitive or radiation-sensitive resin composition containing the resin;

exposing the actinic ray-sensitive or radiation-sensitive film; and

developing the exposed actinic ray-sensitive or radiation-sensitive film to form a pattern by a developer.

[18]

A resin including a repeating unit derived from a compound represented by General formula (P-1) below, and a repeating unit derived from a compound represented by any one of Formulas (A-2) to (A-5) below.

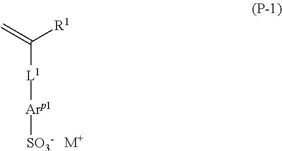

In General formula (P-1),

R¹ represents a hydrogen atom, an alkyl group, an aryl group, or a halogen atom,

L¹ represents a single bond or a divalent linking group,

Ar^{p1} represents an aromatic ring group or an aromatic heterocyclic group, and

M⁺ represents a lithium cation, a potassium cation, or an ammonium cation.

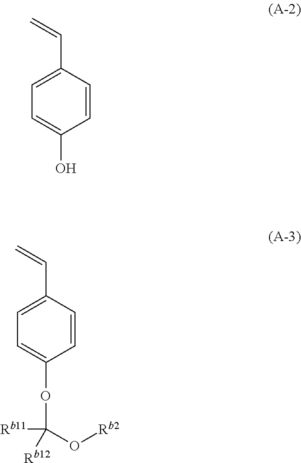

In Formula (A-3), R^{b11} and R^{b12} each independently represent a hydrogen atom, an alkyl group, an aryl group, or a heteroaryl group, and R^{b2} represents an alkyl group, an aryl group, or a heteroaryl group.

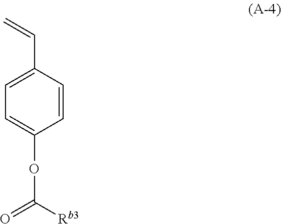

In Formula (A-4), R^{b3} represents an alkyl group, an alkoxy group, an aryl group, an aryloxy group, or a heteroaryl group.

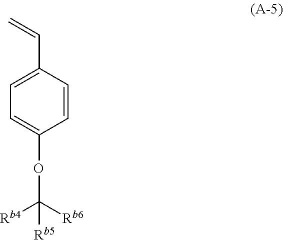

In Formula (A-5), R^{b4} to R^{b6} each independently represent an alkyl group, an aryl group, or a heteroaryl group.

The present invention can provide a production method that enables easy and highly precise production of a resin useful for producing an actinic ray-sensitive or radiation-sensitive resin composition that enables formation of a pattern having high roughness performance and high etching resistance performance, a method for producing an actinic ray-sensitive or radiation-sensitive resin composition, a pattern forming method, and a resin corresponding to a reaction intermediate of the resin.

### DESCRIPTION OF THE PREFERRED EMBODIMENTS

Hereinafter, the present invention will be described in detail.

Features may be described below with reference to representative embodiments according to the present invention; however, the present invention is not limited to the embodiments.

In this Specification, for groups (atomic groups), written forms without substituted or unsubstituted encompass, in addition to groups not having a substituent, groups including a substituent without departing from the spirit and scope of the present invention. For example, “alkyl group” encompasses not only alkyl groups not having a substituent (unsubstituted alkyl groups), but also alkyl groups having a substituent (substituted alkyl groups). In this Specification, “organic group” refers to a group including at least one carbon atom.

The substituent is preferably a monovalent substituent unless otherwise specified.

In this Specification, “actinic ray” or “radiation” means, for example, the emission line spectrum of a mercury lamp, far-ultraviolet rays represented by excimer lasers, extreme ultraviolet rays (EUV light: Extreme Ultraviolet), X-rays, or an electron beam (EB: Electron Beam).

In this Specification, “light” means an actinic ray or a radiation.

In this Specification, “exposure” includes, unless otherwise specified, not only exposure using, for example, the emission line spectrum of a mercury lamp, far-ultraviolet rays represented by excimer lasers, extreme ultraviolet rays, X-rays, or EUV light, but also patterning using a corpuscular beam such as an electron beam or an ion beam.

In this Specification, “a value ‘to’ another value” is used to mean a range including the value and the other value respectively as the lower limit value and the upper limit value.

In this Specification, the bonding directions of divalent groups are not limited to the written forms unless otherwise specified. For example, in a compound represented by a formula “X—Y—Z” where Y is —COO—, Y may be —CO—O— or —O—CO—. In other words, the compound may be “X—CO—O—Z” or “X—O—CO—Z”.

In this Specification, (meth)acrylate represents acrylate and methacrylate, and (meth)acrylic represents acrylic and methacrylic.

In this Specification, weight-average molecular weight (Mw), number-average molecular weight (Mn), and dispersity (hereafter, also referred to as “molecular weight distribution”) (Mw/Mn) are defined as polystyrene equivalent values determined using a GPC (Gel Permeation Chromatography) apparatus (HLC-8120 GPC manufactured by Tosob Corporation) by GPC measurement (solvent: dimethylformamide, amount of flow (sample injection amount): 10 μL, column: TISK gel Multipore HXL-M manufactured by Tosob Corporation, column temperature: 40° C., flow rate: 1.0 mL/min, detector: differential refractive index detector (Refractive Index Detector)).

In this Specification, the acid dissociation constant (pKa) represents pKa in an aqueous solution, specifically, a value determined using the following Software package 1, on the basis of the Hammett's substituent constant and the database of values in publicly known documents, by calculation.

Software package 1: Advanced Chemistry Development (ACD/Labs) Software V8.14 for Solaris (1994-2007 ACD/Labs)

Alternatively, pKa can be determined by the molecular orbital method. Specifically, this method may be a method of, on the basis of a thermodynamic cycle, calculating H-dissociation free energy in an aqueous solution to achieve the determination. As the calculation method for H⁺ dissociation free energy, for example, DFT (density function method) can be performed for calculation; however, other various methods have been reported in documents etc. and the calculation method is not limited to DFT. Note that there are a plurality of pieces of software for performing DFT; for example, Gaussian 16 may be used.

In this Specification, as described above, pKa refers to a value determined using Software package 1, on the basis of the Hammett's substituent constant and the database of values in publicly known documents, by calculation; however, when use of this method cannot determine pKa, a value determined on the basis of DFT (density function method) using Gaussian 16 is employed.

In this Specification, as described above, pKa refers to “pKa in an aqueous solution”; however, when pKa in an aqueous solution cannot be determined, “pKa in a dimethyl sulfoxide (DMSO) solution” is employed.

“Solid content” means components forming the actinic ray-sensitive or radiation-sensitive film and does not include solvents. As long as a component forms the actinic ray-sensitive or radiation-sensitive film, even when the component has the form of liquid, it is regarded as the solid content.

In this Specification, in the case of using a phrase “may have a substituent”, the type of the substituent, the position of the substituent, and the number of such substituents are not particularly limited. The number of the substituents may be, for example, one, two, three, or more. Examples of the substituents include monovalent non-metallic atomic groups except for the hydrogen atom and, for example, can be selected from the following Substituent T.

### Substituent T

Examples of Substituent T include halogen atoms such as a fluorine atom, a chlorine atom, a bromine atom, and an iodine atom; alkoxy groups such as a methoxy group, an ethoxy group, and a tert-butoxy group; aryloxy groups such as a phenoxy group and a p-tolyloxy group; alkoxycarbonyl groups such as a methoxycarbonyl group, a butoxycarbonyl group, and a phenoxycarbonyl group; acyloxy groups such as an acetoxy group, a propionyloxy group, and a benzoyloxy group; acyl groups such as an acetyl group, a benzoyl group, an isobutyryl group, an acryloyl group, a methacryloyl group, and a methoxalyl group; alkylsulfanyl groups such as a methylsulfanyl group and a tert-butylsulfanyl group; arylsulfanyl groups such as a phenylsulfanyl group and a p-tolylsulfanyl group; alkyl groups; alkenyl groups; cycloalkyl groups; aryl groups; heteroaryl groups; a hydroxy group; a carboxy group; a formyl group; a sulfo group; a cyano group; alkylaminocarbonyl groups; arylaminocarbonyl groups; a sulfonamide group; a silyl group; an amino group; monoalkylamino groups; dialkylamino groups; arylamino groups; and combinations of the foregoing.

### Method for Producing Resin

A method for producing a resin according to the present invention is a method for producing a resin having a repeating unit that is decomposed by irradiation with an actinic ray or a radiation to generate acid, the method including a step of polymerizing a compound represented by General formula (P-1) below and a copolymerizable monomer compound.

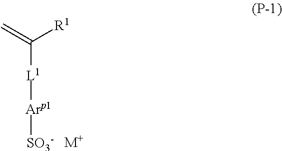

In General formula (P1),

R¹ represents a hydrogen atom, an alkyl group, an aryl group, or a halogen atom;

L¹ represents a single bond or a divalent linking group;

Ar^{p1} represents an aromatic ring group or an aromatic heterocyclic group; and

M⁺ represents a lithium cation, a potassium cation, or an ammonium cation.

The groups in General formula (P-1) will be individually described later.

The mechanism by which such features enable easy and highly precise production of a resin useful for producing an actinic ray-sensitive or radiation-sensitive resin composition that enables formation of a pattern having high roughness performance and high etching resistance performance is not necessarily clear; however, the mechanism is inferred by the inventors of the present invention as follows.

First, the method for producing a resin according to the present invention is a method for producing a resin having a repeating unit that is decomposed by irradiation with an actinic ray or a radiation to generate acid. Thus, the produced resin has a feature in which the acid generation moiety is incorporated into the resin, so that, for the acid generated in the exposed regions of the actinic ray-sensitive or radiation-sensitive film, excessive spreading to unexposed regions is suppressed, which inferentially results in formation of a pattern having high roughness performance.

In addition, the method for producing a resin according to the present invention includes a step of polymerizing the compound represented by General formula (P-1) above and a copolymerizable monomer compound. The compound represented by General formula (P-1) has an aromatic ring group or an aromatic heterocyclic group; these groups are rigid groups. The resin used for the actinic ray-sensitive or radiation-sensitive resin composition similarly has, as a rigid group, the aromatic ring group or the aromatic heterocyclic group, which inferentially results in formation of a pattern having high etching resistance performance. In addition for the compound represented by General formula (P-1) and serving as an ionic monomer compound, M⁺ serving as a counter cation represents a lithium cation, a potassium cation, or an ammonium cation, so that the ionic monomer compound in a monomer solution has an increased solubility, compared with a case where the counter cation is, for example, a sodium cation. The specific reason for this is not clear; however, in the case of the sodium cation, the compound is inferentially less likely to undergo solvation due to the organic solvent, and has a lower degree of solubility.

In such a case where the ionic monomer compound in the monomer solution has an increased solubility, for example, the amount of polymerization solvent used in the monomer solution can be reduced, so that the production costs can be reduced; in addition, for example, for such a monomer that has, as a counter cation, a sodium cation and is impractical for copolymerization from the viewpoint of solubility in the polymerization solvent, the counter cation is changed to a lithium cation, a potassium cation, or an ammonium cation, so that the monomer can be appropriately used for copolymerization, and the range of application of production can be broadened.

For the above-described reasons etc., in the copolymerization step, use of the compound represented by General formula (P-1) inferentially enables easy production of the resin.

Furthermore, in a method for producing a resin having a repeating unit that is decomposed by irradiation with an actinic ray or a radiation to generate acid according to the present invention, M⁺ serving as a counter cation represents a lithium cation, a potassium cation, or an ammonium cation, so that the method includes a step of polymerizing a compound that is represented by General formula (P-1) and that is less likely to be decomposed by irradiation with an actinic ray or a radiation to generate acid. Thus, in the polymerization step, unintended reactions such as decomposition of the resin by acid can be greatly suppressed, which inferentially results in highly precise production of the resin having a repeating unit that is decomposed by irradiation with an actinic ray or a radiation to generate acid.

Hereinafter, in the method for producing a resin, the step of polymerizing the compound represented by General formula (P-1) and a copolymerizable monomer compound (also referred to as Step (1)) will be described.

### Step (1) (Polymerization Step)

Step (1) in the present invention refers to a step of polymerizing the compound represented by General formula (P-1) and a copolymerizable monomer compound.

### Polymerization Initiator

For the reaction in Step (1) above, ordinarily, a polymerization initiator is further included. As the polymerization initiator, for example, a radical initiator such as an azo-based initiator or a peroxide is used to initiate polymerization. The radical initiator is preferably an azo-based initiator, preferably an azo-based initiator having an ester group, a cyano group, or a carboxyl group. Preferred examples of the initiator include 2,2-azobisisobutyronitrile, 2,2′ azobis(2,4-dimethylvaleronitrile), and dimethyl 2,2-azobis(2-methylpropionate). Note that, as appropriate, the initiator may be divided and added a plurality of times.

### Solvent

The reaction in Step (1) above is typically caused in a liquid phase. Specifically, the reaction system typically further includes a solvent,

The solvent is not particularly limited as long as it dissolves components; examples include alcohol-based solvents, alkylene glycol monoalkyl ether carboxylates, alkylene glycol monoalkyl ethers, cyclic lactones, chain or cyclic ketones, alkylene carbonates, alkyl carboxylates, alkyl alkoxyacetates, and alkyl pyruvates. Examples of other usable solvents include solvents described in [0244] and subsequent paragraphs of US2008/0248425A1.

The alcohol-based solvents are not particularly limited as long as they are solvents including —OH; examples include methanol, ethanol, I-propanol, 2-propanol, 1-butanol, ethylene glycol, propylene glycol, 2-methoxyethanol, 1-methoxy-2-propanol, methyl lactate, ethyl lactate, propyl lactate, butyl lactate, and diacetone alcohol.

Preferred examples of the alkylene glycol monoalkyl ether carboxylates include propylene glycol mononethyl ether acetate (PGMEA), propylene glycol monoethyl ether acetate, propylene glycol monopropyl ether acetate, propylene glycol monobutyl ether acetate, propylene glycol monomethyl ether propionate, propylene glycol monoethyl ether Propionate, ethylene glycol monomethyl ether acetate, and ethylene glycol monoethyl ether acetate.

Preferred examples of the alkylene glycol monoalkyl ethers include propylene glycol monomethyl ether (1-methoxy-2-propanol), propylene glycol monoethyl ether, propylene glycol monopropyl ether, propylene glycol monobutyl ether, ethylene glycol monomethyl ether, and ethylene glycol monoethyl ether.

Note that the alkylene glycol monoalkyl ethers are encompassed by alcohol-based solvents.

Preferred examples of alkyl alkoxypropionates include ethyl 3-ethoxypropionate, methyl 3-methoxypropionate, methyl 3-ethoxypropionate, and ethyl 3-methoxypropionate.

Preferred examples of the cyclic lactones include β-propiolactone, γ-butyrolactone, γ-butyrolactone, α-methyl-γ-butyrolactone, β-methyl-γ-butyrolactone, γ-valerolactone, γ-caprolactone, γ-octanoiclactone, and c-hydroxy-y-butyrolactone.

Preferred examples of the chain or cyclic ketones include 2-butanone (methyl ethyl ketone), 3-methylbutanone, pinacolone, 2-pentanone, 3-pentanone, 3-methyl-2-pentanone, 4-methyl-2-pentanone, 2-methyl-3-pentanone, 4,4-dimethyl-2-pentanone, 2,4-dimethyl-3-pentanone, 2,2,4,4-tetramethyl-3-pentanone, 2-hexanone, 3-hexanone, 5-methyl-3-hexanone, 2-heptanone, 3-heptanone, 4-heptanone, 2-methyl-3-heptanone, 5-methyl-3-heptanone, 2,6-dimethyl-4-heptanone, 2-octanone, 3-octanone, 2-nonanone, 3-nonanone, 5-nonanone, 2-decanone, 3-decanone, 4-decanone, 5-hexen-2-one, 3-penten-2-one, cyclopentanone, 2-methylcyclopentanone, 3-methylcyclopentanone, 2,2-dimethylcyclopentanone, 2,4,4-trimethylcyclopentanone, cyclohexanone, 3-methylcyclohexanone, 4-methylcyclohexanone, 4-ethylcyclohexanone, 2,2-dimethylcyclohexanone, 2,6-dimethylcyclohexanone, 2,2,6-trimethylcyclohexanone, cycloheptanone, 2-methylcycloheptanone, and 3-methylcycloheptanone.

Preferred examples of the alkylene carbonates include propylene carbonate, vinylene carbonate, ethylene carbonate, and butylene carbonate.

Preferred examples of the alkyl carboxylates include butyl acetate.

Preferred examples of the alkyl alkoxyacetates include 2-methoxyethyl acetate, 2-ethoxyethyl acetate, 2-(2-ethoxyethoxy)ethyl acetate, 3-methoxy-3-methylbutyl acetate, and 1-methoxy-2-propyl acetate.

Preferred examples of the alkyl pyruvates include methyl pyruvate, ethyl pyruvate, and propyl pyruvate.

These solvents may be used alone or in combination of two or more thereof

The above-described polymerization reaction is preferably caused in an inert gas atmosphere such as nitrogen or argon. As needed, the polymerization may be performed in the presence of a chain transfer agent (for example, alkylmercaptan).

In the reaction system, the monomer concentration is preferably 20 to 70 mass %, more preferably 25 to 50 mass %.

The reaction temperature is ordinarily 10° C. to 150° C., preferably 30° C. to 120° C., still more preferably 40° C. to 00° C.

The reaction time is ordinarily 1 to 48 hours, preferably 1 to 24 hours, still more preferably 1 to 12 hours.

In a preferred embodiment, the polymerization step is preferably performed using a solvent and, with respect to the total amount of the solvent, the content of an alcohol-based solvent is preferably 20 mass % or more.

With respect to the total amount of the solvent, the content of an alcohol-based solvent is preferably 50 mass % or more, more preferably 60 mass % or more, still more preferably 70 mass % or more.

The alcohol-based solvent is preferably at least one selected from the group consisting of methanol, ethanol, 1-propanol, 2-propanol, ethylene glycol, propylene glycol, 2-methoxyethanol, 1-methoxy-2-propanol, methyl lactate, ethyl lactate, and diacetone alcohol.

### Compound Represented by General Formula (P-1)

Hereinafter, the compound represented by General formula (P-1) will be described.

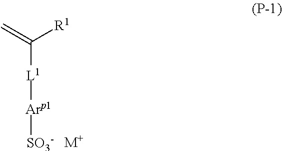

In General formula (P-1),

R¹ represents a hydrogen atom, an alkyl group, an aryl group, or a halogen atom;

L¹ represents a single bond or a divalent linking group;

Ar^{p1} represents an aromatic ring group or an aromatic heterocyclic group; and

M⁺ represents a lithium cation, a potassium cation, or an ammonium cation.

In R¹, the alkyl group is not particularly limited, but may be a linear or branched alkyl group having 1 to 12 carbon atoms, and is preferably an alkyl group having 1 to 6 carbon atoms, more preferably an alkyl group having 1 to 3 carbon atoms.

The aryl group is not particularly limited, but is preferably an aryl group having 6 to 14 carbon atoms; examples include a phenyl group, a naphthyl group, and an anthryl group.

The halogen atom may be, for example, a fluorine atom, a chlorine atom, a bromine atom, or an iodine atom, and is preferably a fluorine atom or an iodine atom,

The alkyl group and the aryl group may have a substituent. The substituent is not particularly limited, but may be, for example, the above-described Substituent T.

R¹ is preferably a hydrogen atom.

In L¹, the divalent linking group is not particularly limited; examples include alkylene groups, cycloalkylene groups, aromatic ring groups, aromatic heterocyclic groups, —C(═O)—, —O—, and divalent linking groups provided by combining a plurality of the foregoing.

Such an alkylene group is not particularly limited, may be linear or branched, and is preferably an alkylene group having 1 to 20 carbon atoms, more preferably an alkylene group having 1 to 10 carbon atoms, still more preferably an alkylene group having 1 to 3 carbon atoms.

Such a cycloalkylene group is not particularly limited, and is preferably a cycloalkylene group having 3 to 20 carbon atoms, more preferably an cycloalkylene group having 3 to 10 carbon atoms, still more preferably a cycloalkylene group having 1 to 6 carbon atoms.

Such an aromatic ring group is not particularly limited, may be monocyclic or polycyclic, and is preferably an aromatic ring group having 6 to 20 carbon atoms, more preferably an aromatic ring group having 6 to 14 carbon atoms, still more preferably an aromatic ring group having 6 to 10 carbon atoms.

Such an aromatic heterocyclic group is not particularly limited, and may be monocyclic or polycyclic. The aromatic heterocycle forming the aromatic heterocyclic group is not particularly limited; examples include thiophene, furan, pyrrole, benzothiophene, benzofuran, benzopyrrole, triazine, imidazole, benzoimidazole, triazole, thiadiazole, and thiazole.

The alkylene groups, the cycloalkylene groups, the aromatic ring groups, and the aromatic heterocyclic groups may have a substituent. The substituent is not particularly limited, but may be, for example, the above-described Substituent T.

As a preferred example, L¹ is preferably a single bond.

In Ar^{p1}, the aromatic ring group is not particularly limited, but may be monocyclic or polycyclic, and is preferably an aromatic ring group having 6 to 20 carbon atoms, more preferably an aromatic ring group having 6 to 14 carbon atoms, still more preferably an aromatic ring group having 6 to 10 carbon atoms.

The aromatic heterocyclic group is not particularly limited, and may be monocyclic or polycyclic. The aromatic heterocycle forming the aromatic heterocyclic group is not particularly limited; examples include thiophene, furan, pyrrole, benzothiophene, benzofuran, benzopyrrole, triazine, imidazole, benzoimidazole, triazole, thiadiazole, and thiazole.
The aromatic ring group and the aromatic heterocyclic group may have a substituent. The substituent is not particularly limited, but may be, for example, the above-described Substituent T.

M⁺ represents a lithium cation, a potassium cation, or an ammonium cation,

The ammonium cation may be, for example, an ammonium cation (NH₄⁺) or a tetraalkylammonium cation, but is preferably an ammonium cation (NH₄⁺).

In the tetraalkylammonium cation, such an alkyl group is preferably an alkyl group having 1 to 6 carbon atoms; the plurality of alkyl groups may be the same or different.

M⁺ is preferably a lithium cation or an ammonium cation (NH₄⁺), more preferably a lithium cation.

The compound represented by General formula (P-1) above is preferably a compound represented by General formula (P-2) below.

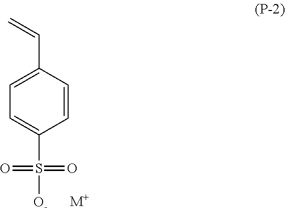

In General formula (P-2),

M⁺ has the same definition and preferred examples as M⁺ In General formula (P-1) above.

Hereinafter, specific examples of the compound represented by General formula (P-1) will be described; however, the present invention is not limited to these.

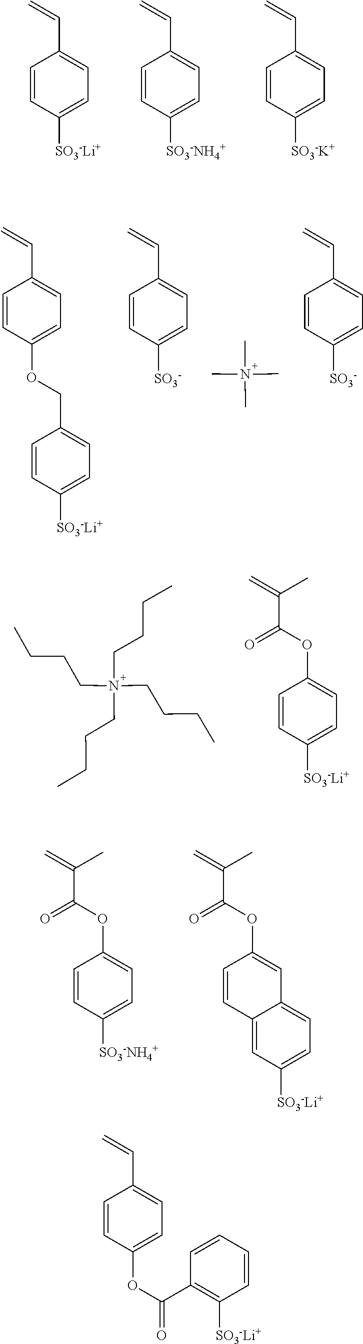

The compound represented by General formula (P-1) can be synthesized by standard procedures. For example, a synthesis method described in JP6705121B etc. can be used.

Such compounds represented by General formula (P-1) above may be used alone or in combination of two or more thereof.

In Step (1), the content of the compound represented by General formula (P-1) with respect to the total monomer amount is preferably 0.5 mol % to 30 mol %, more preferably 1 mol % to 20 mol %.

Before the polymerization step (Step (1)) is performed, a solution containing the compound represented by General formula (P-1) above is preferably passed through a filter having a pore size of 0.05 to 5 μm and subsequently the polymerization step is performed.

The pore size is 0.05 to 5 μm, more preferably 0.1 to 3 μm.

The filter is not particularly limited, examples include membrane filters, cartridge filters, and syringe filters.

### Copolymerizable Monomer Compound

Hereinafter, the copolymerizable monomer compound will be described. The copolymerizable monomer compound is a compound copolymerizable with the compound represented by General formula (P-1) above.

The copolymerizable monomer compound is not particularly limited; however, at least one of the copolymerizable monomer compound is preferably a compound represented by General formula (A-1) below.

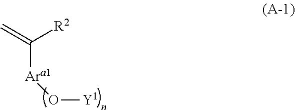

In General formula (A-1),

R² represents a hydrogen atom, an alkyl group, an aryl group, or a halogen atom;

Ar^{a1} represents an (n+1) valent aromatic ring group or an (n+1) valent aromatic heterocyclic group;

n represents an integer of 1 to 4;

Y¹ represents a hydrogen atom or a substituent, and, when n represents an integer of 2 to 4, the plurality of Y¹'s may be the same or different.

In R², the alkyl group is not particularly limited, but may be a linear or branched alkyl group having 1 to 12 carbon atoms, and is preferably an alkyl group having 1 to 6 carbon atoms, more preferably an alkyl group having 1 to 3 carbon atoms.

The aryl group is not particularly limited, but is preferably an aryl group having 6 to 14 carbon atoms, examples include a phenyl group, a naphthyl group, and an anthryl group.

The halogen atom may be, for example, a fluorine atom, a chlorine atom, a bromine atom, or an iodine atom, and is preferably a fluorine atom or an iodine atom.

The alkyl group and the aryl group may have a substituent. The substituent is not particularly limited, but may be, for example, the above-described Substituent T.

R² is preferably a hydrogen atom or an alkyl group.

Ar^{a1} represents an (n+1) valent aromatic ring group or an (n+1) valent aromatic heterocyclic group. First, for a case where n is 1, the divalent aromatic ring group and the divalent aromatic heterocyclic group will be described as follows.

The divalent aromatic ring group is not particularly limited, and may be a monocyclic or polycyclic, and is preferably an aromatic ring group having 6 to 20 carbon atoms, more preferably an aromatic ring group having 6 to 14 carbon atoms, still more preferably an aromatic ring group having 6 to 10 carbon atoms.

The divalent aromatic heterocyclic group is not particularly limited, and may be monocyclic or polycyclic. The aromatic heterocycle forming the aromatic heterocyclic group is not particularly limited; examples include thiophene, furan, pyrrole, benzothiophene, benzofuran, benzopyrrole, triazine, imidazole, benzoimidazole, triazole, thiadiazole, and thiazole.

The aromatic ring group and the aromatic heterocyclic group may have a substituent. The substituent is not particularly limited, but may be, for example, the above-described Substituent T.

The (n+1) valent aromatic ring group may be a group provided by removing, from the divalent aromatic ring group, (n−1) hydrogen atoms.

The (n+1) valent aromatic heterocyclic group may be a group provided by removing, from the divalent aromatic heterocyclic group, (n−1) hydrogen atoms.

In Y¹, the substituent is not particularly limited; examples include alkyl groups, alkylcarbonyl groups, arylcarbonyl groups, heteroarylcarbonyl groups, alkoxycarbonyl groups, and aryloxycarbonyl groups.

Such an alkyl group is not particularly limited, but may be a linear or branched alkyl group having 1 to 20 carbon atoms, and is preferably an alkyl group having 1 to 12 carbon atoms, more preferably an alkyl group having 1 to 6 carbon atoms.

In such an alkylcarbonyl group, the alkyl group is not particularly limited, but may be a linear or branched alkyl group having 1 to 20 carbon atoms, and is preferably an alkyl group having 1 to 12 carbon atoms, more preferably an alkyl group having 1 to 6 carbon atoms. In such an arylcarbonyl group, the aryl group is not particularly limited, but is preferably an aryl group having 6 to 20 carbon atoms; examples include a phenyl group, a naphthyl group, and an anthryl group.

In such a heteroarylcarbonyl group, the heteroaryl group is not particularly limited, and may be monocyclic or polycyclic. The aromatic heterocycle forming the heteroaryl group is not particularly limited; examples include thiophene, furan, pyrrole, benzothiophene, benzofuran, benzopyrrole, triazine, imidazole, benzoimidazole, triazole, thiadiazole, and thiazole.

In such an alkoxycarbonyl group, the alkoxy group is not particularly limited, but may be a linear or branched alkoxy group having 1 to 20 carbon atoms, and is preferably an alkoxy group having 1 to 12 carbon atoms, more preferably an alkoxy group having 1 to 6 carbon atoms. In such an aryloxycarbonyl group, the aryl group is not particularly limited, but is preferably an aryl group having 6 to 20 carbon atoms; examples include a phenyl group, a naphthyl group, and an anthryl group.

The alkyl group, alkylcarbonyl group, arylcarbonyl group, heteroarylcarbonyl group, alkoxycarbonyl group, and aryloxycarbonyl group may have a substituent. The substituent is not particularly limited, but may be, for example, the above-described Substituent T.

The alkyl group, alkylcarbonyl group, arylcarbonyl group, heteroarylcarbonyl group, alkoxycarbonyl group, and aryloxycarbonyl group may have a plurality of substituents.

In a preferred example, the substituent may be an aryl group, a heteroaryl group, an alkoxy group, an aryloxy group, or a heteroaryloxy group.

The aryl group may be the same as the aryl group in the arylcarbonyl group, and preferred examples thereof are also the same as those of the aryl group in the arylcarbonyl group.

The heteroaryl group may be the same as the heteroaryl group in the heteroarylcarbonyl group, and preferred examples thereof are also the same as those of the heteroaryl group in the heteroarylcarbonyl group.

The alkoxy group is not particularly limited, but may be a linear or branched alkoxy group having 1 to 20 carbon atoms, and is preferably an alkoxy group having 1 to 12 carbon atoms, more preferably an alkoxy group having 1 to 6 carbon atoms.

The aryl group in the aryl oxy group is not particularly limited, but is preferably an aryl group having 6 to 20 carbon atoms; examples include a phenyl group, a naphthyl group, and an anthryl group.

In the heteroaryloxy group, the heteroaryl group is not particularly limited, but may be the same as the heteroaryl group in the heteroarylcarbonyl group, and preferred examples thereof are also the same as those of the heteroaryl group in the heteroarylcarbonyl group.

In General formula (A-1) above, Y¹ is preferably a hydrogen atom or a group represented by any one of the following Formulas (AY-1) to (AY-3).

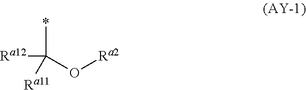

In Formula (AY-1), R^{a11} and R^{a12} each independently represent a hydrogen atom, an alkyl group, an aryl group, or a heteroaryl group, R^{a2} represents an alkyl group, an aryl group, or a heteroaryl group, and

* represents a bonding site.

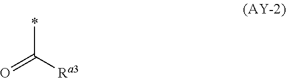

In Formula (AY-2), R^{a3} represents an alkyl group, an alkoxy group, an aryl group, an aryloxy group, or a heteroaryl group, and

* represents a bonding site.

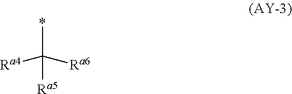

In Formula (AY-3), R^{a4} to Rₐ₆ each independently represent an alkyl group, an aryl group, or a heteroaryl group, and

* represents a bonding site.

In Formula (AY-1), in R^{a11}, R^{a12}, and R^{a2}, the alkyl group is not particularly limited, but may be a linear or branched alkyl group having 1 to 20 carbon atoms, and is preferably an alkyl group having 1 to 12 carbon atoms, more preferably an alkyl group having 1 to 6 carbon atoms.

In Rₐ₁₁, R^{a12}, and R^{a2}, the aryl group is not particularly limited, but is preferably an aryl group having 6 to 20 carbon atoms; examples include a phenyl group, a naphthyl group, and an anthryl group.

In R^{a11}, R^{a12}, and R^{a2}, the heteroaryl group is not particularly limited, and may be monocyclic or polycyclic. The aromatic heterocycle forming the heteroaryl group is not particularly limited; examples include thiophene, furan, pyrrole, benzothiophene, benzofuran, benzopyrrole, triazine, imidazole, benzoimidazole, triazole, thiadiazole, and thiazole.

The alkyl group, aryl group, and heteroaryl group may have a substituent. The substituent is not particularly limited, but may be, for example, the above-described Substituent T.

In a preferred example, R^{a12} and R^{a2} may each independently be an alkyl group.

In another preferred example, R^{a11} may be a hydrogen atom, and R^{a12} and R^{a2} may each independently be an alkyl group.

In Formula (AY-2), in R^{a3}, the alkyl group is not particularly limited, but may be the same as the above-described alkyl group in R^{a11}, R^{a12}, and R^{a2}, and preferred examples thereof are also the same as those of the above-described alkyl group in R^{a11}, R^{a12}, and R^{a2}.

In R^{a3}, the alkoxy group is not particularly limited, but may be a linear or branched alkoxy group having 1 to 20 carbon atoms, and is preferably an alkoxy group having 1 to 12 carbon atoms, more preferably an alkoxy group having 1 to 6 carbon atoms.

In R^{a3}, the aryl group is not particularly limited, but may be the same as the above-described aryl group in R^{a11}, R^{a12}, and R^{a2}, and preferred examples thereof are also the same as those of the above-described aryl group in R^{a11}, R^{a12}, and R^{a2}.

In R^{a3}, the aryl group in the aryloxy group is not particularly limited, but is preferably an aryl group having 6 to 20 carbon atoms; examples include a phenyl group, a naphthyl group, and an anthryl group.

In R^{a3}, the heteroaryl group is not particularly limited, but may be the same as the above-described heteroaryl group in R^{a11}, R^{a12}, and R^{a2}, and preferred examples thereof are also the same as those of the above-described heteroaryl group in R^{a11}, R^{a12}, and R^{a2}.

R^{a3} is preferably an alkyl group.

In Formula (AY-3), in R^{a4} to R^{a6}, the alkyl group is not particularly limited, but may be the same as the above-described alkyl group in R^{a11}, R^{a12}, and R^{a2}, and preferred examples thereof are also the same as those of the above-described alkyl group in R^{a11}, R^{a12}, and R^{a2}.

In R^{a4} to R^{a6}, the aryl group is not particularly limited, but may be the same as the above-described aryl group in R^{a11}, R^{a12}, and R^{a2}, and preferred examples thereof are also the same as those of the above-described aryl group in R^{a11}, R^{a12}, and R^{a2}.

In R^{a4} to R^{a6}, the heteroaryl group is not particularly limited, but may be the same as the above-described heteroaryl group in R^{a11}, R^{a12}, and R^{a2}, and preferred examples thereof are also the same as those of the above-described heteroaryl group in R^{a11}, R^{a12}, and R^{a2}.

R^{a4} to R^{a6} are each independently preferably an alkyl group.

The compound represented by General formula (A-1) above is preferably the compound represented by any one of the following Formulas (A-2) to (A-5).

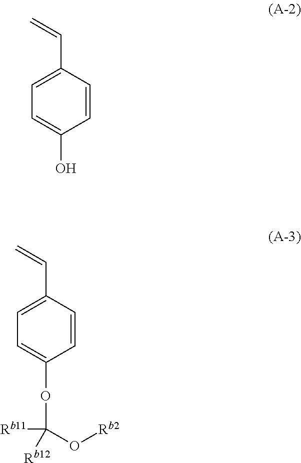

In Formula (A-3), R^{b11} and R^{b12} each independently represent a hydrogen atom, an alkyl group, an aryl group, or a heteroaryl group. R^{b2} represents an alkyl group, an aryl group, or a heteroaryl group.

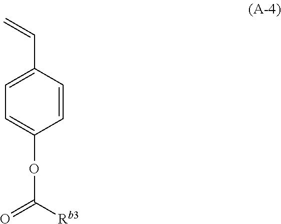

In Formula (A-4), R^{b3} represents an alkyl group, an alkoxy group, an aryl group, an aryloxy group, or a heteroaryl group.

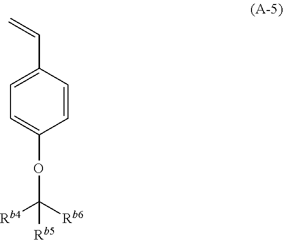

In Formula (A-5), R^{b4} to R^{b6} each independently represent an alkyl group, an aryl group, or a heteroaryl group.

In Formula (A-3), in R^{b11}, R^{b12}, and R^{b2}, the alkyl group is not particularly limited, but may be the same as the above-described alkyl group in R^{a11}, R^{a12}, and R^{a2} in Formula (AY-1), and preferred examples thereof are also the same as those of the above-described alkyl group in R^{a11}, R^{a12}, and R^{a12} in Formula (AY-1).

In R^{b11}, R^{b12}, and R^{b2}, the aryl group is not particularly limited, but may be the same as the above-described aryl group in R^{a11}, R^{a11}, and R^{a2} in Formula (AY-1), and preferred examples thereof are also the same as those of the above-described aryl group in R^{a11}, R^{a12}, and R^{a2} in Formula (AY-1).

In R^{b11}, R^{b12}, and R^{b2}, the heteroaryl group is not particularly limited, but may be the same as the above-described heteroaryl group in R^{a11}, R^{a12}, and R^{a2} in Formula (AY-1), and preferred examples thereof are also the same as those of the above-described heteroaryl group in R^{a11}, R^{a12}, and R^{a2} in Formula (AY-1).

In Formula (A-4), in R^{b3}, the alkyl group is not particularly limited, but may be the same as the above-described alkyl group in R^{a11}, R^{a12}, and R^{a2} in Formula (AY-1), and preferred examples thereof are also the same as those of the above-described alkyl group in R^{a11}, R^{a12}, and R² in Formula (AY-1).

In R^{b3}, the alkoxy group is not particularly limited, but may be a linear or branched alkoxy group having 1 to 20 carbon atoms, and is preferably an alkoxy group having 1 to 12 carbon atoms, more preferably an alkoxy group having 1 to 6 carbon atoms.

In R^{b3}, the aryl group is not particularly limited, but may be the same as the above-described aryl group in R^{a11}, R^{a12}, and R^{a12} in Formula (AY-1), and preferred examples thereof are also the same as those of the above-described aryl group in R^{a11}, R^{a12}, and R^{a2} in Formula (AY-1).

In R^{b3}, in the aryloxy group, the aryl group is not particularly limited, but is preferably an aryl group having 6 to 20 carbon atoms; examples include a phenyl group, a naphthyl group, and an anthryl group.

In R^{b3}, the heteroaryl group is not particularly limited, but may be the same as the above-described heteroaryl group in R^{a11}, R^{a12}, and R^{a2} in Formula (AY-1), and preferred examples thereof are also the same as those of the above-described heteroaryl group in R^{a11}, R^{a12}, and R^{a2} in Formula (AY-1).

In Formula (A-5), in R^{b4} to R^{b6}, the alkyl group is not particularly limited, but may be the same as the above-described alkyl group in R^{a11}, R^{a12}, and R^{a2} in Formula (AY-1), and preferred examples thereof are also the same as those of the above-described alkyl group in R^{a11}, R^{a12}, and R^{a2} in Formula (AY-1).

In R^{b4} to R^{b6}, the aryl group is not particularly limited, but may be the same as the above-described aryl group in R^{a11}, R^{a12}, and R^{a2} in Formula (AY-1), and preferred examples thereof are also the same as those of the above-described aryl group in R^{a11}, R^{a12}, and R^{a2} in Formula (AY-1).

In R^{b4} to R^{b6}, the heteroaryl group is not particularly limited, but may be the same as the above-described heteroaryl group in R^{a11}, R^{a12}, and R^{a2} in Formula (AY-1), and preferred examples thereof are also the same as those of the above-described heteroaryl group in R^{a11}, R^{a12l}, and R¹² in Formula (AY-1).

The compound represented by General formula (A-1) above is preferably a compound represented by any one of Formulas (A-3) to (A-5) above.

As the copolymerizable monomer compound, a compound other than the compound represented by General formula (A-1) above, the compound being copolymerizable with the compound represented by General formula (P-1) above, can be appropriately used.

The following are specific examples of the copolymerizable monomer compound; however, the present invention is not limited to these.

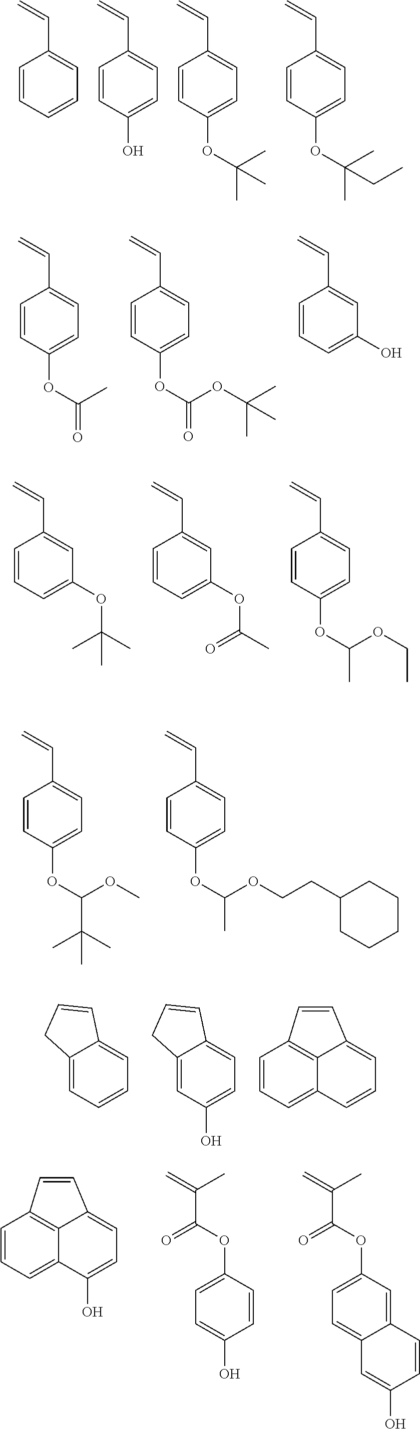

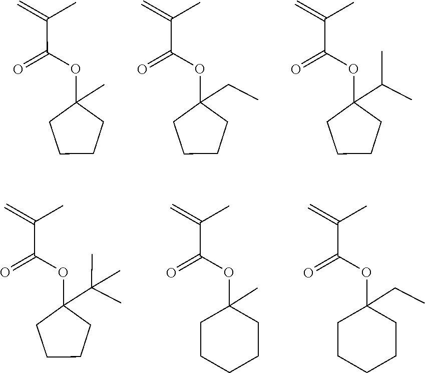

Such copolymerizable monomer compounds may be used alone or in combination of two or more thereof.

In Step (1), the content of the copolymerizable monomer compound with respect to the total monomer amount is preferably 70 mol % to 99.5 mol %, more preferably 80 mol % to 99 mol %.

In Step (1), the total amount of the content of the compound represented by General formula (P-1) above and the content of the compound represented by General formula (A-1) above with respect to the total monomer amount is preferably 70 mol % to 100 mol %, more preferably 80 mol % to 100 mol %.

In Step (1), the compound represented by General formula (P-1) above and the copolymerizable monomer compound can be polymerized to synthesize Resin P. Resin P corresponds to a reaction intermediate of the resin.

Resin P can be synthesized in accordance with standard procedures (for example, radical polymerization).

Resin P has a weight-average molecular weight (determined as a polystyrene equivalent value by the GPC method) of preferably 30,000 or less, more preferably 1,000 to 30,000, still more preferably 3,000 to 30,000, particularly preferably 5,000 to 15,000.

Resin P has a dispersity (molecular weight distribution) of preferably 1 to 5, more preferably 1 to 3, still more preferably 1.2 to 3.0, particularly preferably 1.2 to 2.0.

The method for producing a resin according to the present invention preferably includes a step of, after the polymerization step (Step (1)), causing, in the repeating unit derived from the compound represented by General formula (P-1) above, exchange between cation M* and an organic cation.

Hereinafter, in the method for producing a resin according to the present invention, a step of, after Step (1) above, causing, in the repeating unit derived from the compound represented by General formula (P-1) above, exchange between cation M* and an organic cation (also referred to as Step (2)) will be described.

### Step (2)

In the present invention, Step (2) refers to a step of causing, in the repeating unit derived from the compound represented by General formula (P-1) above, exchange between cation M⁺ and an organic cation.

This exchange (salt exchange) can be performed by causing a reaction between Resin P above and a compound having an organic cation (hereafter, also referred to as Compound A) in a solvent.

Compound A is a compound that is used for the exchange and has an organic cation serving as a cationic moiety and an anionic moiety.

The anionic moiety is preferably a non-nucleophilic ion; examples include halogen ions such as a bromide ion and a chloride ion, a carbonate ion, and a trifluoroacetate ion.

In Compound A, the organic cation serving as a cationic moiety is not particularly limited, but is preferably a cation represented by Formula (ZaI) (hereafter, also referred to as “Cation (ZaI)”), or a cation represented by Formula (ZaII) (hereafter, also referred to as “Cation (ZaII)”).

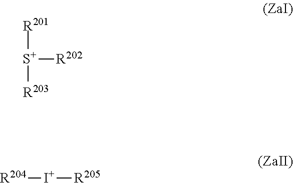

In Formula (ZaI) above,

R²⁰¹, R²⁰², and R²⁰³ each independently represent an organic group.

In R²⁰¹, R²⁰² and R²⁰³, such an organic group preferably has 1 to 30, more preferably 1 to 20 carbon atoms. Of R²⁰¹ to R²⁰³, two may be linked together to form a ring structure and the ring may include an oxygen atom, a sulfur atom, an ester group, an amide group, or a carbonyl group. Examples of the group formed by linking together two of R²⁰¹ to R²⁰³ include alkylene groups (such as a butylene group and a pentylene group), and —CH₂—CH₂—O—CH₂—CH₂—.

In Formula (ZaI), preferred examples of the organic cation include, as described later,

Cation (ZaI-1), Cation (ZaI-2), an organic cation represented by Formula (ZaI-3b) (Cation (ZaI-3b)), and an organic cation represented by Formula (ZaI-4b) (Cation (ZaI-4b)).

First, Cation (ZaI-1) will be described.

Cation (ZaI-1) is an aryl sulfonium cation represented by Formula (ZaI) above where at least one of R²⁰¹ to R²⁰³ is an aryl group.

In the aryl sulfonium cation, all of R²⁰¹ to R²⁰³ may be aryl groups, or at least one of R²⁰¹ to R²⁰³ may be an aryl group and the other may be an alkyl group or a cycloalkyl group. Alternatively, one of R²⁰¹ to R²⁰³ may be an aryl group and the other two of R²⁰¹ to R²⁰³ may be linked together to form a ring structure and the ring may include an oxygen atom, a sulfur atom, an ester group, an amide group, or a carbonyl group. Examples of the group formed by linking together two of R²⁰¹ to R²⁰³ include alkylene groups in which at least one methylene group may be substituted with an oxygen atom, a sulfur atom, an ester group, an amide group, and/or a carbonyl group (such as a butylene group, a pentylene group, and —CH₂—CH₂—O—CH₂—CH₂—).

Examples of the aryl sulfonium cation include triaryl sulfonium cations, diaryl alkyl sulfonium cations, aryl dialkyl sulfonium cations, diaryl cycloalkyl sulfonium cations, and aryl dicycloalkyl sulfonium cations.

The aryl group included in the aryl sulfonium cation is preferably a phenyl group or a naphthyl group, more preferably a phenyl group. The aryl group may be an aryl group having a heterocyclic structure having an oxygen atom, a nitrogen atom, or a sulfur atom, for example. Examples of the heterocyclic structure include a pyrrole residue, a furan residue, a thiophene residue, an indole residue, a benzofuran residue, and a benzothiophene residue. When the aryl sulfonium cation has two or more aryl groups, the two or more aryl groups may be the same or different.

The aryl sulfonium cation optionally has an alkyl group or cycloalkyl group that is preferably a linear alkyl group having 1 to 15 carbon atoms, a branched alkyl group having 3 to 15 carbon atoms, or a cycloalkyl group having 3 to 15 carbon atoms, more preferably a methyl group, an ethyl group, a propyl group, an n-butyl group, a sec-butyl group, a t-butyl group, a cyclopropyl group, a cyclobutyl group, or a cyclohexyl group.

In R²⁰¹ to R²⁰³, the aryl group, the alkyl group, and the cycloalkyl group may have a substituent; the substituent is preferably an alkyl group (having, for example, 1 to 15 carbon atoms), a cycloalkyl group (having, for example, 3 to 15 carbon atoms), an aryl group (having, for example, 6 to 14 carbon atoms), an alkoxy group (having, for example, 1 to 15 carbon atoms), a cycloalkylalkoxy group (having, for example, 1 to 15 carbon atoms), a halogen atom (for example, fluorine or iodine), a hydroxy group, a carboxyl group, an ester group, a sulfinyl group, a sulfonyl group, an alkylthio group, or a phenylthio group.

The substituent may further have, if possible, a substituent; the alkyl group preferably has, as a substituent, a halogen atom to serve as an alkyl halide group such as a trifluoromethyl group.

Hereinafter, Cation (ZaI-2) will be described.

Cation (ZaI-2) is a cation represented by Formula (ZaI) where R²⁰¹ to R²⁰³ each independently represent an organic group not having an aromatic ring. The aromatic ring also encompasses aromatic rings including heteroatoms.

In R²⁰¹ to R²⁰³, the organic group not having an aromatic ring preferably has 1 to 30, more preferably 1 to 20 carbon atoms.

R₂₀₁ to R²⁰³ each independently represent preferably an alkyl group, a cycloalkyl group, an allyl group, or a vinyl group, more preferably a linear or branched 2-oxoalkyl group, a 2-oxocycloalkyl group, or an alkoxycarbonylmethyl group, still more preferably a linear or branched 2-oxoalkyl group.

In R²⁰¹ to R²⁰³, the alkyl group and the cycloalkyl group may be, for example, a linear alkyl group having 1 to 10 carbon atoms or a branched alkyl group having 3 to 10 carbon atoms (for example, a methyl group, an ethyl group, a propyl group, a butyl group, or a pentyl group), and a cycloalkyl group having 3 to 10 carbon atoms (for example, a cyclopentyl group, a cyclohexyl group, or a norbornyl group).

R²⁰¹ to R²⁰³ may be further substituted with a halogen atom, an alkoxy group (having, for example, 1 to 5 carbon atoms), a hydroxy group, a cyano group, or a nitro group.

Hereinafter, Cation (ZaI-3b) will be described.

Cation (ZaI-3b) is a cation represented by the following Formula (ZaI-3b).

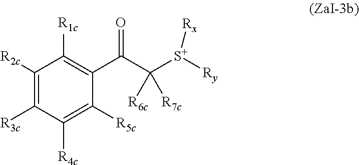

In Formula (ZaI-3b),

R_{1c} to R_{5c} each independently represent a hydrogen atom, an alkyl group, a cycloalkyl group, an aryl group, an alkoxy group, an aryloxy group, an alkoxycarbonyl group, an alkylcarbonyloxy group, a cycloalkylcarbonyloxy group, a halogen atom, a hydroxy group, a nitro group, an alkylthio group, or an arylthio group.

R_{6c} and R^{7c} each independently represent a hydrogen atom, an alkyl group (for example, a t-butyl group), a cycloalkyl group, a halogen atom, a cyano group, or an aryl group.

Rₓ and R_{y} each independently represent an alkyl group, a cycloalkyl group, a 2-oxoalkyl group, a 2-oxocycloalkyl group, an alkoxycarbonylalkyl group, an allyl group, or a vinyl group.

Any two or more of R_{1c} to R_{5c}, R_{5c} and R_{6c}, R_{6c} and R_{7c}, R_{5c} and Rₓ and Rₓ and R_{y} may be individually linked together to form rings; these rings may each independently include an oxygen atom, a sulfur atom, a ketone group, an ester bond, or an amide bond.

Such a ring may be an aromatic or non-aromatic hydrocarbon ring, an aromatic or non-aromatic heterocycle, or a polycyclic fused ring formed as a combination of two or more of these rings. The ring may be a 3 to 10-membered ring, and is preferably a 4 to 8-membered ring, more preferably a 5- or 6-membered ring.

Examples of the groups formed by linking together any two or more of R_{1c} to R_{5c}, R_{6c} and R_{7c}, and Rₓ and R_{y} include alkylene groups such as a butylene group and a pentylene group. In such an alkylene group, a methylene group may be substituted with a heteroatom such as an oxygen atom.

The groups formed by linking together R^{5c} and R_{6c}, and R_{5c} and Rₓ are preferably single bonds or alkylene groups. The alkylene groups may be a methylene group and an ethylene group.

R_{1c} to R_{5c}, R_{5c}, R_{7c}, Rₓ, R_{y}, and the rings formed by individually linking together any two or more of R_{1c} to R_{5c}, R_{5c} and R_{6c}, R₆ₑ and R_{7c}, R_{5c} and Rₓ, and Rₓ and R_{y} may have a substituent.

Hereinafter, Cation (ZaI-4b) will be described.

Cation (ZaI-4b) is a cation represented by the following Formula (ZaI-4b).

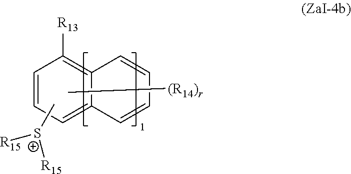

In Formula (ZaI-4b),

l represents an integer of 0 to 2; and

r represents an integer of 0 to 8.

R₁₃ represents a hydrogen atom, a halogen atom (for example, a fluorine atom or an iodine atom), a hydroxy group, an alkyl group, an alkyl halide group, an alkoxy group, a carboxyl group, an alkoxycarbonyl group, or a group including a cycloalkyl group (may be the cycloalkyl group itself or a group including, as a part thereof, the cycloalkyl group). These groups may have a substituent.

R₁₄ represents a hydroxy group, a halogen atom (for example, a fluorine atom or an iodine atom), an alkyl group, an alkyl halide group, an alkoxy group, an alkoxycarbonyl group, an alkylcarbonyl group, an alkylsulfonyl group, a cycloalkylsulfonyl group, or a group including a cycloalkyl group (may be the cycloalkyl group itself or a group including, as a part thereof, the cycloalkyl group). These groups may have a substituent. When there are a plurality of R₁₄'s, R₁₄'s each independently represent such a group, for example, a hydroxy group.

R₁₅'s each independently represent an alkyl group, a cycloalkyl group, or a naphthyl group. Two R₁₅'s may be linked together to form a ring. When two R₁₅'s are linked together to form a ring, the ring skeleton may include a heteroatom such as an oxygen atom or a nitrogen atom.

In an example, two R₁₅'s are preferably alkylene groups and linked together to form a ring structure. Note that the alkyl group, the cycloalkyl group, the naphthyl group, and the ring formed by linking together two R₁₅'s may have a substituent.

In Formula (ZaI-4b), in R₁₃, R₁₄, and R₁₅, the alkyl groups may be linear or branched. Such an alkyl group preferably has 1 to 10 carbon atoms. Preferred examples of the alkyl group include a methyl group, an ethyl group, an n-butyl group, and a t-butyl group.

In R₁₃ to R₁₅, and Rₓ and R_{y}, the substituents also preferably independently form, as a result of an appropriate combination of the substituents, an acid decomposable group.

Hereinafter, Formula (ZaII) will be described.

In Formula (ZaII), R²⁰⁴ and R²⁰⁵ each independently represent an aryl group, an alkyl group or a cycloalkyl group.

In R²⁰⁴ and R²⁰⁵, the aryl group is preferably a phenyl group or a naphthyl group, more preferably a phenyl group. In R²⁰⁴ and R²⁰ 5, the aryl group may be an aryl group having a heterocycle having an oxygen atom, a nitrogen atom, or a sulfur atom, for example. Examples of the skeleton of the aryl group having a heterocycle include pyrrole, furan, thiophene, indole, benzofuran, and benzothiophene.

In R²⁰⁴ and R²⁰⁵, the alkyl group and the cycloalkyl group are preferably a linear alkyl group having 1 to 10 carbon atoms or a branched alkyl group having 3 to 10 carbon atoms (for example, a methyl group, an ethyl group, a propyl group, a butyl group, or a pentyl group), and a cycloalkyl group having 3 to 10 carbon atoms (for example, a cyclopentyl group, a cyclohexyl group, or a norbornyl group).

In R²⁰⁴ and R²⁰⁵, the aryl group, the alkyl group, and the cycloalkyl group may each independently have a substituent. In R²⁰⁴ and R²⁰⁵, the aryl group, the alkyl group, and the cycloalkyl group may have a substituent; examples of the substituent include alkyl groups (having, for example, 1 to 15 carbon atoms), cycloalkyl groups (having, for example, 3 to 15 carbon atoms), aryl groups (having, for example, 6 to 15 carbon atoms), alkoxy groups (having, for example, 1 to 15 carbon atoms), halogen atoms, a hydroxy group, and a phenylthio group. In R²⁰⁴ and R²⁰⁵, each independently, substituents also preferably, as a result of an appropriate combination of the substituents, form an acid decomposable group.

The following are specific examples of the organic cation; however, the present invention is not limited to these.

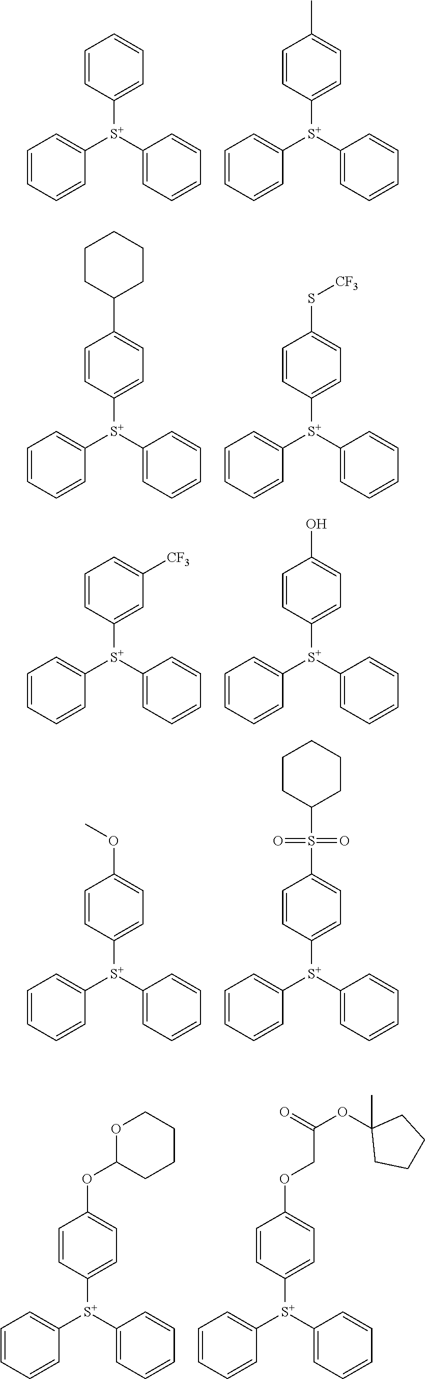

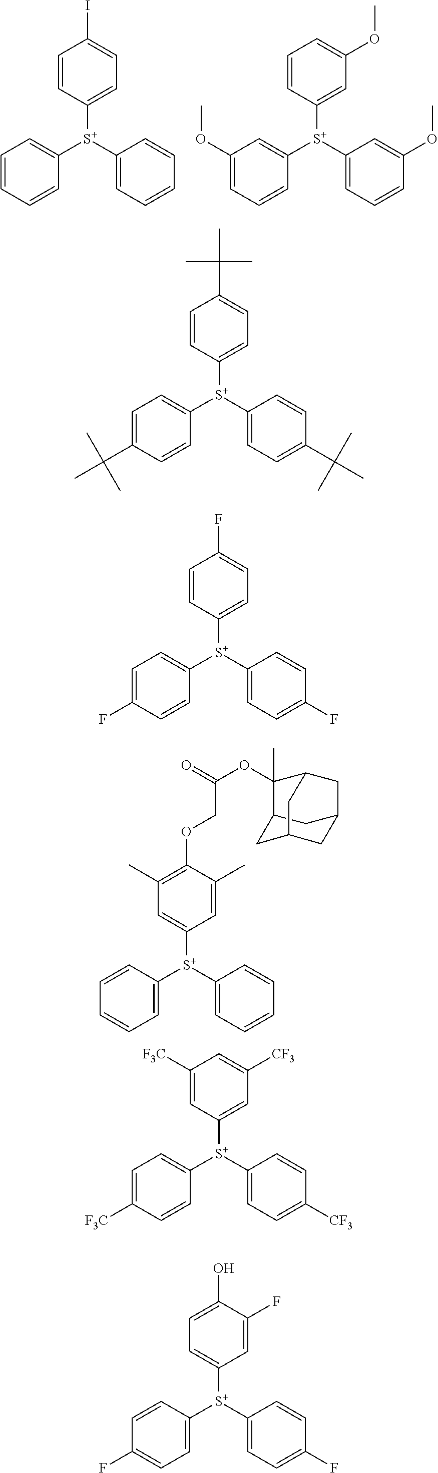

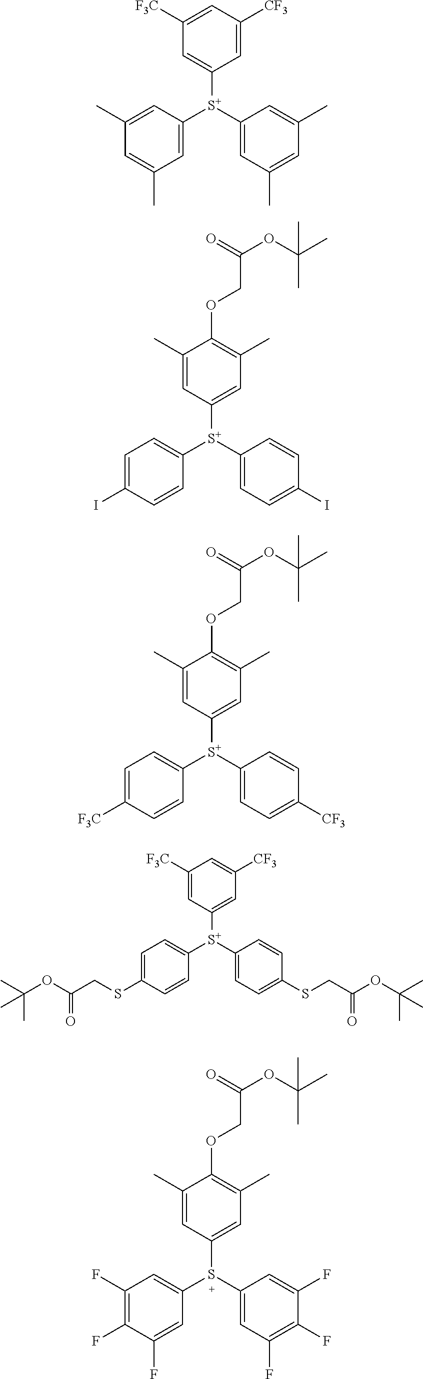

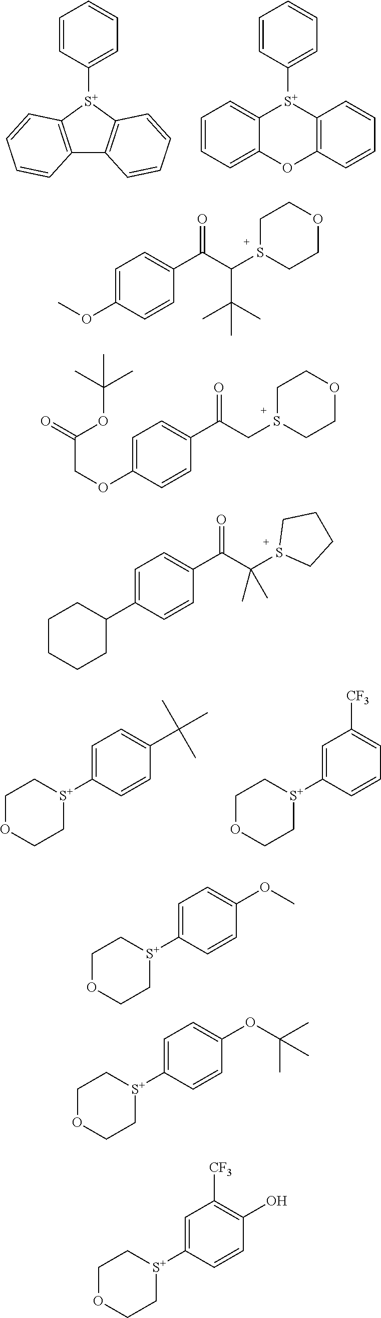

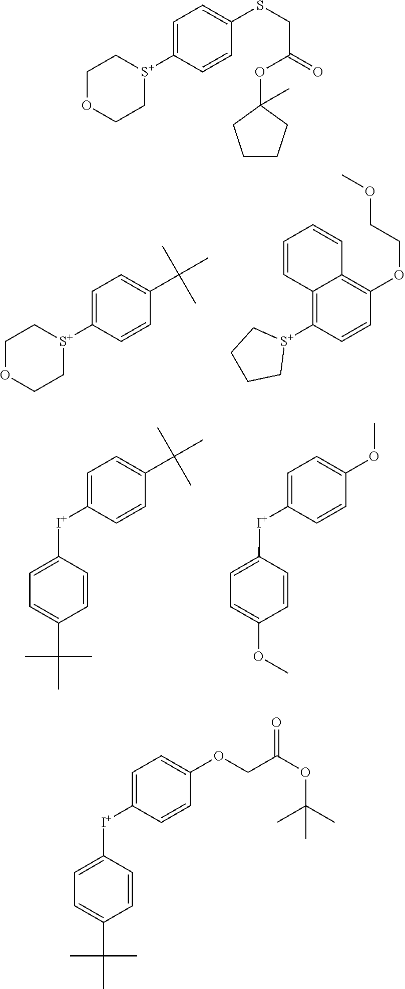 [SMILES: CC1(OC(=O)CSc2ccc([S+]3CCOCC3)cc2)CCCC1 ; CC(C)(C)c1ccc([S+]2CCOCC2)cc1 ; COCCOc1ccc([S+]2CCCC2)c2ccccc12 ; CC(C)(C)c1ccc([I+]c2ccc(C(C)(C)C)cc2)cc1 ; COc1ccc([I+]c2ccc(OC)cc2)cc1 ; CC(C)(C)OC(=O)COc1ccc([I+]c2ccc(C(C)(C)C)cc2)cc1]

### Solvent

In Step (2) above, the reaction is typically caused in a liquid phase. Specifically, the reaction system typically includes a solvent.

This solvent is not particularly limited as long as it dissolves components to allow the salt exchange; examples include water, alcohol-based solvents, nitrile-based solvents, halogen-based solvents, ester-based solvents, and mixed solvents of two or more of the foregoing.

The reaction temperature is preferably about 0 to about 40° C., more preferably about 10 to about 30° C.

The reaction time varies depending on, for example, the reactivity between Resin A and the compound for exchange (Compound A) and the reaction temperature, but is ordinarily preferably 10 minutes or more and 24 hours or less, more preferably 0.25 to 6 hours.

In Step (2) above, in the exchange, the amount of Compound A used is ordinarily, with respect to the number of moles of a repeating unit derived from the compound represented by General formula (P-1) in 1 mol of Resin P above, preferably about 1 to about 3 moles.

The method for producing a resin according to the present invention preferably includes the following example.

A method for producing a resin, wherein the compound represented by General formula (A-1) above is the compound represented by any one of Formulas (A-3) to (A-5) above, and the method includes a step of, after the polymerization step, converting a repeating unit derived from the compound represented by General formula (A-1) above, to a repeating unit represented by the following Formula (AP-1).

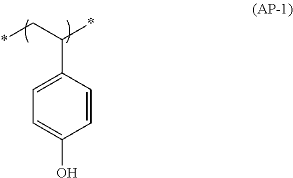

In the step of, after the polymerization step, converting the repeating unit derived from the compound represented by General formula (A-1) above to the repeating unit represented by Formula (AP-1) below (hereafter, also referred to as Step (3)), the reaction is typically a hydrolysis reaction, and the reaction is not particularly limited as long as it is caused after the polymerization step (Step (1)).

In a preferred example, Step (3) may be performed before Step (2) above, after Step (2) above, or concurrently with Step (2) above. Step (3) is preferably performed before Step (2) above.

Step (3) above can be performed by standard procedures.

A production method according to the present invention preferably includes a step of converting at least partially the repeating unit represented by Formula (AP-1) above to a repeating unit represented by the following Formula (AP-2) (hereafter, also referred to as Step (4)).

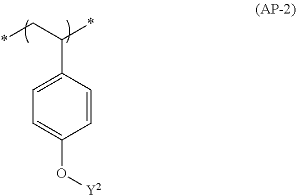

In Formula (AP-2), Y² represents a group that leaves due to the action of acid.

Examples of the group that leaves due to the action of acid (leaving group) include groups represented by Formulas (Y1) to (Y5).

—C(Rx₁)(Rx₂)(Rx₃) Formula (Y1):

—C(═O)OC(Rx₁)(Rx₂)(Rx₃) Formula (Y2):

—C(R₃₆)(R₃₇)(OR₃₈) Formula(Y3):

—C(Rn)(H)(Ar) Formula (Y4):

—C(═O)R₅₁ Formula (Y5):

In Formula (Y1) and Formula (Y2), Rx₁ to Rx₃ each independently represent an alkyl group (linear or branched), a cycloalkyl group (monocyclic or polycyclic), an alkenyl group (linear or branched), an aryl group (monocyclic or polycyclic), or a heteroaryl group (monocyclic or polycyclic). Note that, when Rx₁ to Rx₃ are all alkyl groups (linear or branched), at least two of Rx₁ to Rx₃ are preferably methyl groups.

In particular, Rx₁ to Rx₃ each independently represent preferably a linear or branched alkyl group; more preferably, Rx₁ to Rx₃ each independently represent a linear alkyl group.

Of Rx₁ to Rx₃, two may be linked together to form a monocycle or a polycycle.

In Rx₁ to Rx₃, the alkyl group is not particularly limited, but may be, for example, an alkyl group having 1 to 20 carbon atoms, and is preferably an alkyl group having 1 to 5 carbon atoms such as a methyl group, an ethyl group, an n-propyl group, an isopropyl group, an n-butyl group, an isobutyl group, or a t-butyl group.

In Rx₁ to Rx₃, the cycloalkyl group is not particularly limited, but may be, for example, a cycloalkyl group having 3 to 20 carbon atoms, and is preferably a monocyclic cycloalkyl group such as a cyclopentyl group or a cyclohexyl group or a polycyclic cycloalkyl group such as a norbornyl group, a tetracyclodecanyl group, a tetracyclododecanyl group, or an adamantyl group.

In Rx₁ to Rx₃, the aryl group is not particularly limited, but may be, for example, an aryl group having 6 to 20 carbon atoms, and is preferably an aryl group having 6 to 10 carbon atoms, for example, a phenyl group, a naphthyl group, or an anthryl group.

In Rx₁ to Rx₃, the heteroaryl group is not particularly limited, and may be monocyclic or polycyclic. The aromatic heterocycle forming the heteroaryl group is not particularly limited; examples include thiophene, furan, pyrrole, benzothiophene, benzofuran, benzopyrrole, triazine, imidazole, benzoimidazole, triazole, thiadiazole, and thiazole.

In Rx₁ to Rx₃, the alkenyl group is not particularly limited, but is preferably a vinyl group.

The ring formed by linking together two of Rx₁ to Rx₃ is preferably a cycloalkyl group. The cycloalkyl group formed by linking together two of Rx₁ to Rx₃ is preferably a monocyclic cycloalkyl group such as a cyclopentyl group or a cyclohexyl group, or a polycyclic cycloalkyl group such as a norbornyl group, a tetracyclodecanyl group, a tetracyclododecanyl group, or an adamantyl group, more preferably a monocyclic cycloalkyl group having 5 to 6 carbon atoms.

In the cycloalkyl group formed by linking together two of Rx₁ to Rx₃, one of methylene groups forming the ring may be replaced by a heteroatom such as an oxygen atom, a group including a heteroatom such as a carbonyl group, or a vinylidene group. In the cycloalkyl group, one or more ethylene groups forming the cycloalkane ring may be replaced by vinylene groups.

The group represented by Formula (Y1) or Formula (Y2) preferably has a form in which, for example, Rx₁ is a methyl group or an ethyl group, and Rx₂ and Rx₃ are linked together to form the cycloalkyl group.

In Formula (Y3), R₃₆ to R₃₈ each independently represent a hydrogen atom or a monovalent organic group. R₃₇ and R₃₈ may be linked together to form a ring. The monovalent organic group may be an alkyl group, a cycloalkyl group, an aryl group, a heteroaryl group, an aralkyl group, or an alkenyl group. R₃₆ is also preferably a hydrogen atom.

Note that the alkyl group, the cycloalkyl group, the aryl group, and the aralkyl group may include a heteroatom such as an oxygen atom and/or a group including a heteroatom such as a carbonyl group. For example, in the alkyl group, the cycloalkyl group, the aryl group, and the aralkyl group, at least one methylene group may be replaced by a heteroatom such as an oxygen atom and/or a group including a heteroatom such as a carbonyl group.

R₃₈ and another substituent of the main chain of the repeating unit may be linked together to form a ring. The group formed by linking together R₃₈ and another substituent of the main chain of the repeating unit is preferably an alkylene group such as a methylene group.

Formula (Y3) is preferably a group represented by the following Formula (Y3-1).

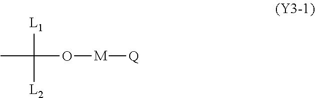

L₁ and L₂ each independently represent a hydrogen atom, an alkyl group, a cycloalkyl group, an aryl group, a heteroaryl group, or a group of a combination of the foregoing (for example, a group of a combination of an alkyl group and an aryl group).

M represents a single bond or a divalent linking group.

Q represents an alkyl group that may include a heteroatom, a cycloalkyl group that may include a heteroatom, an aryl group that may include a heteroatom, an amino group, an ammonium group, a mercapto group, a cyano group, an aldehyde group, or a group of a combination of the foregoing (for example, a group of a combination of an alkyl group and a cycloalkyl group).

In the alkyl group and the cycloalkyl group, for example, one of methylene groups may be replaced by a heteroatom such as an oxygen atom or a group including a heteroatom such as a carbonyl group.

Note that one of L₁ and L₂ is preferably a hydrogen atom and the other is an alkyl group, a cycloalkyl group, an aryl group, or a group that is a combination of an alkylene group and an aryl group.

At least two of Q, M, and L₁ may be linked together to form a ring (preferably a five-membered or six-membered ring).

In Formula (Y4), Ar represents an aromatic ring group. Rn represents an alkyl group, a cycloalkyl group, or an aryl group. Rn and Ar may be linked together to form a non-aromatic ring. Ar is preferably an aryl group.

In Formula (Y5), R₅₁ represents an alkyl group (linear or branched), an alkoxy group (linear or branched), a cycloalkyl group (monocyclic or polycyclic), an alkenyl group (linear or branched), an aryl group (monocyclic or polycyclic), an aryloxy group, or a heteroaryl group (monocyclic or polycyclic).

The alkyl group (linear or branched), the cycloalkyl group (monocyclic or polycyclic), the alkenyl group (linear or branched), the aryl group (monocyclic or polycyclic), or the heteroaryl group (monocyclic or polycyclic) is respectively the same as and has the same preferred examples as, in Rx₁ to Rx₃ above, the alkyl group (linear or branched), the cycloalkyl group (monocyclic or polycyclic), the alkenyl group (linear or branched), the aryl group (monocyclic or polycyclic), or the heteroaryl group (monocyclic or polycyclic).

In R₅₁, the alkoxy group is not particularly limited, but may be a linear or branched alkoxy group having 1 to 20 carbon atoms, and is preferably an alkoxy group having 1 to 12 carbon atoms, more preferably an alkoxy group having 1 to 6 carbon atoms.

In R₅₁, in the aryloxy group, the aryl group is not particularly limited, but is preferably an aryl group having 6 to 20 carbon atoms; examples include a phenyl group, a naphthyl group, and an anthryl group.

Step (4) above is not particularly limited as long as it is performed after the polymerization step (Step (1)) and after Step (3) above; however, as a preferred example, Step (4) may be performed before Step (2) above or after Step (2) above. Alternatively, Step (4) may be performed concurrently with Step (2) above.

The step is a step of protecting at least partially the phenolic hydroxy groups in the repeating unit represented by Formula (AP-1) above, with Groups Y² that leave due to the action of acid, and can be performed by standard procedures.

In the repeating unit represented by Formula (AP-1) above, at least partially the phenolic hydroxy groups are protected by Groups Y² that leave due to the action of acid; the ratio of protecting the phenolic hydroxy groups by Groups Y² that leave due to the action of acid can be appropriately selected in accordance with the structure of the resin synthesized.

A method for producing a resin according to the present invention preferably includes the following example.

A method for producing a resin, wherein the compound represented by General formula (A-1) above is the compound represented by Formula (A-2) above, the method including a step of converting, after the polymerization step, at least partially the repeating unit derived from the compound represented by General formula (A-2) above to the repeating unit represented by the following Formula (AP-2).

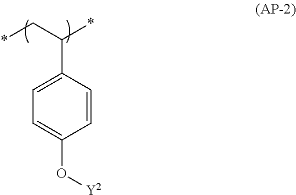

In Formula (AP-2), Y² represents a group that leaves due to the action of acid.

Y² has the same definition and preferred examples as Y² in Formula (AP-2) in Step (4) above.

The step of converting, after the polymerization step, the repeating unit derived from the compound represented by General formula (A-2) above to the repeating unit represented by Formula (AP-1) below (hereafter, also referred to as Step (5)) is not particularly limited as long as it is performed after the polymerization step (Step (1)); in a preferred example, Step (5) may be performed before Step (2) above, or after Step (2) above. Alternatively, Step (5) may be performed concurrently with Step (2) above.

The step is a step of protecting at least partially phenolic hydroxy groups in the repeating unit represented by Formula (A-2) above with Groups Y² that leave due to the action of acid, and can be performed by standard procedures.

In the repeating unit represented by Formula (A-2) above, at least partially the phenolic hydroxy groups are protected by Groups Y² that leave due to the action of acid; the ratio of protecting the phenolic hydroxy groups by Groups Y² that leave due to the action of acid can be appropriately selected in accordance with the structure of the resin synthesized.

In Formula (AP-2) above, Y² is preferably the group represented by the following Formula (AY-4).

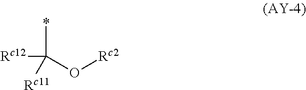

In Formula (AY-4), R^{c11} and R^{c12} each independently represent a hydrogen atom, an alkyl group, an aryl group, or a heteroaryl group; R^{c2} represents an alkyl group, an aryl group, or a heteroaryl group; and

* represents a bonding site.

In Formula (AY-4), in R^{c11}, R^{c12}, and R_{c2}, the alkyl group is not particularly limited, but may be the same as the above-described alkyl group in R^{a11}, R^{a12}, and R^{a2} in Formula (AY-1), and preferred examples thereof are also the same as those of the above-described alkyl group in R^{a11}, R^{a12}, and R^{a2} in Formula (AY-1).

In R^{c11}, R^{c12}, and R^{c2}, the aryl group is not particularly limited, but may be the same as the above-described aryl group in R^{a11}, R^{a12}, and R^{a2} in Formula (AY-1), and preferred examples thereof are also the same as those of the above-described aryl group in R^{a11}, R^{a12}, and R^{a2} in Formula (AY-1).

In R^{c11}, R^{c12}, and R^{c2}, the heteroaryl group is not particularly limited, but may be the same as the above-described heteroaryl group in R^{a11}, R^{a12}, and R^{a2} in Formula (AY-1), and preferred examples thereof are also the same as those of the above-described heteroaryl group in R^{a11}, R^{a12}, and R^{a2} in Formula (AY-1).

In a preferred example, R^{c12} and R^{c2} may each independently be an alkyl group.

In another preferred example, R^{c11} may be a hydrogen atom, and R^{c12} and R^{c2} may each independently be an alkyl group.

The resin produced by a method for producing a resin according to the present invention can be, after completion of the reaction, isolated and purified by standard procedures.

### (A) Resin

The resin produced by a method for producing a resin according to the present invention (hereafter, also referred to as Resin (A)) has a repeating unit that is decomposed by irradiation with an actinic ray or a radiation to generate acid (hereafter, also referred to as Repeating unit (a1)).

The resin is a compound that generates acid by exposure.

Repeating unit (a1) above is typically a repeating unit represented by the following General formula (P-11).

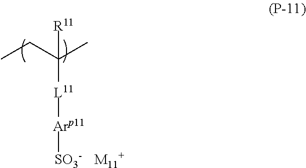

In General formula (P-11),

R¹¹ represents a hydrogen atom, an alkyl group, an aryl group, or a halogen atom;

L¹¹ represents a single bond or a divalent linking group;

Ar^{p11} represents an aromatic ring group or an aromatic heterocyclic group; and

M₁₁⁺ represents an organic cation.

In R¹¹, the alkyl group is not particularly limited, but may be a linear or branched alkyl group having 1 to 12 carbon atoms, and is preferably an alkyl group having 1 to 6 carbon atoms, more preferably an alkyl group having 1 to 3 carbon atoms.

The aryl group is not particularly limited, but is preferably an aryl group having 6 to 14 carbon atoms; examples include a phenyl group, a naphthyl group, and an anthryl group.

The halogen atom may be, for example, a fluorine atom, a chlorine atom, a bromine atom, or an iodine atom, and is preferably a fluorine atom or an iodine atom.

The alkyl group and the aryl group may have a substituent. The substituent is not particularly limited, but may be, for example, the above-described Substituent T.

R¹¹ is preferably a hydrogen atom.

In L¹¹, the divalent linking group is not particularly limited, but may be an alkylene group, a cycloalkylene group, an aromatic ring group, an aromatic heterocyclic group, —C(═O)—, —O—, or a divalent linking group formed by combining a plurality of the foregoing.

The alkylene group is not particularly limited, but may be linear or branched, and 1s preferably an alkylene group having 1 to 20 carbon atoms, more preferably an alkylene group having 1 to 10 carbon atoms, still more preferably an alkylene group having 1 to 3 carbon atoms. The cycloalkylene group is not particularly limited, but is preferably a cycloalkylene group having 3 to 20 carbon atoms, more preferably an cycloalkylene group having 3 to 10 carbon atoms, still more preferably a cycloalkylene group having 1 to 6 carbon atoms.

The aromatic ring group is not particularly limited, may be monocyclic or polycyclic, and is preferably an aromatic ring group having 6 to 20 carbon atoms, more preferably an aromatic ring group having 6 to 14 carbon atoms, still more preferably an aromatic ring group having 6 to 10 carbon atoms.

The aromatic heterocyclic group is not particularly limited, and may be monocyclic or polycyclic. The aromatic heterocycle forming the aromatic heterocyclic group is not particularly limited; examples include thiophene, furan, pyrrole, benzothiophene, benzofuran, benzopyrrole, triazine, imidazole, benzoimidazole, triazole, thiadiazole, and thiazole.

The alkylene group, the cycloalkylene group, the aromatic ring group, and the aromatic heterocyclic group may have a substituent. The substituent is not particularly limited, but may be, for example, the above-described Substituent T.

In a preferred example, L¹¹ is preferably a single bond.

In Ar^{p11}, the aromatic ring group is not particularly limited, may be monocyclic or polycyclic, and is preferably an aromatic ring group having 6 to 20 carbon atoms, more preferably an aromatic ring group having 6 to 14 carbon atoms, still more preferably an aromatic ring group having 6 to 10 carbon atoms.

The aromatic heterocyclic group is not particularly limited, and may be monocyclic or polycyclic. The aromatic heterocycle forming the aromatic heterocyclic group is not particularly limited; examples include thiophene, furan, pyrrole, benzothiophene, benzofuran, benzopyrrole, triazine, imidazole, benzoimidazole, triazole, thiadiazole, and thiazole.

The aromatic ring group and the aromatic heterocyclic group may have a substituent. The substituent is not particularly limited, but may be, for example, the above-described Substituent T.

In M₁₁⁺, the organic cation is not particularly limited, but is preferably a cation represented by Formula (ZaI) above (hereafter, also referred to as “Cation (ZaI)”), or a cation represented by Formula (ZaII) above (hereafter, also referred to as “Cation (ZaII)”).

In the above-described resin, such Repeating units (a1) may be used alone or in combination of two or more thereof.

In the above-described resin, the content of Repeating unit (a1) with respect to all the repeating units of the resin is preferably 0.5 to 30 mol %, more preferably 1 to 20 mol %, still more preferably 2 to 15 mol %.

When the above-described resin is used for a method for producing an actinic ray-sensitive or radiation-sensitive resin composition containing the resin, the method including the above-described method for producing a resin (hereafter, also referred to as “method for producing a composition according to the present invention”), Resin (A) is typically an acid decomposable resin, ordinarily includes a group that is decomposed due to the action of acid to have increased polarity (hereafter, also referred to as “acid decomposable group”), and preferably includes a repeating unit having an acid decomposable group.

Thus, in a pattern forming method according to the present invention, typically, in a case of employing a developer that is an alkali developer, a positive-type pattern is suitably formed or, in another case of employing a developer that is an organic-based developer, a negative-type pattern is suitably formed.

The repeating unit having an acid decomposable group is preferably, in addition to (repeating unit having an acid decomposable group) described later, (repeating unit having an acid decomposable group including an unsaturated bond).

Repeating unit (a2) having acid decomposable group

Resin (A) above may further have a repeating unit having an acid decomposable group (also referred to as “Repeating unit (a2)”).

The acid decomposable group refers to a group that is decomposed due to the action of acid to generate a polar group. The acid decomposable group preferably has a structure in which the polar group is protected with a group that leaves due to the action of acid. Thus, Resin (A) has a repeating unit having a group that is decomposed due to the action of acid to generate a polar group. The resin having the repeating unit is subjected to the action of acid to have increased polarity to have increased solubility in the alkali developer, but have decreased solubility in organic solvents.

The polar group is preferably an alkali soluble group; examples include acidic groups (typically, groups that dissociate in a 2.38 mass % aqueous solution of tetramethylammonium hydroxide) such as a carboxyl group, a phenolic hydroxy group, fluorinated alcohol groups, a sulfonic group, a phosphate group, a sulfonamide group, a sulfonylimide group, (alkylsulfonyl)(alkylcarbonyl)methylene groups, (alkylsulfonyl)(alkylcarbonyl)imide groups, bis(alkylcarbonyl)methylene groups, bis(alkylcarbonyl)imide groups, bis(alkylsulfonyl)methylene groups, bis(alkylsulfonyl)imide groups, tris(alkylcarbonyl)methylene groups, and tris(alkylsulfonyl)methylene groups, and an alcoholic hydroxy group.

Note that the alcoholic hydroxy group refers to a hydroxy group that is bonded to a hydrocarbon group, that is a hydroxy group other than hydroxy groups directly bonded to aromatic rings (phenolic hydroxy groups), and that is not hydroxy groups in aliphatic alcohols substituted with, at the α positions, electron-withdrawing groups such as fluorine atoms (for example, a hexafluoroisopropanol group). The alcoholic hydroxy group is preferably a hydroxy group having a pKa (acid dissociation constant) of 12 or more and 20 or less.

In particular, the polar group is preferably a carboxyl group, a phenolic hydroxy group, a fluorinated alcohol group (preferably a hexafluoroisopropanol group), or a sulfonic group.

Examples of the group that leaves due to the action of acid (leaving group) include groups represented by Formulas (Y1) to (Y5).

—C(Rx₁)(Rx₂)(Rx₃) Formula (Y1):

—C(═O)OC(Rx₁)(Rx₂)(Rx₃) Formula (Y2):

—C(R₃₆)(R₃₇)(OR₃₈) Formula (Y3):

—C(Rn)(H)(Ar) Formula (Y4):

—C(═O)R₅₁ Formula (Y5):

In Formula (Y1) and Formula (Y2), Rx₁ to Rx₃ each independently represent an alkyl group (linear or branched), a cycloalkyl group (monocyclic or polycyclic), an alkenyl group (linear or branched), an aryl group (monocyclic or polycyclic), or a heteroaryl group (monocyclic or polycyclic). Note that, when Rx₁ to Rx₃ are all alkyl groups (linear or branched), at least two of Rx₁ to Rx₃ are preferably methyl groups.

In particular, Rx₁ to Rx₃ preferably each independently represent a linear or branched alkyl group, and Rx₁ to Rx₃ more preferably each independently represent a linear alkyl group.

Two of Rx₁ to Rx₃ may be linked together to form a monocycle or a polycycle.

In Rx₁ to Rx₃, the alkyl group is not particularly limited, but may be, for example, an alkyl group having 1 to 20 carbon atoms, and is preferably an alkyl group having 1 to 5 carbon atoms such as a methyl group, an ethyl group, an n-propyl group, an isopropyl group, an n-butyl group, an isobutyl group, or a t-butyl group.

In Rx₁ to Rx₃, the cycloalkyl group is not particularly limited, but may be, for example, a cycloalkyl group having 3 to 20 carbon atoms, and is preferably a monocyclic cycloalkyl group such as a cyclopentyl group or a cyclohexyl group or a polycyclic cycloalkyl group such as a norbornyl group, a tetracyclodecanyl group, a tetracyclododecanyl group, or an adamantyl group.

In Rx₁ to Rx₃, the aryl group is not particularly limited, but may be, for example, an aryl group having 6 to 20 carbon atoms, and is preferably an aryl group having 6 to 10 carbon atoms, for example, a phenyl group, a naphthyl group, or an anthryl group.

In Rx₁ to Rx₃, the heteroaryl group is not particularly limited, and may be monocyclic or polycyclic. The aromatic heterocycle forming the heteroaryl group is not particularly limited; examples include thiophene, furan, pyrrole, benzothiophene, benzofuran, benzopyrrole, triazine, imidazole, benzoimidazole, triazole, thiadiazole, and thiazole.

In Rx₁ to Rx₃, the alkenyl group is not particularly limited, but is preferably a vinyl group.

The ring formed by linking together two of Rx₁ to Rx₃ is preferably a cycloalkyl group. The cycloalkyl group formed by linking together two of Rx₁ to Rx₃ is preferably a monocyclic cycloalkyl group such as a cyclopentyl group or a cyclohexyl group, or a polycyclic cycloalkyl group such as a norbornyl group, tetracyclodecanyl group, a tetracyclododecanyl group, or an adamantyl group, more preferably a monocyclic cycloalkyl group having 5 to 6 carbon atoms.

In the cycloalkyl group formed by linking together two of Rx₁ to Rx₃, one of methylene groups forming the ring may be replaced by a heteroatom such as an oxygen atom, a group including a heteroatom such as a carbonyl group, or a vinylidene group. In the cycloalkyl group, one or more of the ethylene groups forming the cycloalkane ring may be replaced by vinylene groups.

The group represented by Formula (Y1) or Formula (Y2) preferably has a form in which, for example, Rx₁ is a methyl group or an ethyl group, and Rx₂ and Rx₃ are linked together to form the above-described cycloalkyl group.

In a method for producing a composition according to the present invention, when the composition 1s, for example, an EUV-exposure actinic ray-sensitive or radiation-sensitive resin composition, the alkyl groups, the cycloalkyl groups, the alkenyl groups, and the aryl groups represented by Rx₁ to Rx₃, and the ring formed by linking together two of Rx₁ to Rx₃ also preferably further have, as a substituent, a fluorine atom or an iodine atom.

In Formula (Y3), R₃₆ to R₃₈ each independently represent a hydrogen atom or a monovalent organic group. R₃₇ and R₃₈ may be linked together to form a ring. The monovalent organic group may be an alkyl group, a cycloalkyl group, an aryl group, a heteroaryl group, an aralkyl group, or an alkenyl group. R₃₆ is also preferably a hydrogen atom.

Note that the alkyl group, the cycloalkyl group, the aryl group, and the aralkyl group may include a heteroatom such as an oxygen atom and/or a group including a heteroatom such as a carbonyl group. For example, in the alkyl group, the cycloalkyl group, the aryl group, and the aralkyl group, one or more methylene groups may be replaced by a heteroatom such as an oxygen atom and/or a group including a heteroatom such as a carbonyl group.

R₃₈ and another substituent of the main chain of the repeating unit may be linked together to form a ring. The group formed by linking together R₃₈ and another substituent of the main chain of the repeating unit is preferably an alkylene group such as a methylene group.

In a method for producing a composition according to the present invention, when the composition 1s, for example, an EUV-exposure actinic ray-sensitive or radiation-sensitive resin composition, the monovalent organic groups represented by R₃₆ to R₃₈ and the ring formed by linking together R₃₇ and R₃₉ also preferably further have, as a substituent, a fluorine atom or an iodine atom.

Formula (Y3) is preferably a group represented by the following Formula (Y3-1).

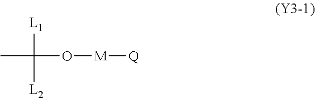

L₁ and L₂ each independently represent a hydrogen atom, an alkyl group, a cycloalkyl group, an aryl group, a heteroaryl group, or a group of a combination of the foregoing (for example, a group of a combination of an alkyl group and an aryl group).

M represents a single bond or a divalent linking group.

Q represents an alkyl group that may include a heteroatom, a cycloalkyl group that may include a heteroatom, an aryl group that may include a heteroatom, an amino group, an ammonium group, a mercapto group, a cyano group, an aldehyde group, or a group of a combination of the foregoing (for example, a group of a combination of an alkyl group and a cycloalkyl group).

In the alkyl group and the cycloalkyl group, for example, one of methylene groups may be replaced by a heteroatom such as an oxygen atom or a group including a heteroatom such as a carbonyl group.

Note that one of L₁ and L₂ is preferably a hydrogen atom and the other is preferably an alkyl group, a cycloalkyl group, an aryl group, or a group that is a combination of an alkylene group and an aryl group.

At least two of Q, M, and L₁ may be linked together to form a ring (preferably a five-membered or six-membered ring).

From the viewpoint of forming finer patterns, L₂ is preferably a secondary or tertiary alkyl group, more preferably a tertiary alkyl group. Examples of the secondary alkyl group include an isopropyl group, a cyclohexyl group, and a norbornyl group; examples of the tertiary alkyl group include a tert-butyl group and an adamantane group. In such examples, Tg (glass transition temperature) and activation energy are increased, so that film hardness is ensured and fog can be suppressed.

When, in the method for producing a composition according to the present invention, the composition 1s, for example, an EUV-exposure actinic ray-sensitive or radiation-sensitive resin composition, the alkyl group, the cycloalkyl group, the aryl group, and the group of a combination of the foregoing represented by L₁ and L₂ also preferably have, as a substituent, a fluorine atom or an iodine atom. The alkyl group, the cycloalkyl group, the aryl group, and the aralkyl group also preferably include, in addition to a fluorine atom and an iodine atom, a heteroatom such as an oxygen atom (specifically, in the alkyl group, the cycloalkyl group, the aryl group, and the aralkyl group, for example, one of methylene groups is replaced by a heteroatom such as an oxygen atom or a group including a heteroatom such as a carbonyl group).

When, in the method for producing a composition according to the present invention, the composition 1s, for example, an EUV-exposure actinic ray-sensitive or radiation-sensitive resin composition, in the alkyl group that may include a heteroatom, the cycloalkyl group that may include a heteroatom, the aryl group that may include a heteroatom, the amino group, the ammonium group, the mercapto group, the cyano group, the aldehyde group, and the group of a combination of the foregoing represented by Q, such a heteroatom is also preferably a heteroatom selected from the group consisting of a fluorine atom, an iodine atom, and an oxygen atom.

In Formula (Y4), Ar represents an aromatic ring group. Rn represents an alkyl group, a cycloalkyl group, or an aryl group. Rn and Ar may be linked together to form a non-aromatic ring. Ar is preferably an aryl group.

When, in the method for producing a composition according to the present invention, the composition 1s, for example, an EUV-exposure actinic ray-sensitive or radiation-sensitive resin composition, the aromatic ring group represented by Ar and the alkyl group, the cycloalkyl group, and the aryl group represented by Rn also preferably have, as a substituent, a fluorine atom or an iodine atom.

In Formula (Y5), R₅₁ represents an alkyl group (linear or branched), an alkoxy group (linear or branched), a cycloalkyl group (monocyclic or polycyclic), an alkenyl group (linear or branched), an aryl group (monocyclic or polycyclic), an aryloxy group, or a heteroaryl group (monocyclic or polycyclic).

The alkyl group (linear or branched), the cycloalkyl group (monocyclic or polycyclic), the alkenyl group (linear or branched), the aryl group (monocyclic or polycyclic), or the heteroaryl group (monocyclic or polycyclic) is respectively the same as and has the same preferred examples as, as Rx₁ to Rx₃ above, the alkyl group (linear or branched), the cycloalkyl group (monocyclic or polycyclic), the alkenyl group (linear or branched), the aryl group (monocyclic or polycyclic), or the heteroaryl group (monocyclic or polycyclic).

In R₅₁, the alkoxy group is not particularly limited, but may be a linear or branched alkoxy group having 1 to 20 carbon atoms, and is preferably an alkoxy group having 1 to 12 carbon atoms, more preferably an alkoxy group having 1 to 6 carbon atoms.

In R₅₁, in the aryloxy group, the aryl group is not particularly limited, but is preferably an aryl group having 6 to 20 carbon atoms; examples include a phenyl group, a naphthyl group, and an anthryl group.

From the viewpoint of providing a repeating unit having high acid decomposability, in the leaving group protecting the polar group, when a non-aromatic ring is directly bonded to the polar group (or its residue), in the non-aromatic ring, a ring-member atom adjacent to a ring-member atom directly bonded to the polar group (or its residue) also preferably does not have, as a substituent, a halogen atom such as a fluorine atom.

Alternatively, the group that leaves due to the action of acid may be a 2-cyclopentenyl group having a substituent (such as an alkyl group) such as 3-methyl-2-cyclopentenyl group, or a cyclohexyl group having a substituent (such as an alkyl group) such as a 1,1,4,4-tetramethylcyclohexyl group.

The repeating unit having an acid decomposable group is also preferably a repeating unit represented by Formula (A).

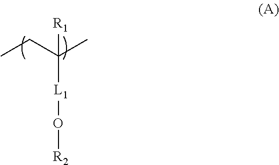

L₁ represents a divalent linking group that may have a fluorine atom or an iodine atom; R₁ represents a hydrogen atom, a fluorine atom, an iodine atom, or an alkyl group that may have a fluorine atom or an iodine atom, or an aryl group that may have a fluorine atom or an iodine atom; R₂ represents a group that leaves due to the action of acid and that may have a fluorine atom or an iodine atom. Note that at least one of L₁, R₁, or R₂ has a fluorine atom or an iodine atom.

Lₜ represents a divalent linking group that may have a fluorine atom or an iodine atom. Examples of the divalent linking group that may have a fluorine atom or an iodine atom include —CO—, —O—, —S—, —SO—, —SO₂—, hydrocarbon groups that may have a fluorine atom or an iodine atom (for example, alkylene groups, cycloalkylene groups, alkenylene groups, aromatic ring groups, and aromatic heterocyclic groups), and linking groups provided by linking together a plurality of the foregoing. In particular, L₁ is preferably —CO—, an aromatic ring group, or an—aromatic ring group-alkylene group having a fluorine atom or an iodine atom-, more preferably —CO— or an—aromatic ring group-alkylene group having a fluorine atom or an iodine atom-.

The aromatic ring group is not particularly limited, but is preferably a phenylene group.

The alkylene group may be linear or branched. The number of carbon atoms of the alkylene group is not particularly limited, but is preferably 1 to 10, more preferably 1 to 3.

In the alkylene group having a fluorine atom or an iodine atom, the total number of fluorine atoms and iodine atoms is not particularly limited, but is preferably 2 or more, more preferably 2 to 10, still more preferably 3 to 6.

R₁ represents a hydrogen atom, a fluorine atom, an iodine atom, an alkyl group that may have a fluorine atom or an iodine atom, or an aryl group that may have a fluorine atom or an iodine atom.

The alkyl group may be linear or branched. The number of carbon atoms of the alkyl group is not particularly limited, but is preferably 1 to 10, more preferably 1 to 3.

In the alkyl group having a fluorine atom or an iodine atom, the total number of fluorine atoms and iodine atoms is not particularly limited, but is preferably 1 or more, more preferably 1 to 5, still more preferably 1 to 3.

The alkyl group may include a heteroatom other than halogen atoms, such as an oxygen atom.

The aryl group is not particularly limited, but is preferably an aryl group having 6 to 14 carbon atoms; examples include a phenyl group, a naphthyl group, and an anthryl group.

The aryl group may include a heteroatom other than halogen atoms, such as an oxygen atom.

R₂ represents a leaving group that leaves due to the action of acid and that may have a fluorine atom or an iodine atom. Examples of the leaving group that may have a fluorine atom or an iodine atom include groups that are represented by Formulas (Y1) to (Y5) above and that may have a fluorine atom or an iodine atom.

The repeating unit having an acid decomposable group is also preferably a repeating unit represented by Formula (AI).

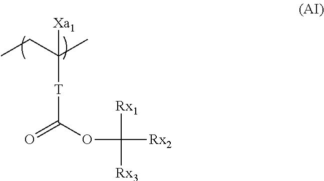

In Formula (A), Xa₁ represents a hydrogen atom or an alkyl group that may have a substituent. T represents a single bond or a divalent linking group. Rx₁ to Rx₃ each independently represent an alkyl group (linear or branched), a cycloalkyl group (monocyclic or polycyclic), an alkenyl group (linear or branched), or an aryl (monocyclic or polycyclic) group. Note that, when Rx₁ to Rx; are all alkyl groups (linear or branched), at least two of Rx₁ to Rx; are preferably methyl groups.

Two of Rx₁ to Rx₃ may be linked together to form a monocycle or polycycle (such as a monocyclic or polycyclic cycloalkyl group).

In Xa₁, the alkyl group that may have a substituent may be, for example, a methyl group or a group represented by —CH₂—R₁₁. R₁₁ represents a halogen atom (such as a fluorine atom), a hydroxy group, or a monovalent organic group such as an alkyl group that has 5 or less carbon atoms and that may be substituted with a halogen atom, an acyl group that has 5 or less carbon atoms and that may be substituted with a halogen atom, or an alkoxy group that has 5 or less carbon atoms and that may be substituted with a halogen atom, and is preferably an alkyl group having 3 or less carbon atoms, more preferably a methyl group. Xa₁ is preferably a hydrogen atom, a methyl group, a trifluoromethyl group, or a hydroxymethyl group.

In T, the divalent linking group may be an alkylene group, an aromatic ring group, a —COO-Rt- group, or an —O-Rt- group. In the formulas, Rt represent an alkylene group or a cycloalkylene group.

T is preferably a single bond or a —COO-Rt- group. When T represents a —COO-Rt- group, Rt is preferably an alkylene group having 1 to 5 carbon atoms, more preferably a —CH₂— group, a —(CH₂)₂— group, or a —(CH₂)₃— group.

In Rx₁ to Rx₃, the alkyl group is preferably an alkyl group having 1 to 4 carbon atoms such as a methyl group, an ethyl group, an n-propyl group, an isopropyl group, an n-butyl group, an isobutyl group, or a t-butyl group.

In Rx₁ to Rx₃, the cycloalkyl group is preferably a monocyclic cycloalkyl group such as a cyclopentyl group or a cyclohexyl group, or a polycyclic cycloalkyl group such as a norbornyl group, a tetracyclodecanyl group, a tetracyclododecanyl group, or an adamantyl group.

In Rx₁ to Rx₃, the aryl group is preferably an aryl group having 6 to 10 carbon atoms, for example, a phenyl group, a naphthyl group, or an anthryl group.

In Rx₁ to Rx₃, the alkenyl group is preferably a vinyl group.

The cycloalkyl group formed by linking together two of Rx₁ to Rx₃ is preferably a monocyclic cycloalkyl group such as a cyclopentyl group or a cyclohexyl group, or preferably a polycyclic cycloalkyl group such as a norbornyl group, a tetracyclodecanyl group, a tetracyclododecanyl group, or an adamantyl group. In particular, preferred is a monocyclic cycloalkyl group having 5 to 6 carbon atoms.

In the cycloalkyl group formed by linking together two of Rx₁ to Rx₃, for example, one of methylene groups forming the ring may be replaced by a heteroatom such as an oxygen atom, a group including a heteroatom such as a carbonyl group, or a vinylidene group. In the cycloalkyl group, one or more of the ethylene groups forming the cycloalkane ring may be replaced by vinylene groups.

The repeating unit represented by Formula (AI) preferably has a form in which, for example, Rx₁ is a methyl group or an ethyl group, and Rx₂ and Rx₃ are linked together to form the cycloalkyl group.

When the above-described groups each have a substituent, examples of the substituent include alkyl groups (having 1 to 4 carbon atoms), halogen atoms, a hydroxy group, alkoxy groups (having 1 to 4 carbon atoms), a carboxyl group, and alkoxycarbonyl groups (having 2 to 6 carbon atoms). The substituent preferably has 8 or less carbon atoms.

The repeating unit represented by Formula (AI) is preferably an acid-decomposable (meth)acrylic acid tertiary alkyl ester-based repeating unit (repeating unit where Xa₁ represents a hydrogen atom or a methyl group and T represents a single bond).

The following are specific examples of the repeating unit having an acid decomposable group; however, the present invention is not limited to these. Note that, in the formulas, Xa₁ represent H, CH₃, CF₃, or CH₂OH, and Rxa and Rxb each independently represent a linear or branched alkyl group having 1 to 5 carbon atoms.

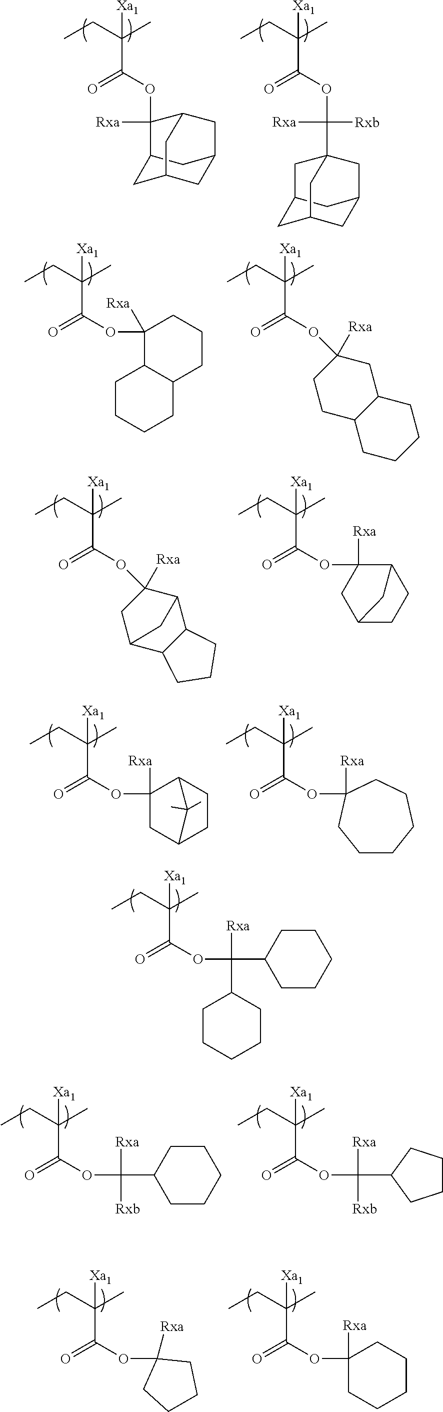

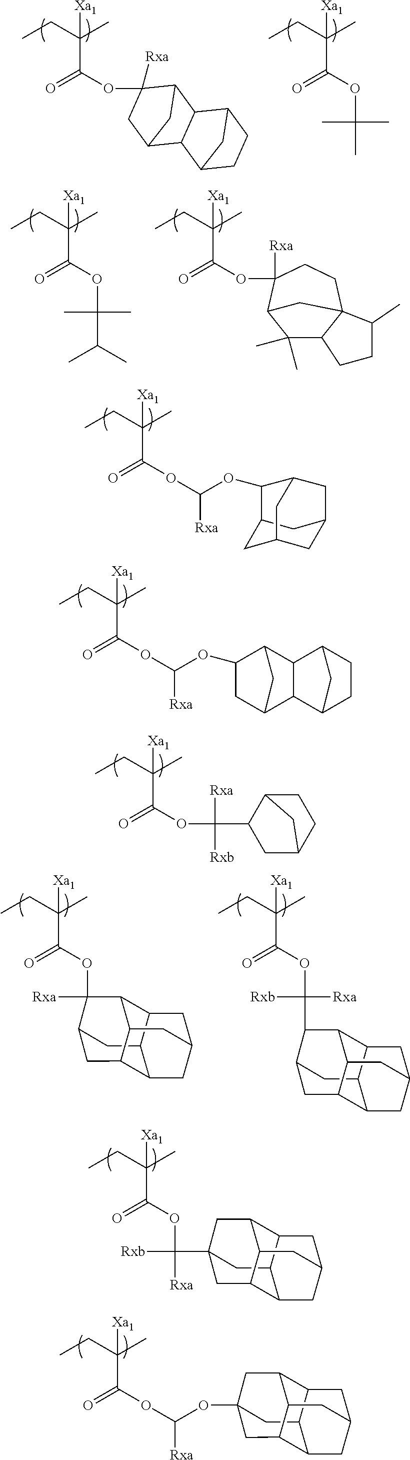

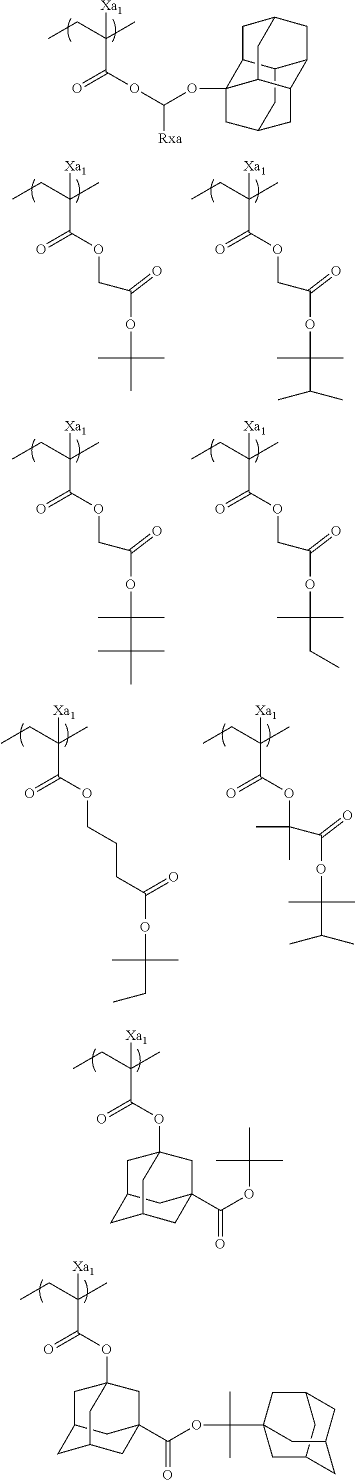

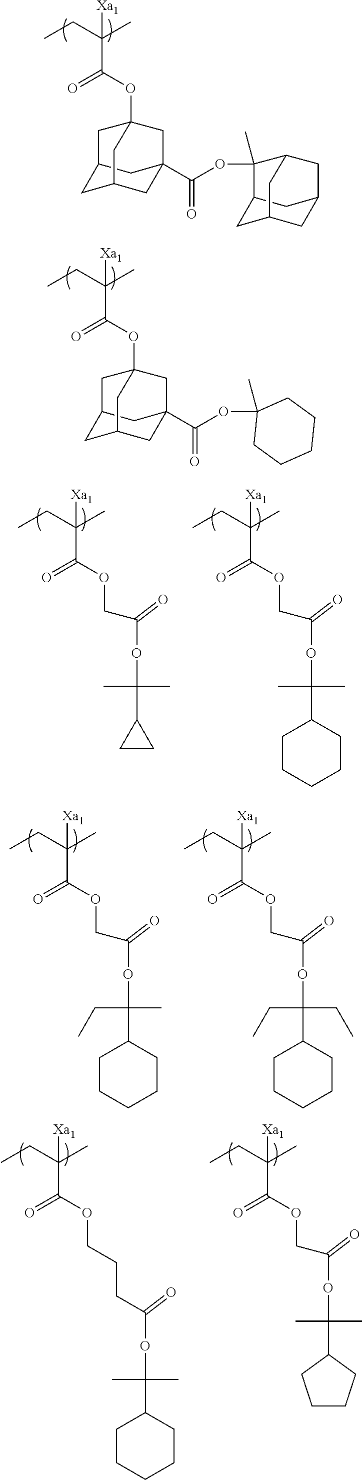

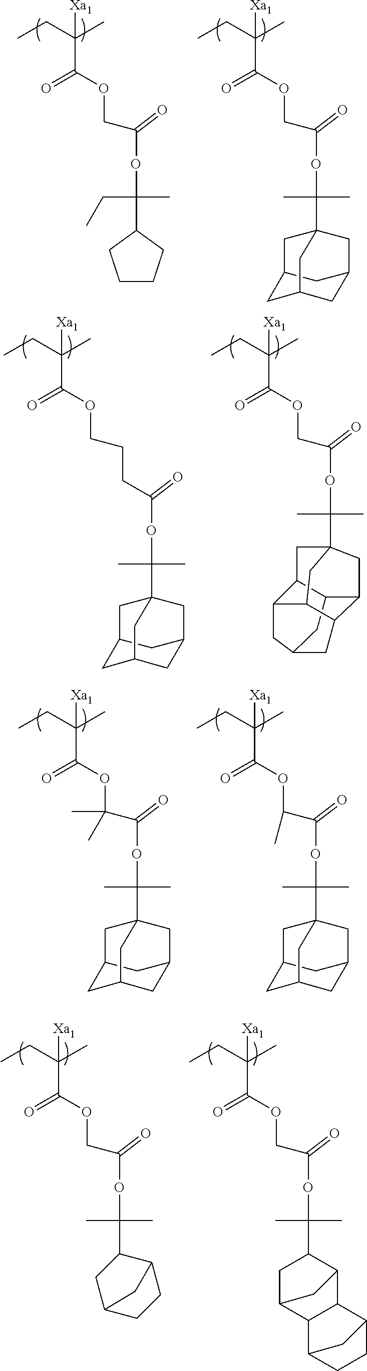

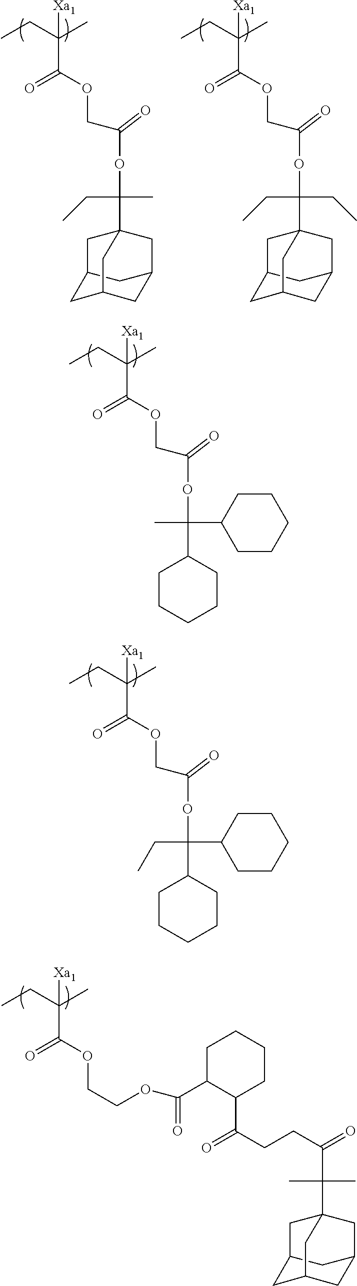

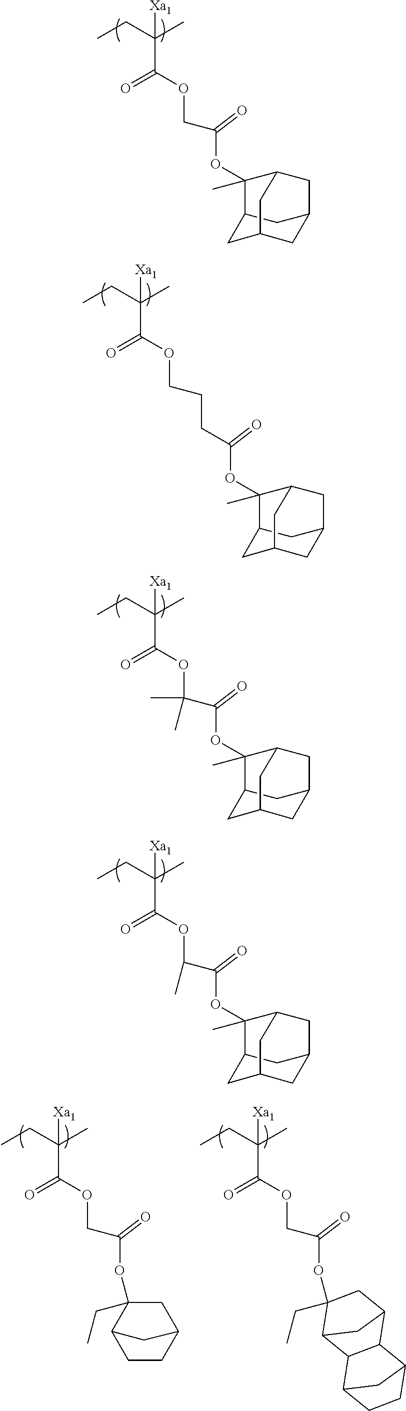

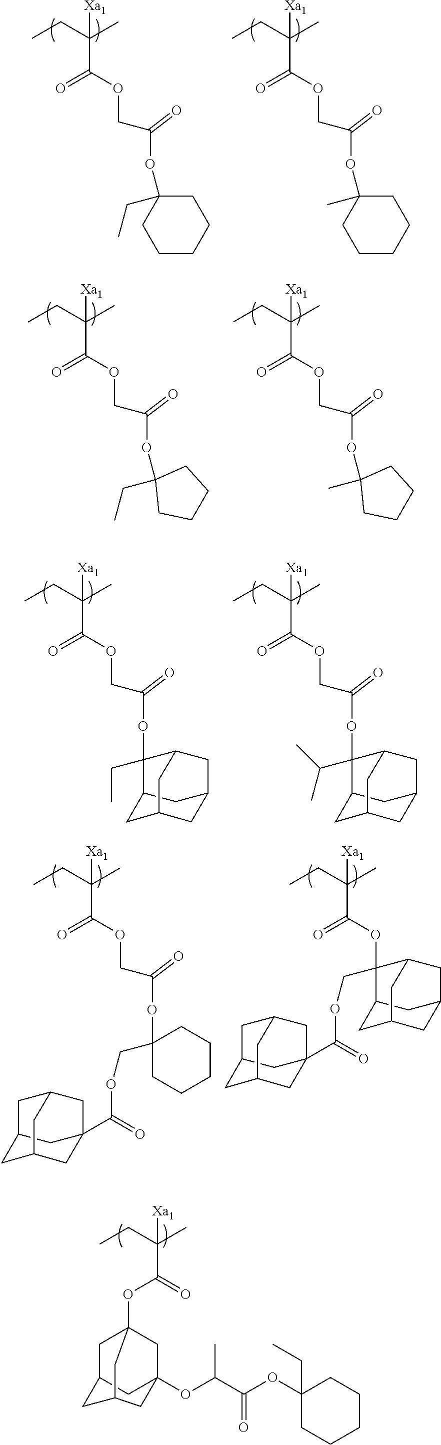

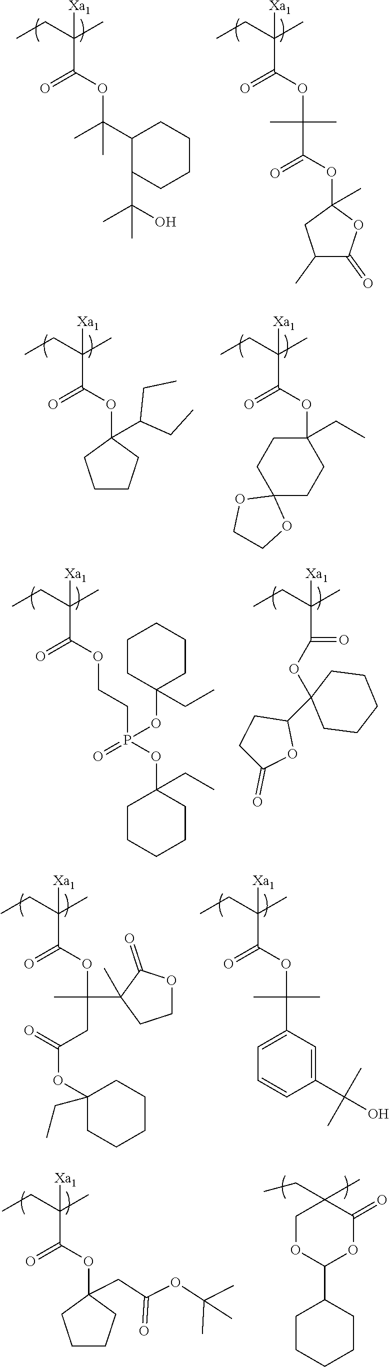

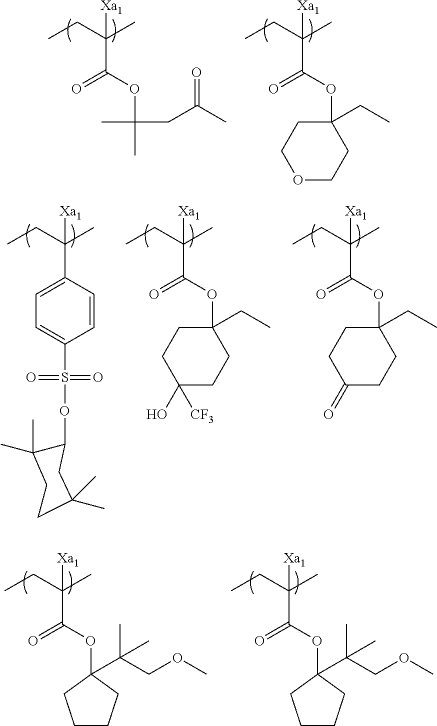

Resin (A) may have, as a repeating unit having an acid decomposable group, a repeating unit having an acid decomposable group including an unsaturated bond.

The repeating unit having an acid decomposable group including an unsaturated bond is preferably a repeating unit represented by Formula (B).

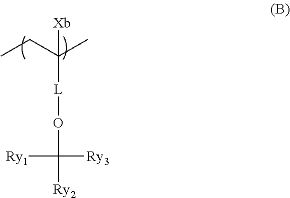

In Formula (B), Xb represents a hydrogen atom, a halogen atom, or an alkyl group that may have a substituent. L represents a single bond or a divalent linking group that may have a substituent. Ry₁ to Ry₃ each independently represent a linear or branched alkyl group, a monocyclic or polycyclic cycloalkyl group, an alkenyl group, an alkynyl group, or a monocyclic or polycyclic aryl group. Note that at least one of Ry₁ to Ry₃ represents an alkenyl group, an alkynyl group, a monocyclic or polycyclic cycloalkenyl group, or a monocyclic or polycyclic aryl group.

Two of Ry₁ to Ry₃ may be linked together to form a monocycle or polycycle (such as a monocyclic or polycyclic cycloalkyl group or cycloalkenyl group).

In Xb, the alkyl group that may have a substituent may be, for example, a methyl group or a group represented by —CH₂—R₁₁. R₁₁ represents a halogen atom (such as a fluorine atom), a hydroxy group, or a monovalent organic group such as an alkyl group that has 5 or less carbon atoms and that may be substituted with a halogen atom, an acyl group that has 5 or less carbon atoms and that may be substituted with a halogen atom, or an alkoxy group that has 5 or less carbon atoms and that may be substituted with a halogen atom, and is preferably an alkyl group having 3 or less carbon atoms, more preferably a methyl group. Xb is preferably a hydrogen atom, a fluorine atom, a methyl group, a trifluoromethyl group, or a hydroxymethyl group.

In L, the divalent linking group may be an -Rt- group, a —CO— group, a —COO-Rt- group, a —COO-Rt-CO— group, an -Rt-CO— group, or an —O-Rt- group. In the formulas, Rt represent an alkylene group, a cycloalkylene group, or an aromatic ring group, and is preferably an aromatic ring group.

L is preferably an -Rt- group, a —CO— group, a —COO-Rt-CO— group, or an -Rt-CO— group. Rt may have a substituent such as a halogen atom, a hydroxy group, or an alkoxy group. Rt is preferably an aromatic ring group.

In Ry₁ to Ry₃, the alkyl group is preferably an alkyl group having 1 to 4 carbon atoms such as a methyl group, an ethyl group, an n-propyl group, an isopropyl group, an n-butyl group, an isobutyl group, or a t-butyl group.

In Ry₁ to Ry₃, the cycloalkyl group is preferably a monocyclic cycloalkyl group such as a cyclopentyl group or a cyclohexyl group, or a polycyclic cycloalkyl group such as a norbornyl group, a tetracyclodecanyl group, a tetracyclododecanyl group, or an adamantyl group.

In Ry₁ to Ry₃, the aryl group is preferably an aryl group having 6 to 10 carbon atoms, and may be, for example, a phenyl group, a naphthyl group, or an anthryl group.

In Ry₁ to Ry₃, the alkenyl group is preferably a vinyl group.

In Ry₁ to Ry₃, the alkynyl group is preferably an ethynyl group.

In Ry₁ to Ry₃, the cycloalkenyl group is preferably a structure in which a monocyclic cycloalkyl group such as a cyclopentyl group or a cyclohexyl group includes partially a double bond.

The cycloalkyl group formed by linking together two of Ry₁ to Ry₃ is preferably a monocyclic cycloalkyl group such as a cyclopentyl group or a cyclohexyl group, or a polycyclic cycloalkyl group such as a norbornyl group, a tetracyclodecanyl group, a tetracyclododecanyl group, or an adamantyl group. In particular, more preferred is a monocyclic cycloalkyl group having 5 to 6 carbon atoms.

In the cycloalkyl group or the cycloalkenyl group formed by linking together two of Ry₁ to Ry₃, for example, one of methylene groups forming the ring may be replaced by a heteroatom such as an oxygen atom, a group including a heteroatom such as a carbonyl group, a —SO₂— group, or a —SO₃— group, a vinylidene group, or a combination of the foregoing. In the cycloalkyl group or the cycloalkenyl group, one or more ethylene groups forming the cycloalkane ring or the cycloalkene ring may be replaced by vinylene groups.

The repeating unit represented by Formula (B) preferably has a form in which, for example, Ry₁ is a methyl group, an ethyl group, a vinyl group, an allyl group, or an aryl group, and Ry₂ and Ry₃ are linked together to form the above-described cycloalkyl group or cycloalkenyl group.

When these groups each have a substituent, examples of the substituent include alkyl groups (having 1 to 4 carbon atoms), halogen atoms, a hydroxy group, alkoxy groups (having 1 to 4 carbon atoms), a carboxyl group, and alkoxycarbonyl groups (having 2 to 6 carbon atoms). The substituent preferably has 8 or less carbon atoms.

The repeating unit represented by Formula (B) is preferably an acid-decomposable (meth)acrylic acid tertiary ester-based repeating unit (a repeating unit in which Xb represents a hydrogen atom or a methyl group, and L represents a —CO— group), an acid-decomposable hydroxystyrene tertiary alkyl ether-based repeating unit (a repeating unit in which Xb represents a hydrogen atom or a methyl group, and L represents a phenyl group), or an acid-decomposable styrenecarboxylic acid tertiary ester-based repeating unit (a repeating unit in which Xb represents a hydrogen atom or a methyl group, and L represents an -Rt-CO— group (Rt is an aromatic group)).

The content of the repeating unit having an acid decomposable group including an unsaturated bond with respect to all the repeating units in Resin (A) is preferably 15 mol % or more, more preferably 20 mol % or more, still more preferably 30 mol % or more. The upper limit value with respect to all the repeating units in Resin (A) is preferably 80 mol % or less, more preferably 70 mol % or less, particularly preferably 60 mol % or less.

The following are specific examples of the repeating unit having an acid decomposable group including an unsaturated bond; however, the present invention is not limited to these. Note that, in the formulas, Xb and L₁ represent the above-described substituent or linking group; Ar represent an aromatic group; R represent a substituent such as a hydrogen atom, an alkyl group, a cycloalkyl group, an aryl group, an aralkyl group, an alkenyl group, a hydroxy group, an alkoxy group, an acyloxy group, a cyano group, a nitro group, an amino group, a halogen atom, an ester group (—OCOR′″ or —COOR′″: R′″ is an alkyl group or a fluorinated alkyl group having 1 to 20 carbon atoms), or a carboxyl group; R′ represent a linear or branched alkyl group, a monocyclic or polycyclic cycloalkyl group, an alkenyl group, an alkynyl group, or a monocyclic or polycyclic aryl group; Q represent a heteroatom such as an oxygen atom, a group including a heteroatom such as a carbonyl group, a —SO₂— group, or a —SO₃— group, a vinylidene group, or a combination of the foregoing; n and m represent an integer of 0 or more.

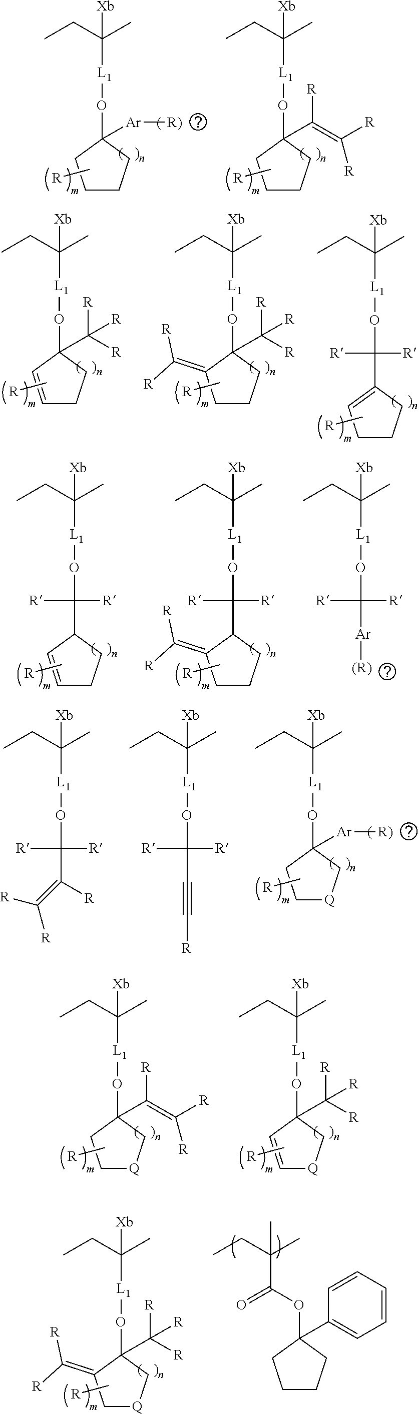

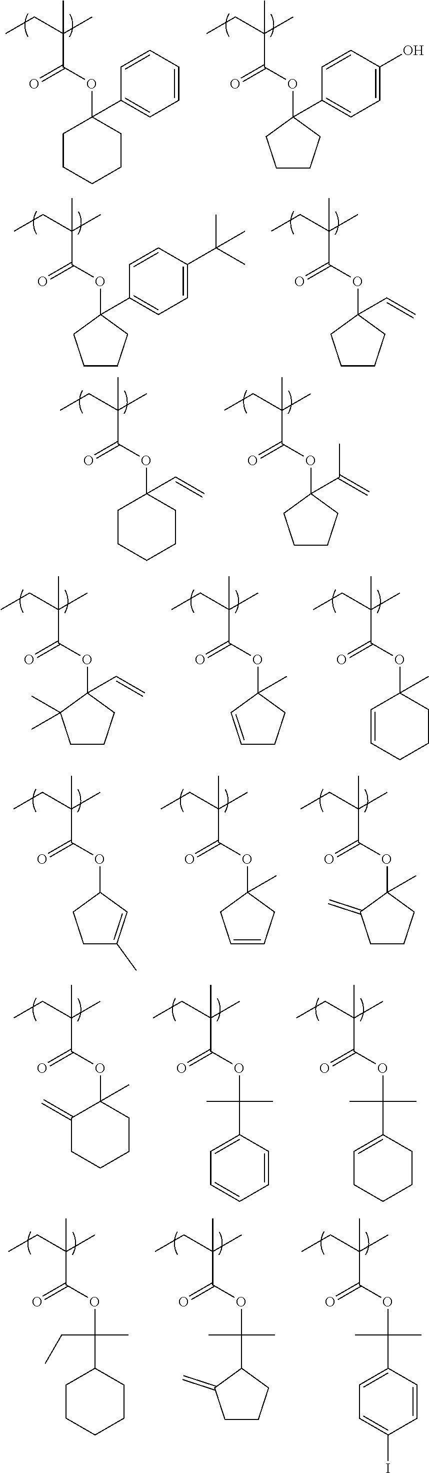

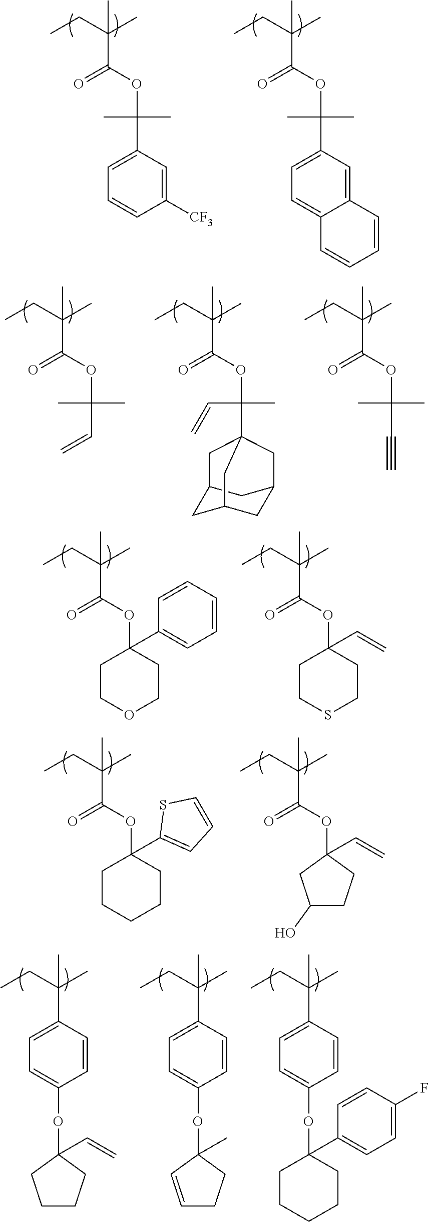

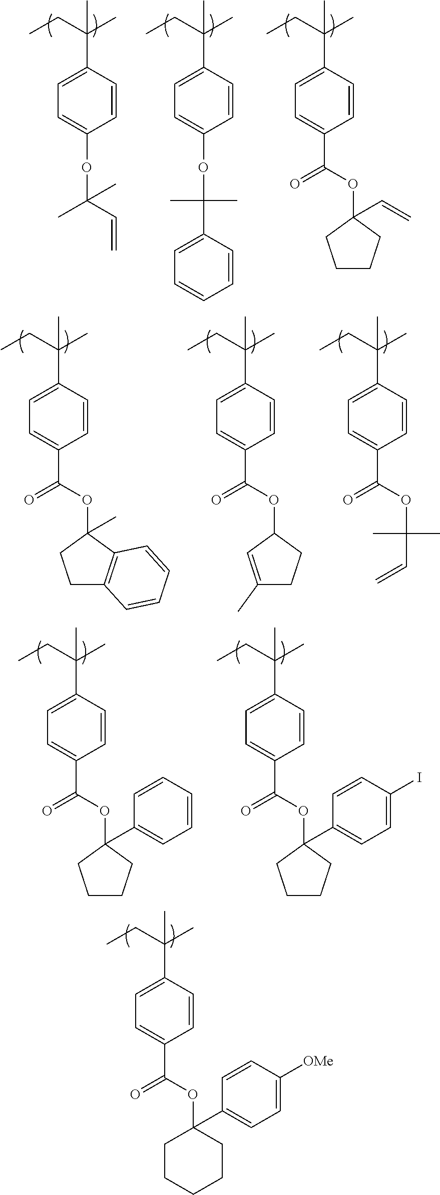

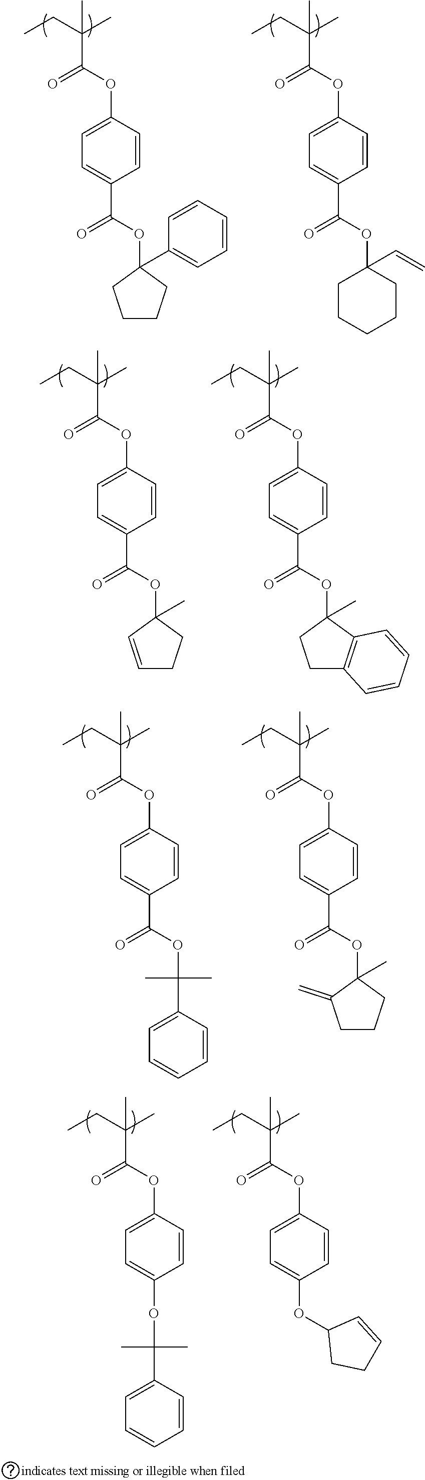

In Resin (A), such repeating units having an acid decomposable group maybe included alone or in combination of two or more thereof.

The content of the repeating unit having an acid decomposable group with respect to all the repeating units in Resin (A) is preferably 10 mol % or more, more preferably 20 mol % or more, still more preferably 30 mol % or more. The upper limit value with respect to all the repeating units in Resin (A) is preferably 90 mol % or less, more preferably 80 mol % or less, still more preferably 70 mol % or less, particularly preferably 60 mol % or less.

In a preferred example, the content of the repeating unit having an acid decomposable group with respect to all the repeating units of Resin (A) is preferably more than 20 mol %.

In Resin (A), the total content of Repeating unit (a1) and Repeating unit (a2) (in the case of a plurality of Repeating units (a1) and a plurality of Repeating units (a2), the total content thereof) with respect to all the repeating units of Resin (A) is preferably 60 mol % or more, more preferably 70 mol % or more, still more preferably 80 mol % or more.

Note that, when Resin (A) has Repeating unit (a1) and Repeating unit (a2) alone, the total content of Repeating unit (a1) and Repeating unit (a2) included in Resin (A) is 100 mol %.

### Repeating Unit (a3) Having Acid Group

Resin (A) may have a repeating unit having an acid group (also referred to as “Repeating unit (a3)”).

The acid group is preferably an acid group having a pKa of 13 or less. The acid group preferably has an acid dissociation constant of 13 or less, more preferably 3 to 13, still more preferably 5 to 10.

When Resin (A) has an acid group having a pKa of 13 or less, the content of the acid group in Resin (A) is not particularly limited, but is often 0.2 to 6.0 mmol/g, in particular, preferably 0.8 to 6.0 mmol/g, more preferably 1.2 to 5.0 mmol/g, still more preferably 1.6 to 4.0 mmol/g. When the content of the acid group is within such a range, development suitably proceeds to form a pattern having a good profile at high resolution.

The acid group is preferably, for example, a carboxyl group, a phenolic hydroxy group, a fluoroalcohol group (preferably a hexafluoroisopropanol group), a sulfonic group, a sulfonamide group, or an isopropanol group.

In the hexafluoroisopropanol group, one or more (preferably one to two) of the fluorine atoms may be substituted with groups other than fluorine atoms (such as alkoxycarbonyl groups). The acid group is also preferably —C(CF₃)(OH)—CF₂— formed in this manner. Alternatively, one or more of the fluorine atoms may be substituted with groups other than fluorine atoms, to form a ring including —C(CF₃)(OH)—CF₂—.

The repeating unit having an acid group is preferably a repeating unit different from the above-described repeating unit having a structure in which a polar group is protected with a leaving group that leaves due to the action of acid.

The repeating unit having an acid group may have a fluorine atom or an iodine atom.

Examples of the repeating unit having an acid group include the following repeating units.

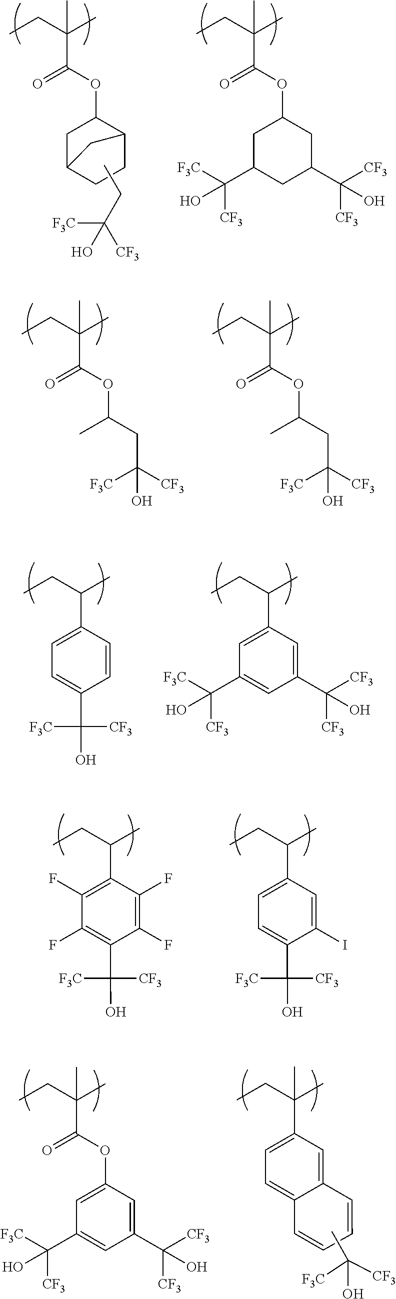

The repeating unit having an acid group is preferably a repeating unit represented by the following Formula (1).

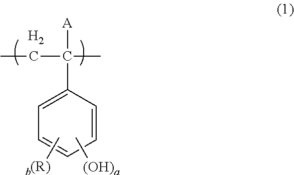

In Formula (1), A represents a hydrogen atom, an alkyl group, a cycloalkyl group, a halogen atom, or a cyano group. R represents a halogen atom, an alkyl group, a cycloalkyl group, an aryl group, an alkenyl group, an aralkyl group, an alkoxy group, an alkylcarbonyloxy group, an alkylsulfonyloxy group, an alkyloxycarbonyl group, or an aryloxycarbonyl group; when there are a plurality of A's, they may be the same or different. When Formula (1) has a plurality of R's, they may together form a ring. R is preferably a hydrogen atom. a represents an integer of 1 to 3. b represents an integer of 0 to (5-a).

The following are examples of the repeating unit having an acid group. In the formulas, a represent 1 or 2.

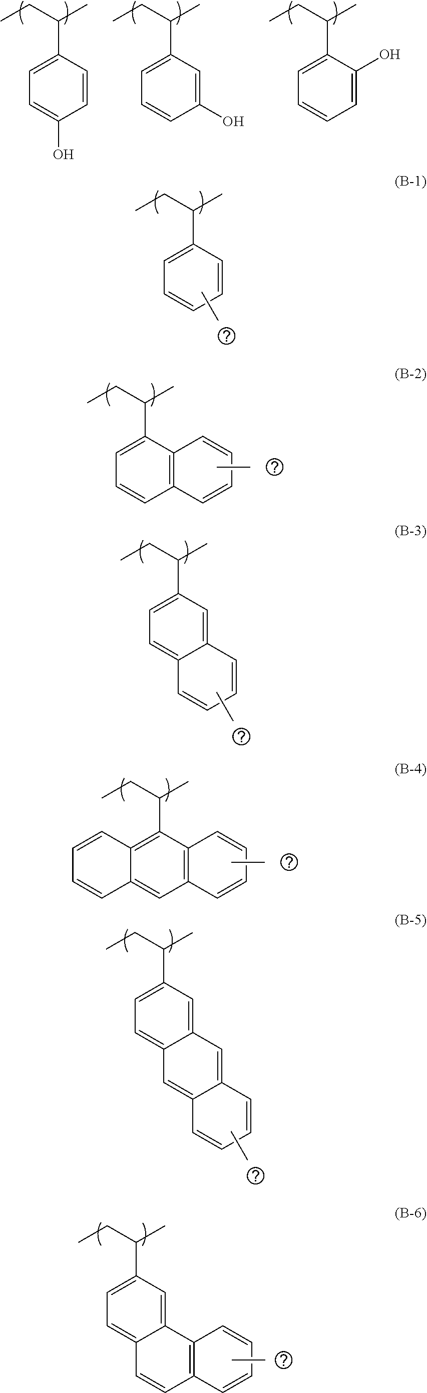

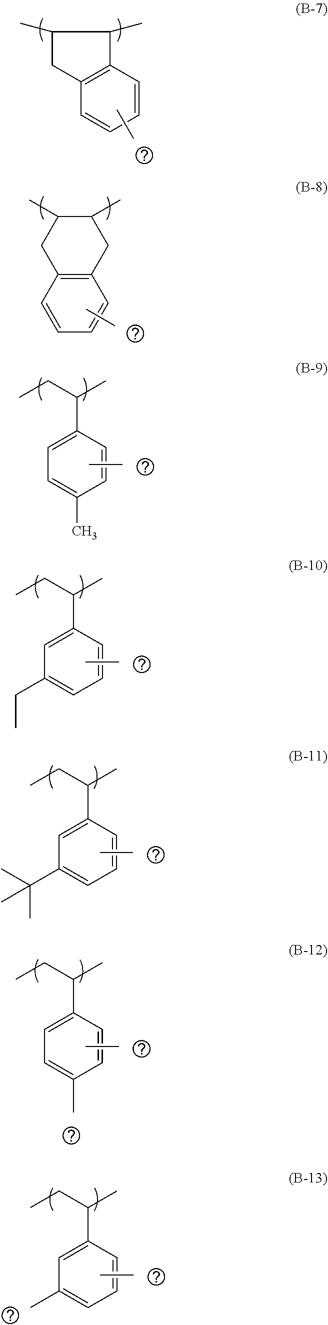

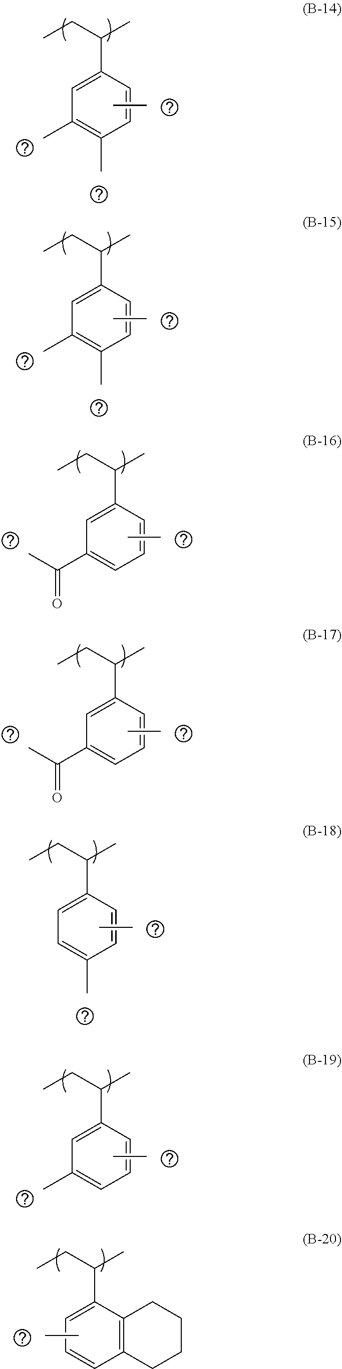

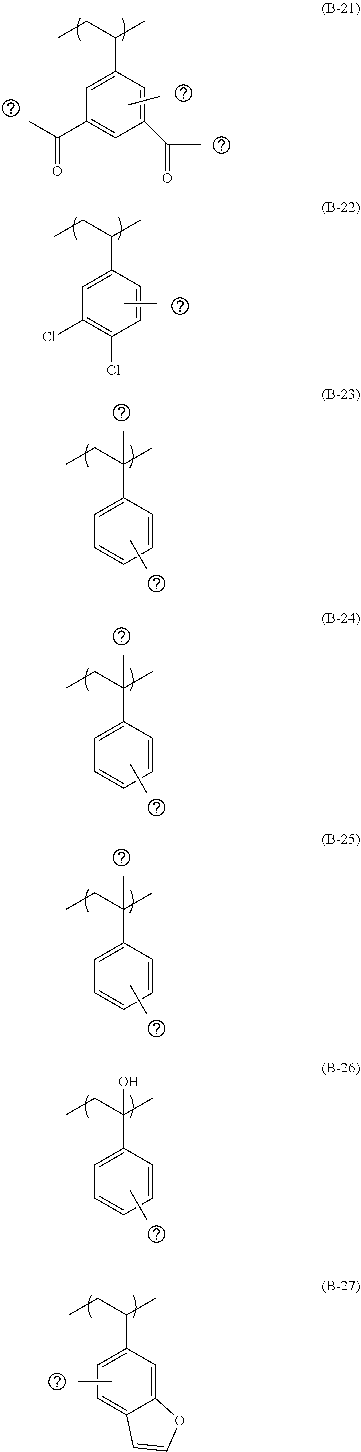

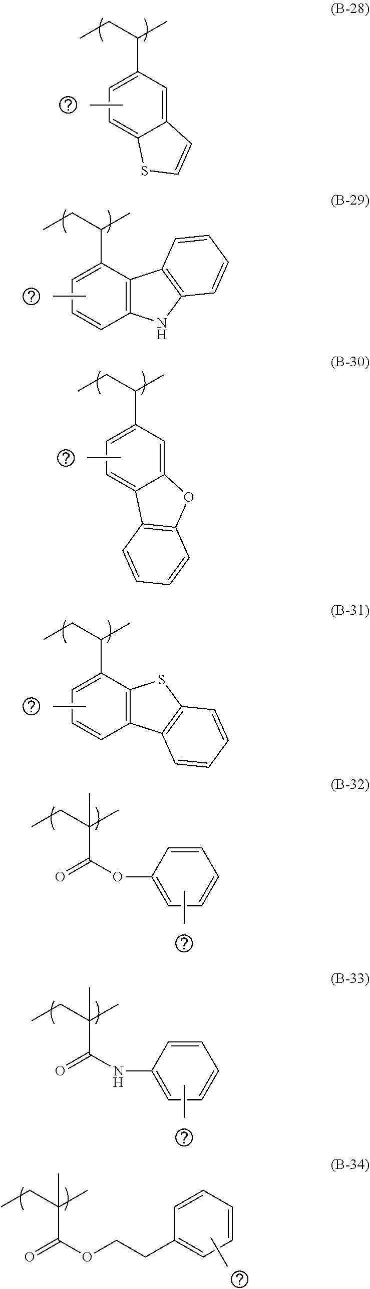

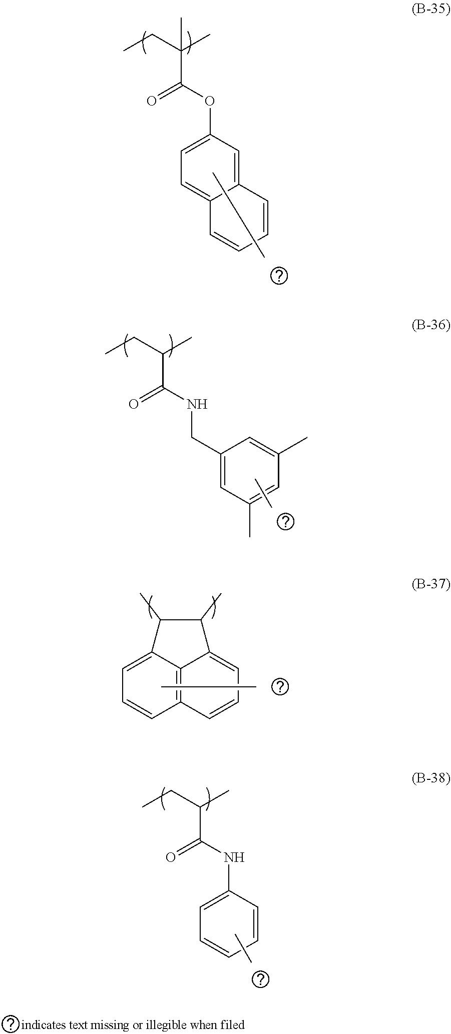

Note that, of the repeating units, preferred are the following specific repeating units. In the formulas, R represent a hydrogen atom or a methyl group, and a represent 2 or 3.

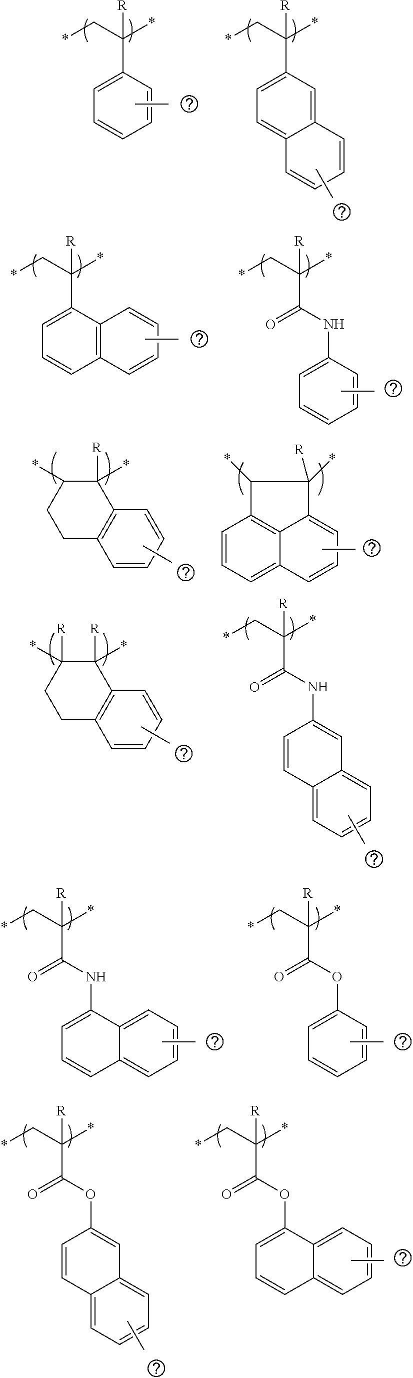

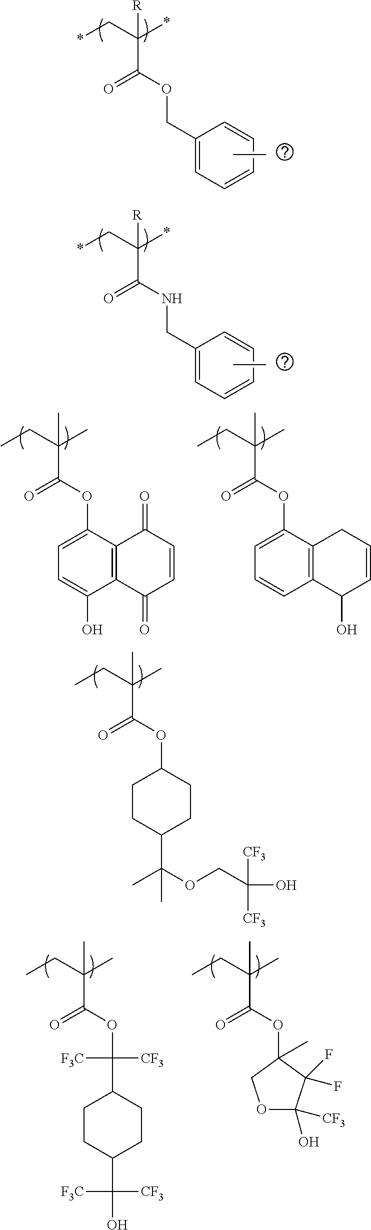

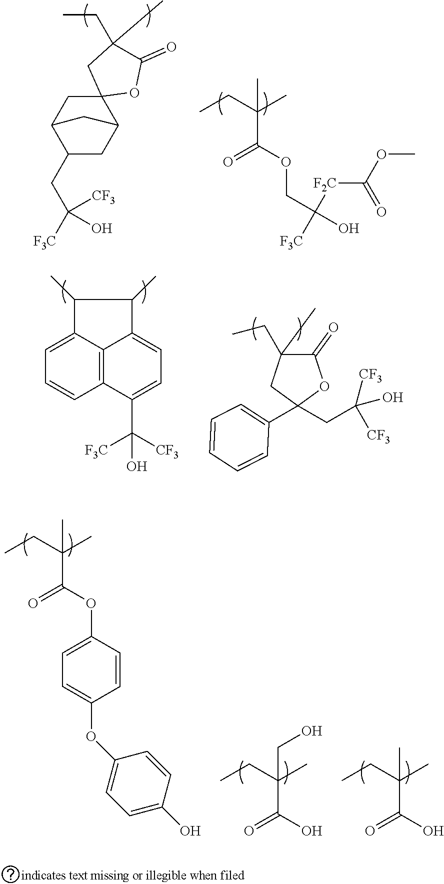

The content of the repeating unit having an acid group with respect to all the repeating units in Resin (A) is preferably 10 mol % or more, more preferably 15 mol % or more. The upper limit value with respect to all the repeating units in Resin (A) is preferably 95 mol % or less, more preferably 85 mol % or less, still more preferably 80 mol % or less.

Note that, when Resin (A) has Repeating unit (a1), Repeating unit (a2), and Repeating unit (a3) alone, the total amount of Repeating unit (a1), Repeating unit (a2), and Repeating unit (a3) included in Resin (A) is 100 mol %.

Resin (A) may have, in addition to the repeating structure units, from the viewpoint of adjusting, for example, dry etching resistance, standard developer suitability, substrate adhesiveness, resist profile, resolution, heat resistance, and sensitivity, various repeating structure units.

Resin (A) may have, for example, repeating units described in [0080] to [0105] of JP2020-95068A, Paragraphs [0370] to [0414] of US2016/0070167A1, Paragraphs [0415] to [0433] of US2016/0070167A1, and Paragraphs [0236] to [0237] of US2016/0026083A1.

In Resin (A) (in particular, in the case where the composition is used as an ArF actinic ray-sensitive or radiation-sensitive resin composition), all the repeating units are preferably constituted by repeating units derived from a compound having an ethylenically unsaturated bond. In particular, all the repeating units are also preferably constituted by (meth)acrylate-based repeating units. In this case, all the repeating units may be methacrylate-based repeating units, all the repeating units may be acrylate-based repeating units, or all the repeating units are methacrylate-based repeating units and acrylate-based repeating units; acrylate-based repeating units are preferably 50 mol % or less of all the repeating units.

Resin (A) can be synthesized by standard procedures (for example, radical polymerization).

Resin (A) has a weight-average molecular weight (as a polystyrene equivalent value determined by GPC method) of preferably 30,000 or less, more preferably 1,000 to 30,000, still more preferably 3,000 to 30,000, particularly preferably 5,000 to 15,000.

Resin (A) preferably has a dispersity (molecular weight distribution) of 1 to 5, more preferably 1 to 3, still more preferably 1.2 to 3.0, particularly preferably 1.2 to 2.0. As the dispersity lowers, the resolution becomes higher, the resist profile becomes better, the sidewalls of the resist pattern become smoother, and the roughness performance becomes higher.

The present invention also relates to a resin having a repeating unit derived from a compound represented by the following General formula (P-1), and a repeating unit derived from a compound represented by any one of the following Formulas (A-2) to (A-5).

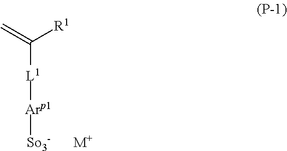

In General formula (P-1),

R¹ represents a hydrogen atom, an alkyl group, an aryl group, or a halogen atom;

L¹ represents a single bond or a divalent linking group;

Ar^{p1} represents an aromatic ring group or an aromatic heterocyclic group; and

M⁺ represents a lithium cation, a potassium cation, or an ammonium cation.

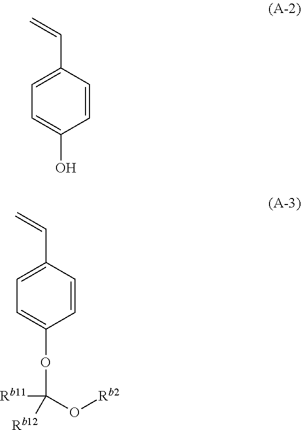

In Formula (A-3), R^{b11} and R^{b12} each independently represent a hydrogen atom, an alkyl group, an aryl group, or a heteroaryl group. R^{b2} represents an alkyl group, an aryl group, or a heteroaryl group.

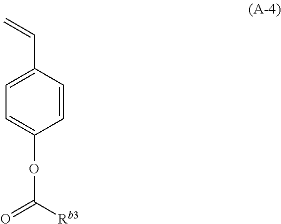

In Formula (A-4), R³ represents an alkyl group, an alkoxy group, an aryl group, an aryloxy group, or a heteroaryl group.

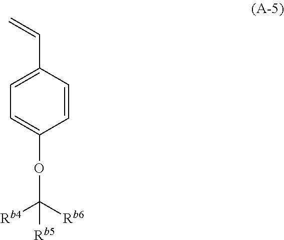

In Formula (A-5), R^{b4} to R^{b6} each independently represent an alkyl group, an aryl group, or a heteroaryl group.

The above-described resin is a resin corresponding to a reaction intermediate of Resin (A) above.

In the resin, the groups of General formula (P-1) are the same as and have the same preferred examples as the groups of General formula (P-1) described in Step (1) of the above-described method for producing a resin according to the present invention.

In the resin, the groups of Formula (A-3) are the same as and have the same preferred examples as the groups of Formula (A-3) described in Step (1) of the above-described method for producing a resin according to the present invention.

In the resin, the groups of Formula (A-4) are the same as and have the same preferred examples as the groups of Formula (A-4) described in Step (1) of the above-described method for producing a resin according to the present invention.

In the resin, the groups of Formula (A-5) are the same as and have the same preferred examples as the groups of Formula (A-5) in Step (1) of the above-described method for producing a resin according to the present invention.

The weight-average molecular weight and dispersity of the resin are respectively the same as and have the same preferred examples as the weight-average molecular weight and dispersity of Resin P described in Step (1) of the above-described method for producing a resin according to the present invention.

The resin can be synthesized by standard procedures (for example, radical polymerization). The resin can be synthesized with reference to, for example, Examples of this Specification.

In the resin, such repeating units derived from the compound represented by General formula (P-1) (also referred to as Repeating unit (b1)) may be used alone or in combination of two or more thereof.

In the resin, the content of Repeating unit (b1) with respect to all the repeating units of the resin is preferably 0.5 to 30 mol %, more preferably 1 to 20 mol %, still more preferably 2 to 15 mol %.

Also in the resin, such repeating units derived from the compound represented by any one of Formulas (A-2) to (A-5) (also referred to as Repeating unit (b2)) may be used alone or in combination of two or more thereof.

In the resin, the content of Repeating unit (b2) with respect to all the repeating units of the resin is preferably 70 to 99.5 mol %, more preferably 80 to 99 mol %, still more preferably 85 to 98 mol %.

In the resin corresponding to the reaction intermediate of Resin (A), the total content of Repeating unit (b1) and Repeating unit (b2) (in the case of a plurality of Repeating units (b1) and a plurality of Repeating units (b2), the total content thereof) with respect to all the repeating units of Resin (A) is preferably 60 mol % or more, more preferably 70 mol % or more, still more preferably 80 mol % or more.

Note that, when the resin has Repeating unit (b1) and Repeating unit (b2) alone, the total amount of Repeating unit (b1) and Repeating unit (b2) included in the resin is 100 mol %.

Method for producing actinic ray-sensitive or radiation-sensitive resin composition containing the resin, the method including method for producing resin according to the present invention

In the method for producing a composition according to the present invention, components that can be included in the actinic ray-sensitive or radiation-sensitive resin composition (hereafter, also referred to as “composition” or “composition according to the present invention”) will be described in detail.

The actinic ray-sensitive or radiation-sensitive resin composition is typically a resist composition, and may be a positive resist composition or a negative resist composition. The composition may be a resist composition for alkali development, or a resist composition for organic-solvent development. The composition is typically a chemically amplified resist composition.

The actinic ray-sensitive or radiation-sensitive resin composition contains the resin. The resin is a resin (Resin (A)) produced by the method for producing a resin according to the present invention.

Resin (A) is the same as that described above.

In the composition according to the present invention, the content of Resin (A) with respect to the total solid content of the composition is preferably 50.0 to 99.9 mass %, more preferably 60.0 to 99.0 mass %, still more preferably 70.0 to 98.0 mass %.

Such Resins (A) may be used alone or in combination of two or more thereof.

The composition according to the present invention may contain, unless advantages of the present invention are hindered, in addition to Resin (A), a resin not having Repeating unit (a1) (also referred to as Resin (A′)).

Resin (A′) is not particularly limited as long as it is a resin not having Repeating unit (a1), but may be a resin, for example, Resin (A) that does not have Repeating unit (a1).

When the composition according to the present invention contains Resin (A′), in the composition according to the present invention, the ratio of the content of Resin (A) to the content of Resin (A′) is preferably a mass ratio of 9:1 to 8:2.

(B) Compound that Generates Acid by Irradiation with Actinic Ray or Radiation

The composition according to the present invention, unless advantages of the present invention are hindered, may include a compound (different from Resin (A) above) that generates acid by irradiation with an actinic ray or a radiation (also referred to as Compound (B), Ionic compound (B), photoacid generator, or Photoacid generator (B)). The photoacid generator is a compound that generates acid by exposure.

Photoacid generator (B) may have the form of a low-molecular-weight compound, or the form of being incorporated into a portion of a polymer. Alternatively, the form of a low-molecular-weight compound and the form of being incorporated into a portion of a polymer may be used in combination.

When Photoacid generator (B) has the form of a low-molecular-weight compound, it preferably has a molecular weight of 3000 or less, more preferably 2000 or less, still more preferably 1000 or less.

In the present invention, Photoacid generator (B) preferably has the form of a low-molecular-weight compound.

In a preferred example, Photoacid generator (B) is preferably an onium salt.

Photoacid generator (B) may be, for example, a compound represented by M₂₁*X⁻ (onium salt), and is preferably a compound that generates an organic acid by exposure.

Examples of the organic acid include sulfonic acids (such as aliphatic sulfonic acids, aromatic sulfonic acids, and camphorsulfonic acid), carboxylic acids (such as aliphatic carboxylic acids, aromatic carboxylic acids, and aralkyl carboxylic acids), carbonylsulfonylimidic acid, bis(alkylsulfonyl)imidic acids, and tris(alkylsulfonyl)methide acids.

In the compound represented by “M₂₁⁺X⁻”, M₂₁⁺ represents an organic cation.

The organic cation is not particularly limited. For the valence, the organic cation may be mono-, di-, or higher valent.

In particular, the organic cation is not particularly limited, but is preferably a cation represented by Formula (ZaI) above (hereafter, also referred to as “Cation (ZaI)”), or a cation represented by Formula (ZaII) above (hereafter, also referred to as “Cation (ZaII)”).

In the compound represented by “M₂₁⁺X⁻”, X-represents an organic anion.

The organic anion is not particularly limited, but may be a mono-, di-, or higher valent organic anion.

The organic anion is preferably an anion that has a very low capability of causing a nucleophilic reaction, more preferably a non-nucleophilic anion.

Examples of the non-nucleophilic anion include sulfonate anions (such as aliphatic sulfonate anions, aromatic sulfonate anions, and a camphorsulfonate anion), carboxylate anions (such as aliphatic carboxylate anions, aromatic carboxylate anions, and aralkyl carboxylate anions), a sulfonylimide anion, bis(alkylsulfonyl)imide anions, and tris(alkylsulfonyl)methide anions.

In such an aliphatic sulfonate anion or aliphatic carboxylate anion, the aliphatic moiety may be a linear or branched alkyl group or a cycloalkyl group, and is preferably a linear or branched alkyl group having 1 to 30 carbon atoms, or a cycloalkyl group having 3 to 30 carbon atoms.

The alkyl group may be, for example, a fluoroalkyl group (may have a substituent other than a fluorine atom or may be a perfluoroalkyl group).

In such an aromatic sulfonate anion or aromatic carboxylate anion, the aryl group 1s preferably an aryl group having 6 to 14 carbon atoms, for example, a phenyl group, a tolyl group, or a naphthyl group.

The above-described alkyl group, cycloalkyl group, and aryl group may have a substituent. The substituent is not particularly limited; examples include a nitro group, halogen atoms such as a fluorine atom and a chlorine atom, a carboxyl group, a hydroxy group, an amino group, a cyano group, alkoxy groups (preferably having 1 to 15 carbon atoms), alkyl groups (preferably having 1 to 10 carbon atoms), cycloalkyl groups (preferably having 3 to 15 carbon atoms), aryl groups (preferably having 6 to 14 carbon atoms), alkoxycarbonyl groups (preferably having 2 to 7 carbon atoms), acyl groups (preferably having 2 to 12 carbon atoms), alkoxycarbonyloxy groups (preferably having 2 to 7 carbon atoms), alkylthio groups (preferably having 1 to 15 carbon atoms), alkylsulfonyl groups (preferably having 1 to 15 carbon atoms), alkyliminosulfonyl groups (preferably having 1 to 15 carbon atoms), and aryloxysulfonyl groups (preferably having 6 to 20 carbon atoms).

In such an aralkyl carboxylate anion, the aralkyl group is preferably an aralkyl group having 7 to 14 carbon atoms.

Examples of the aralkyl group having 7 to 14 carbon atoms include a benzyl group, a phenethyl group, a naphthylmethyl group, a naphthylethyl group, and a naphthylbutyl group.

The sulfonylimide anion may be, for example, a saccharin anion.

In such a bis(alkylsulfonyl)imide anion or a tris(alkylsulfonyl)methide anion, the alkyl groups are preferably an alkyl group having 1 to 5 carbon atoms. In the alkyl group, a substituent may be a halogen atom, an alkyl group substituted with a halogen atom, an alkoxy group, an alkylthio group, an alkyloxysulfonyl group, an aryloxysulfonyl group, or a cycloalkylaryloxysulfonyl group, and is preferably a fluorine atom or an alkyl group substituted with a fluorine atom.

In the bis(alkylsulfonyl)imide anion, the alkyl groups may be linked together to form a ring structure. This results in an increase in the acid strength.

Other examples of the non-nucleophilic anion include phosphorus fluoride (for example, PF₆⁻), boron fluoride (for example, BF₄⁻), and antimony fluoride (for example, SbF₆⁻).

The non-nucleophilic anion is preferably an aliphatic sulfonate anion in which at least the α position of sulfonic acid is substituted with a fluorine atom, an aromatic sulfonate anion substituted with a fluorine atom or a group having a fluorine atom, a bis(alkylsulfonyl)imide anion in which the alkyl groups are substituted with fluorine atoms, or a tris(alkylsulfonyl)methide anion in which the alkyl groups are substituted with fluorine atoms. In particular, the anion is more preferably a perfluoroaliphatic sulfonate anion (preferably having 4 to 8 carbon atoms) or a benzenesulfonate anion having a fluorine atom, still more preferably a nonafluorobutanesulfonate anion, a perfluorooctanesulfonate anion, a pentafluorobenzenesulfonate anion, or a 3,5-bis(trifluoromethyl)benzenesulfonate anion.

A plurality of non-nucleophilic anions may be linked together via a linking group.

The non-nucleophilic anion is also preferably an anion represented by the following Formula (AN1).

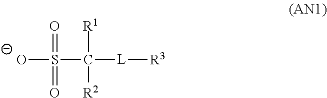

In Formula (AN1), R¹ and R² each independently represent a hydrogen atom or a substituent.

The substituent is not particularly limited, but is preferably a group that is not electron-withdrawing groups. Examples of the group that is not electron-withdrawing groups include hydrocarbon groups, a hydroxy group, oxyhydrocarbon groups, oxycarbonylhydrocarbon groups, an amino group, hydrocarbon-substituted amino groups, and hydrocarbon-substituted amide groups.

Such groups that are not electron-withdrawing groups are each independently preferably −R′, —OH, —OR′, —OCOR′, —NH₂, —NR′₂, —NHR′, or —NHCOR′. R′ are monovalent hydrocarbon groups.

Examples of the monovalent hydrocarbon groups represented by R′ above include monovalent linear or branched hydrocarbon groups such as alkyl groups such as a methyl group, an ethyl group, a propyl group, and a butyl group; alkenyl groups such as an ethenyl group, a propenyl group, and a butenyl group; and alkynyl groups such as an ethynyl group, a propynyl group, and a butynyl group; monovalent alicyclic hydrocarbon groups such as cycloalkyl groups such as a cyclopropyl group, a cyclobutyl group, a cyclopentyl group, a cyclohexyl group, a norbornyl group, and an adamantly group; and cycloalkenyl groups such as a cyclopropenyl group, a cyclobutenyl group, a cyclopentenyl group, and a norbornenyl group; and monovalent aromatic hydrocarbon groups such as aryl groups such as a phenyl group, a tolyl group, a xylyl group, a mesityl group, a naphthyl group, a methylnaphthyl group, an anthryl group, and methylanthryl group; and aralkyl groups such as a benzyl group, a phenethyl group, a phenylpropyl group, a naphthylmethyl group, and an anthrylmethyl group.

In particular, R¹ and R² are each independently preferably a hydrocarbon group (preferably a cycloalkyl group) or a hydrogen atom.

L represents a divalent linking group.

When there are a plurality of L's, L's may be the same or different.

The divalent linking group may be, for example, —O—CO—O—, —COO—, —CONH—, —CO—, —O—, —S—, —SO—, —SO₂—, an alkylene group (preferably having 1 to 6 carbon atoms), a cycloalkylene group (preferably having 3 to 15 carbon atoms), an alkenylene group (preferably having 2 to 6 carbon atoms), or a divalent linking group provided by combining a plurality of the foregoing. In particular, the divalent linking group is preferably —O—CO—O—, —COO—, —CONH—, —CO—, —O—, —SO₂—, —O—CO—O-alkylene group-, —COO-alkylene group-, or —CONH-alkylene group-, more preferably —O—CO—O—, —O—CO—O-alkylene group-, —COO—, —CONH—, —SO₂—, or —COO-alkylene group-.

L is preferably, for example, a group represented by the following Formula (AN1-1).

*^{a}—(CR²₂)_{X}-Q-(CR^{2b}₂)_{Y}—*^{b} (AN1-1)

In Formula (AN 1-1), *^{a} represents the bonding site to R³ in Formula (AN1).

*^{b} represents the bonding site to —C(R¹)(R²)— in Formula (AN1).

X and Y each independently represent an integer of 0 to 10, and is preferably an integer of 0 to 3.

R^{2a} and R^{2b} each independently represent a hydrogen atom or a substituent.

When there are a plurality of R^{2a}'s and a plurality of R^{2b}'s, the plurality of R^{2a}'s and the plurality of R^{2b}'s may be individually the same or different.

Note that, when Y is 1 or more, in Formula (AN1), in CR^{2b}₂ directly bonded to —C(R¹)(R²)—, R^{2b} is not a fluorine atom.

Q represents *^{A}—O—CO—O—*^{B}, *^{A}—CO—*^{B}, *^{A}—CO—O—*^{B}, *^{A}—O—CO—*^{B}, *^{A}—O—*^{B}, *^{A}—S—*^{B}, or *^{A}—SO₂—*^{B}.

Note that, when X+Y in Formula (AN1-1) is 1 or more, and R^{2a} and R^{2b} in Formula (AN1-1) are all hydrogen atoms, Q represents *^{A}—O—CO—O—*^{B}, *^{A}CO—*_{B}, *^{A}—O—CO—*^{B}, *^{A}—O—*B, *^{A}—S—*^{B}, or *^{A}—SO₂—*^{B}.

*^{A} represent a bonding site on the R³ side in Formula (AN1). *^{B} represent a bonding site on the —SO₃⁻ side in Formula (AN1).

In Formula (AN1), R³ represents an organic group.

The organic group is not particularly limited as long as it has 1 or more carbon atoms, and may be a linear group (for example, a linear alkyl group), a branched group (for example, a branched alkyl group such as a t-butyl group), or a cyclic group. The organic group may or may not have a substituent. The organic group may or may not have a heteroatom (such as an oxygen atom, a sulfur atom, and/or a nitrogen atom).

In particular, R³ is preferably an organic group having a ring structure. The ring structure may be monocyclic or polycyclic, and may have a substituent. In the organic group including a ring structure, the ring is preferably directly bonded to L in Formula (AN1).

The organic group having a ring structure, for example, may or may not have a heteroatom (such as an oxygen atom, a sulfur atom, and/or a nitrogen atom). The heteroatom may substitute one or more carbon atoms forming the ring structure.

The organic group having a ring structure is preferably, for example, a hydrocarbon group having a ring structure, a lactone ring group, or a sultone ring group. In particular, the organic group having a ring structure is preferably a hydrocarbon group having a ring structure.

The hydrocarbon group having a ring structure is preferably a monocyclic or polycyclic cycloalkyl group. Such groups may have a substituent.

The cycloalkyl group may be monocyclic (such as a cyclohexyl group) or polycyclic (such as an adamantly group), and preferably has 5 to 12 carbon atoms.

The lactone group and the sultone group are preferably, for example, a group in which, in the above-described structures represented by Formula (LC1-1) to (LC1-21) or structures represented by Formulas (SL1-1) to (SL1-3), from a ring-member atom forming the lactone structure or the sultone structure, a hydrogen atom has been removed.

The non-nucleophilic anion may be a benzenesulfonate anion, and is preferably a benzenesulfonate anion substituted with a branched alkyl group or a cycloalkyl group.

The non-nucleophilic anion is also preferably an anion represented by the following Formula (AN2).

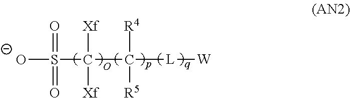

In Formula (AN2), o represents an integer of 1 to 3. p represents an integer of 0 to 10. q represents an integer of 0 to 10.

Xf's represent a hydrogen atom, a fluorine atom, an alkyl group substituted with at least one fluorine atom, or an organic group not having fluorine atoms. The alkyl group preferably has 1 to 10 carbon atoms, more preferably 1 to 4 carbon atoms. The alkyl group substituted with at least one fluorine atom is preferably a perfluoroalkyl group.

Xf's are preferably a fluorine atom or a perfluoroalkyl group having 1 to 4 carbon atoms, more preferably a fluorine atom or CF₃; still more preferably, both Xf's are fluorine atoms.

R⁴ and R⁵ each independently represent a hydrogen atom, a fluorine atom, an alkyl group, or an alkyl group substituted with at least one fluorine atom. When there are a plurality of R⁴'s and R's, R⁴'s and R⁵'s may be individually the same or different.

In R⁴ and R₅, the alkyl group preferably has 1 to 4 carbon atoms. The alkyl group may have a substituent. R⁴ and R⁵ are preferably a hydrogen atom.

L represents a divalent linking group. L has the same definition as Lin Formula (AN1).

W represents an organic group including a ring structure and, in particular, preferably a cyclic organic group.

The cyclic organic group may be, for example, an alicyclic group, an aryl group, or a heterocyclic group.

The alicyclic group may be monocyclic or polycyclic. Examples of the monocyclic alicyclic group include monocyclic cycloalkyl groups such as a cyclopentyl group, a cyclohexyl group, and a cyclooctyl group. Examples of the polycyclic alicyclic group include polycyclic cycloalkyl groups such as a norbornyl group, a tricyclodecanyl group, a tetracyclodecanyl group, a tetracyclododecanyl group, and an adamantyl group. In particular, preferred are alicyclic groups having a bulky structure having 7 or more carbon atoms such as a norbornyl group, a tricyclodecanyl group, a tetracyclodecanyl group, a tetracyclododecanyl group, and an adamantyl group.

The aryl group may be monocyclic or polycyclic. Examples of the aryl group include a phenyl group, a naphthyl group, a phenanthryl group, and an anthryl group.

The heterocyclic group may be monocyclic or polycyclic. In particular, in the case of a polycyclic heterocyclic group, diffusion of acid can be further suppressed. The heterocyclic group may have aromaticity or may not have aromaticity. Examples of the heterocycle having aromaticity include a furan ring, a thiophene ring, a benzofuran ring, a benzothiophene ring, a dibenzofuran ring, a dibenzothiophene ring, and a pyridine ring. Examples of the heterocycle not having aromaticity include a tetrahydropyran ring, a lactone ring, a sultone ring, and a decahydroisoquinoline ring. In the heterocyclic group, the heterocycle is preferably a furan ring, a thiophene ring, a pyridine ring, or a decahydroisoquinoline ring.

The cyclic organic group may have a substituent. The substituent may be, for example, an alkyl group (linear or branched, preferably having 1 to 12 carbon atoms), a cycloalkyl group (having a monocycle, a polycycle, or a spiro ring, preferably having 3 to 20 carbon atoms), an aryl group (preferably having 6 to 14 carbon atoms), a hydroxy group, an alkoxy group, an ester group, an amide group, a urethane group, a ureido group, a thioether group, a sulfonamide group, or a sulfonic acid ester group. Note that a carbon forming the cyclic organic group (carbon contributing to formation of the ring) may be a carbonyl carbon.

The anion represented by Formula (AN2) is preferably SO₃⁻—CF₂—CH₂—OCO-(L)_{q′}-W, SO₃⁻—CF₂—CHF—CH₂—OCO-(L)_{q′}—W, SO₃⁻—CF₂—COO-(L)_{q′}—W, SO₃⁻13 CF₂—CF₂—CH₂—CH₂-(L)_{q′}—W, or SO₃—CF₂—CH(CF₃)—OCO-(L)_{q′}—W, where L, q, and W are the same as in Formula (AN2), and q′represents an integer of 0 to 10.

The non-nucleophilic anion is also preferably an aromatic sulfonate anion represented by the following Formula (AN3).

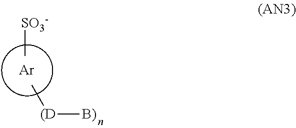

In Formula (AN3), Ar represents an aryl group (such as a phenyl group), and may further have a substituent other than the sulfonate anion and the -(D-B) group. Examples of the substituent that Ar may further have include a fluorine atom and a hydroxy group.

n represents an integer of 0 or more. n is preferably 1 to 4, more preferably 2 to 3, still more preferably 3.

D represents a single bond or a divalent linking group. The divalent linking group may be an ether group, a thioether group, a carbonyl group, a sulfoxide group, a sulfo group, a sulfonic acid ester group, an ester group, or a group of a combination of two or more of the foregoing.

B represents a hydrocarbon group.

B is preferably an aliphatic hydrocarbon group, more preferably an isopropyl group, a cyclohexyl group, or an aryl group that may further have a substituent (such as a tricyclohexylphenyl group).

The non-nucleophilic anion is also preferably a disulfonamide anion.

The disulfonamide anion 1s, for example, an anion represented by N⁻(SO₂—R^{q})₂.

R^{q}'s represent an alkyl group that may have a substituent, and are preferably a fluoroalkyl group, more preferably a perfluoroalkyl group. Two R^{q}'s may be linked together to form a ring. The group formed by linking together two R^{q}'s is preferably an alkylene group that may have a substituent, preferably a fluoroalkylene group, more preferably a perfluoroalkylene group. The alkylene group preferably has 2 to 4 carbon atoms.

Other examples of the non-nucleophilic anion include anions represented by the following Formulas (d1-1) to (d1-4).

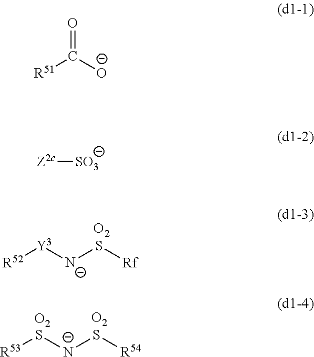

In Formula (d1-1), R⁵¹ represents a hydrocarbon group that may have a substituent (such as a hydroxy group) (for example, an aryl group such as a phenyl group).

In Formula (d1-2), Z^{2c} represents a hydrocarbon group that has 1 to 30 carbon atoms and that may have a substituent (note that the carbon atom adjacent to S is not substituted with a fluorine atom).

In Z^{2c}, the hydrocarbon group may be linear or branched, and may have a ring structure. In the hydrocarbon group, a carbon atom (preferably, in a case where the hydrocarbon group has a ring structure, a carbon atom serving as a ring-member atom) may be a carbonyl carbon (—CO—). The hydrocarbon group may be, for example, a group that has a norbornyl group and that may have a substituent. A carbon atom forming the norbornyl group may be a carbonyl carbon.

In Formula (d1-2), “Z^{2c}—SO₃⁻” is preferably different from the anions represented by Formulas (AN1) to (AN3) above. For example, Z^{2c} is preferably not aryl groups. For example, in Z^{2c}, the atoms at the α position and the β position relative to —SO₃⁻ are preferably atoms other than carbon atoms having, as a substituent, a fluorine atom. For example, in Z^{2c}, the atom at the a position and/or the atom at the β position relative to —SO₃⁻ is preferably a ring-member atom in a ring group.

In Formula (d1-3), R⁵² represents an organic group (preferably a hydrocarbon group having a fluorine atom), Y³ represents a linear, branched, or cyclic alkylene group, an arylene group, or a carbonyl group, and Rf represents a hydrocarbon group.

In Formula (d1-4), R³ and R⁵⁴ each independently represent an organic group (preferably a hydrocarbon group having a fluorine atom). R⁵³ and R⁵⁴ may be linked together to form a ring.

Such organic anions may be used alone or in combination of two or more thereof.

The photoacid generator may also be a betaine compound having a structure having a cationic moiety and an anionic moiety in which these moieties are linked together via a covalent bond.

In the composition according to the present invention, the content of Photoacid generator (B) is not particularly limited, but 1s, from the viewpoint of providing more greatly advantages of the present invention, with respect to the total solid content of the composition, preferably 0.1 mass % or more, more preferably 0.5 mass % or more, still more preferably 1.0 mass % or more. The content is preferably 50 mass % or less, more preferably 40 mass % or less, still more preferably 30 mass % or less.

Such Photoacid generators (B) may be used alone or in combination of two or more thereof.

### Acid Diffusion Control Agent (C)

The composition according to the present invention may include an acid diffusion control agent.

The acid diffusion control agent serves as a quencher that traps acid generated from a photoacid generator or the like upon exposure, to suppress the reaction (due to an excess of generated acid) of the acid decomposable resin in the unexposed region.

The type of the acid diffusion control agent is not particularly limited; examples include Basic compound (CA), Low-molecular-weight compound (CB) having a nitrogen atom and having a group that leaves due to the action of acid, and Compound (CC) whose acid diffusion control capability is reduced or lost by irradiation with an actinic ray or a radiation.

Compound (CC) may be Onium salt compound (CD) that is turned to a weak acid relative to the photoacid generator, or Basic compound (CE) whose basicity is reduced or lost by irradiation with an actinic ray or a radiation.

Specific examples of Basic compound (CA) include compounds described in Paragraphs [0132] to [0136] in WO2020/066824A; specific examples of Basic compound (CE) whose basicity is reduced or lost by irradiation with an actinic ray or a radiation include compounds described in Paragraphs [0137] to [0155] in WO2020/066824A; specific examples of Low-molecular-weight compound (CB) having a nitrogen atom and having a group that leaves due to the action of acid include compounds described in Paragraphs [0156] to [0163] in WO2020/066824A; specific examples of Onium salt compound having, in the cationic moiety, a nitrogen atom include compounds described in Paragraph [0164] in WO2020/066824A. Specific examples of Onium salt compound (CD) that is turned to a weak acid relative to the photoacid generator include compounds described in Paragraphs [0305] to [0314] in WO2020/158337A.

In addition to those described above, for example, publicly known compounds disclosed in Paragraphs [0627] to [0664] in US2016/0070167A1, Paragraphs [0095] to [0187]in US2015/0004544A1, Paragraphs [0403] to [0423] in US2016/0237190A1, and Paragraphs [0259] to [0328] in US2016/0274458A1 are suitably usable as acid diffusion control agents.

When the composition according to the present invention includes an acid diffusion control agent, the content of the acid diffusion control agent (in the case of a plurality of agents, the total content thereof) with respect to the total solid content of the composition is preferably 0.1 to 15.0 mass %, more preferably 1.0 to 15.0 mass %.

In the composition according to the present invention, such acid diffusion control agents may be used alone or in combination of two or more thereof.

### Hydrophobic Resin

The composition according to the present invention may further include a hydrophobic resin different from Resin (A).

The hydrophobic resin is preferably designed so as to be localized in the surface of a resist film; however, unlike surfactants, the hydrophobic resin does not necessarily need to have intramolecularly a hydrophilic group, and does not necessarily contribute to homogeneous mixing of a polar substance and a nonpolar substance.

Advantages due to addition of the hydrophobic resin may be control of static and dynamic contact angles (for water) at the surface of the resist film, and suppression of outgassing.

The hydrophobic resin, from the viewpoint of localization in the surface layer of the film, preferably has one or more, more preferably two or more, selected from the group consisting of a fluorine atom, a silicon atom, and a CH₃ moiety included in the side chain moiety of the resin. The hydrophobic resin preferably has a hydrocarbon group having 5 or more carbon atoms. The resin may have such a group in the main chain or, as a substituent, in a side chain.

Examples of the hydrophobic resin include compounds described in Paragraphs [0275] to [0279] in WO2020/004306A.

When the composition according to the present invention includes a hydrophobic resin, the content of the hydrophobic resin with respect to the total solid content of the composition 1s preferably 0.01 to 20.0 mass %, more preferably 0.1 to 15.0 mass %.

### Solvent

The composition according to the present invention may include a solvent.

The solvent preferably includes at least one of (M1) propylene glycol monoalkyl ether carboxylate or (M2) at least one selected from the group consisting of propylene glycol monoalkyl ether, lactate, acetate, alkoxypropionate, chain ketone, cyclic ketone, lactone, and alkylene carbonate. Note that the solvent may further include a component other than Components (M1) and (M2).

The inventors of the present invention have found that, in the case of using such a solvent and the above-described resin in combination, the resultant composition has improved coatability, and a pattern having a smaller number of development defects can be formed. The reason for this is not necessarily clear; however, such solvents are well-balanced in terms of solubility of the above-described resin, boiling point, and viscosity, to thereby suppress, for example, unevenness of the film thickness of the resist film and generation of deposit during spin-coating, which is inferred by the inventors of the present invention.

Details of Component (M1) and Component (M2) are described in Paragraphs [0218]to [0226] in WO2020/004306A, and these contents are incorporated herein by reference.

As described above, the solvent may further include a component other than Components (M1) and (M2). In this case, the content of the component other than Components (M1) and (M2) with respect to the total amount of the solvent is preferably 5 to 30 mass %.

In the composition according to the present invention, the content of the solvent 1s preferably set such that the concentration of solid content becomes 0.5 to 30 mass %, more preferably 1 to 20 mass %. In such a case, the composition according to the present invention has further improved coatability.

Note that the solid content means all the components other than the solvent, and means, as described above, components for forming an actinic ray-sensitive or radiation-sensitive film.

The concentration of solid content 1s, with respect to the total mass of the composition according to the present invention, mass percentage of the mass of components except for the solvent.

The term “total solid content” refers to the total mass of the components excluding the solvent from all the components of the composition according to the present invention. The term “solid content” refers to, as described above, components except for the solvent, and may be, for example, at 25° C., solid or liquid.

### Surfactant

The composition according to the present invention may include a surfactant. The composition including a surfactant enables formation of a pattern having higher adhesiveness and a smaller number of development defects.

The surfactant is preferably a fluorine-based and/or silicon-based surfactant.

Examples of the fluorine-based and/or silicon-based surfactant include surfactants disclosed in Paragraphs [0218] and [0219] in WO2018/19395A.

Such surfactants may be used alone or in combination of two or more thereof.

When the composition according to the present invention includes a surfactant, the content of the surfactant with respect to the total solid content of the composition is preferably 0.0001 to 2.0 mass %, more preferably 0.0005 to 1.0 mass %, still more preferably 0.1 to 1.0 mass %.

### Other Additives

The composition according to the present invention may further include a dissolution inhibition compound, a dye, a plasticizer, a light sensitizer, a light absorbent, and/or a compound that improves solubility in a developer (for example, a phenol compound having a molecular weight of 1000 or less, or an alicyclic or aliphatic compound including a carboxyl group).

The composition according to the present invention may further include a dissolution inhibition compound. The term “dissolution inhibition compound” refers to a compound that has a molecular weight of 3000 or less and that is decomposed due to the action of acid to undergo a decrease in the solubility in an organic-based developer.

A method for producing a composition according to the present invention may include a step of mixing the resin included in the composition with another component that can be included, as needed, in the composition.

### Applications

The composition according to the present invention relates to an actinic ray-sensitive or radiation-sensitive resin composition that reacts due to irradiation with an actinic ray or a radiation to undergo a change in a property. More specifically, the composition according to the present invention relates to an actinic ray-sensitive or radiation-sensitive resin composition used for a step of producing a semiconductor such as an IC (Integrated Circuit), production of a circuit board for, for example, liquid crystal or a thermal head, production of an imprint mold structure, another photo fabrication step, or production of a planographic plate or an acid curable composition. A pattern formed in the present invention is usable in an etching step, an ion implantation step, a bump electrode formation step, a redistribution formation step, and MEMS (Micro Electro Mechanical Systems), for example.

### Pattern Forming Method

The procedures of the pattern forming method using the above-described method for producing a resin is not particularly limited, but preferably have the following steps:

Step 1: a step of performing the method for producing a resin to produce the resin;

Step 2: a step of using an actinic ray-sensitive or radiation-sensitive resin composition containing the resin, to form, on a substrate, an actinic ray-sensitive or radiation-sensitive film;

Step 3: a step of exposing the actinic ray-sensitive or radiation-sensitive film; and

Step 4: a step of using a developer, to develop the exposed actinic ray-sensitive or radiation-sensitive film, to form a pattern.

Hereinafter, procedures in each of the steps will be described in detail.

### Step 1: Resin Production Step

Step 1 is a step of performing the method for producing a resin, to produce the resin. The method for producing a resin according to the present invention is the same as that described above.

### Step 2: Actinic Ray-Sensitive or Radiation-Sensitive Film Formation Step

Step 2 is a step of using an actinic ray-sensitive or radiation-sensitive resin composition containing the resin, to form, on a substrate, an actinic ray-sensitive or radiation-sensitive film (typically, “resist film”).

The actinic ray-sensitive or radiation-sensitive resin composition contains the resin produced by the production method according to the present invention.

The process of using the actinic ray-sensitive or radiation-sensitive resin composition to form, on a substrate, an actinic ray-sensitive or radiation-sensitive film may be, for example, a process of applying the actinic ray-sensitive or radiation-sensitive resin composition onto the substrate.

Note that, prior to the application, the actinic ray-sensitive or radiation-sensitive resin composition is preferably, as needed, subjected to filtration through a filter. The filter preferably has a pore size of 0.1 μm or less, more preferably 0.05 μm or less, still more preferably 0.03 μm or less. The filter is preferably formed of polytetrafluoroethylene, polyethylene, or nylon.

The actinic ray-sensitive or radiation-sensitive resin composition can be applied onto a substrate (for example, formed of silicon and covered with silicon dioxide) as with substrates used for producing integrated circuit elements, by an appropriate coating process using a spinner or a coater, for example. The coating process is preferably spin-coating using a spinner. The spin-coating using a spinner is preferably performed at a rotation rate of 1000 to 3000 rpm. After the application of the actinic ray-sensitive or radiation-sensitive resin composition, the substrate may be dried to form a resist film. Note that, as needed, as underlayers of the resist film, various underlying films (an inorganic film, an organic film, or an antireflection film) may be formed.

The drying process 1s, for example, a process of performing heating to achieve drying. The heating can be performed using means included in an ordinary exposure device and/or an ordinary development device, or may alternatively be performed using a hot plate, for example. The heating temperature is preferably 80 to 150° C., more preferably 80 to 140° C., still more preferably 80 to 130° C. The heating time is preferably 30 to 1000 seconds, more preferably 60 to 800 seconds, still more preferably 60 to 600 seconds.

The film thickness of the actinic ray-sensitive or radiation-sensitive film is not particularly limited, but 1s, from the viewpoint of enabling formation of more precise fine patterns, preferably 10 to 120 nm.

In particular, in the case of EUV exposure, the film thickness of the actinic ray-sensitive or radiation-sensitive film is more preferably 10 to 65 nm, still more preferably 15 to 50 nm. Alternatively, in the case of ArF liquid immersion exposure, the film thickness of the actinic ray-sensitive or radiation-sensitive film is more preferably 10 to 120 nm, still more preferably 15 to 90 nm.

Note that, as an overlying layer of the actinic ray-sensitive or radiation-sensitive film, a topcoat composition may be used to form a topcoat.

The topcoat composition preferably does not mix with the actinic ray-sensitive or radiation-sensitive film, and can be uniformly applied, as an overlying layer of the actinic ray-sensitive or radiation-sensitive film.

The topcoat is not particularly limited; a publicly known topcoat can be formed by a publicly known process; for example, on the basis of descriptions of Paragraphs [0072] to [0082]in JP2014-059543A, a topcoat can be formed.

For example, a topcoat including a basic compound and described in JP2013-61648A is preferably formed on the actinic ray-sensitive or radiation-sensitive film. Specific examples of the basic compound that can be included in the topcoat include the above-described basic compound that can be included in the actinic ray-sensitive or radiation-sensitive resin composition.

The topcoat also preferably includes a compound including at least one group or bond selected from the group consisting of an ether bond, a thioether bond, a hydroxy group, a thiol group, a carbonyl bond, and an ester bond.

### Step 3: Exposure Step

Step 3 is a step of exposing the actinic ray-sensitive or radiation-sensitive film.

The exposure process may be a process of irradiating the formed actinic ray-sensitive or radiation-sensitive film, through a predetermined mask, with an actinic ray or a radiation.

Examples of the actinic ray or radiation include infrared light, visible light, ultraviolet light, far-ultraviolet light, extreme ultraviolet light, X-rays, and an electron beam; the actinic ray or radiation is preferably far-ultraviolet light having wavelengths of 250 nm or less, more preferably 220 nm or less, particularly preferably 1 to 200 nm; specific examples include KrF excimer laser (248 nm), ArF excimer laser (193 nm), F₂ excimer laser (157 nm), EUV (13 nm), X-rays, and an electron beam.

After the exposure, before development, baking (heating) is preferably performed. The baking accelerates the reaction in the exposed regions, to provide higher sensitivity and a better pattern profile.

The heating temperature is preferably 80 to 150° C., more preferably 80 to 140° C., still more preferably 80 to 130° C.

The heating time is preferably 10 to 1000 seconds, more preferably 10 to 180 seconds, still more preferably 30 to 120 seconds.

The heating can be performed using means included in an ordinary exposure device and/or an ordinary development device, and may alternatively be performed using a hot plate, for example.

This step is also referred to as post-exposure baking.

### Step 4: Development Step

Step 4 is a step of using a developer, to develop the exposed actinic ray-sensitive or radiation-sensitive film, to form a pattern.

The developer may be an alkali developer or a developer containing an organic solvent (hereafter, also referred to as organic-based developer).

Examples of the development process include a process of immersing, for a predetermined time, the substrate in a tank filled with the developer (dipping process), a process of puddling the developer over the surface of the substrate using surface tension and leaving the developer at rest for a predetermined time to achieve development (puddling process), a process of spraying the developer to the surface of the substrate (spraying process), and a process of scanning, at a constant rate, over the substrate rotated at a constant rate, a developer ejection nozzle to continuously eject the developer (dynamic dispensing process).

After the step of performing development, a step of performing exchange for another solvent to stop the development may be performed.

The development time is not particularly limited as long as the resin in the unexposed regions is sufficiently dissolved in the time, and is preferably 10 to 300 seconds, more preferably 20 to 120 seconds.

The temperature of the developer is preferably 0 to 50° C., more preferably 15 to 35° C.

As the alkali developer, an alkali aqueous solution including an alkali is preferably used. The type of the alkali aqueous solution is not particularly limited, but may be, for example, an alkali aqueous solution including a quaternary ammonium salt represented by tetramethylammonium hydroxide, an inorganic alkali, a primary amine, a secondary amine, a tertiary amine, an alcoholamine, or a cyclic amine. In particular, the alkali developer 1s preferably an aqueous solution of a quaternary ammonium salt represented by tetramethylammonium hydroxide (TMAH). To the alkali developer, an appropriate amount of an alcohol, a surfactant, or the like may be added. The alkali developer ordinarily has an alkali concentration of 0.1 to 20 mass %. The alkali developer ordinarily has a pH of 10.0 to 15.0.

The organic-based developer is preferably a developer containing at least one organic solvent selected from the group consisting of ketone-based solvents, ester-based solvents, alcohol-based solvents, amide-based solvents, ether-based solvents, and hydrocarbon-based solvents.

Such solvents may be mixed together, or such a solvent may be mixed with a solvent other than those described above or water. The developer as a whole has a moisture content of preferably less than 50 mass %, more preferably less than 20 mass %, still more preferably less than 10 mass %, particularly preferably contains substantially no moisture.

In the organic-based developer, the content of the organic solvent with respect to the total amount of the developer is preferably 50 mass % or more and 100 mass % or less, more preferably 80 mass % or more and 100 mass % or less, still more preferably 90 mass % or more and 100 mass % or less, particularly preferably 95 mass % or more and 100 mass % or less.

### Other Step

The pattern forming method preferably includes a step of, after Step 4, using a rinse liquid to perform rinsing.

After the development step using an alkali developer, in the rinsing step, the rinse liquid employed may be, for example, pure water. Note that, to the pure water, an appropriate amount of surfactant may be added. To the rinse liquid, an appropriate amount of surfactant may be added.

After the development step using an organic-based developer, in the rinsing step, the rinse liquid employed is not particularly limited as long as it does not dissolve the resist pattern, and may be a solution including an ordinary organic solvent. The rinse liquid employed 1s preferably a rinse liquid containing at least one organic solvent selected from the group consisting of hydrocarbon-based solvents, ketone-based solvents, ester-based solvents, alcohol-based solvents, amide-based solvents, and ether-based solvents.

The process of performing the rinsing step is not particularly limited; examples include a process of continuously ejecting, onto the substrate rotated at a constant rate, the rinse liquid (spin-coating process), a process of immersing, in a tank filled with the rinse liquid, the substrate for a predetermined time (dipping process), and a process of spraying, to the surface of the substrate, the rinse liquid (spraying process).

The pattern forming method according to the present invention may include a heating step (Post Bake) performed after the rinsing step. In this step, baking removes the developer and the rinse liquid remaining between and within the patterns. In addition, this step provides an effect of annealing the resist pattern to address the rough surface of the pattern. The heating step after the rinsing step is performed ordinarily at 40 to 250° C. (preferably 90 to 200° C.) for ordinarily 10 seconds to 3 minutes (preferably 30 seconds to 120 seconds).

The formed pattern may be used as a mask for subjecting the substrate to etching treatment. Specifically, the pattern formed in Step 4 may be used as a mask for processing the substrate (or the lower layer film and the substrate), to form a pattern in the substrate.

The process of processing the substrate (or the lower layer film and the substrate) 1s not particularly limited, but is preferably a process of using the pattern formed in Step 4 as a mask for subjecting the substrate (or the lower layer film and the substrate) to dry etching, to form a pattern in the substrate. The dry etching is preferably oxygen plasma etching.

The composition according to the present invention and various materials used in the pattern forming method according to the present invention (for example, the solvent, the developer, the rinse liquid, the antireflection film-forming composition, and the topcoat-forming composition) preferably do not include impurities such as metal. The content of impurities included in such materials is preferably 1 mass ppm or less, more preferably 10 mass ppb or less, still more preferably 100 mass ppt or less, particularly preferably 10 mass ppt or less, most preferably 1 mass ppt or less. The lower limit is not particularly limited, but is preferably 0 mass ppt or more. Examples of the metallic impurities include Na, K, Ca, Fe, Cu, Mg, Al, Li, Cr, Ni, Sn, Ag, As, Au, Ba, Cd, Co, Pb, Ti, V, W, and Zn.

The process of removing, from various materials, impurities such as metal 1s, for example, filtration using a filter. The details of filtration using a filter is described in Paragraph [0321] in WO2020/004306A.

Examples of the process of reducing the amount of impurities such as metal included in various materials include a process of selecting, as raw materials constituting various materials, raw materials having lower metal content, a process of subjecting raw materials constituting various materials to filtration using a filter, and a process of performing distillation under conditions under which contamination is minimized by, for example, lining the interior of the devices with TEFLON (registered trademark).

Instead of the filtration using a filter, an adsorption material may be used to remove impurities; alternatively, the filtration using a filter may be combined with the use of an adsorption material. Such adsorption materials can be publicly known adsorption materials, and examples include inorganic adsorption materials such as silica gel and zeolite, and organic adsorption materials such as active carbon. In order to reduce the amount of impurities such as metal included in the various materials, ingress of metallic impurities in the production steps needs to be prevented. Whether or not metallic impurities are sufficiently removed from the production apparatuses can be determined by measuring the content of metallic components included in the washing liquid having been used for washing the production apparatuses. The content of metallic components included in the washing liquid having been used is preferably 100 mass ppt (parts per trillion) or less, more preferably 10 mass ppt or less, still more preferably 1 mass ppt or less. The lower limit is not particularly limited, and is preferably 0 mass ppt or more.

To organic treatment liquids such as the rinse liquid, in order to prevent electrostatic buildup and the subsequent electrostatic discharge causing failure of the chemical solution pipe and various parts (such as a filter, an O-ring, and a tube), a conductive compound may be added. The conductive compound is not particularly limited, but may be, for example, methanol. The amount of addition is not particularly limited, but 1s, from the viewpoint of maintaining preferred development performance or rinsing performance, preferably 10 mass % or less, more preferably 5 mass % or less. The lower limit is not particularly limited, but is preferably 0.01 mass % or more.

Examples of the chemical solution pipe include various pipes formed of SUS (stainless steel), or coated with polyethylene, polypropylene, or a fluororesin (such as polytetrafluoroethylene or a perfluoroalkoxy resin) treated so as to be antistatic. Similarly for the filter and the O-ring, polyethylene, polypropylene, or a fluororesin (such as polytetrafluoroethylene or a perfluoroalkoxy resin) treated so as to be antistatic can be used.

### Method for Producing Electronic Device

The present invention also relates to a method for producing an electronic device, the method including the above-described pattern forming method, and an electronic device produced by the production method.

The electronic device according to the present invention may be suitably mounted on electric or electronic devices (such as household appliances, OA (Office Automation), media-related devices, optical devices, and communication devices).

### EXAMPLES

Hereinafter, the present invention will be described further in detail with reference to Examples. In the following Examples, materials, usage amounts, ratios, details of treatment, orders of treatments, and the like can be appropriately changed without departing from the spirit and scope of the present invention. Thus, the scope of the present invention should not be construed as being limited to the following Examples.

### Examples 1A to 1E, Examples 2A to 2B, Examples 3A to 3B, Examples 4 to 6, Examples 7A to 7B, Example 8, Examples 9A to 9C, Examples 10 to 11, Examples 12A to 12B, Examples 13 to 16, Comparative Examples 1A to 1B, and Comparative Examples 2 to 16

Monomers described in Tables 1-1 to 1-5 and solvents described in Tables 1-1 to 1-5 were used in the following manner to synthesize Resins P-1A to P-1E, Resins P-2A to P-2B, Resins P-3A to P-3B, Resins P-4 to P-6, Resins P-7A to P-7B, Resin P-8, Resins P-9A to P-9C, Resins P-10 to P-11, Resins P-12A to P-12B, Resins P-13 to P-16, Resins PC-1A to PC-1B, and Resins PC-2 to PC-16; in the synthesis of each resin, the allowable polymerization concentration was determined.

### Allowable Polymerization Concentration

Monomers were weighed in a molar ratio in Tables 1-1 to 1-5 such that the total mass of the monomers became 50 g; a solvent described in Tables 1-1 to 1-5 was added; stirring for 30 minutes was performed to achieve dissolution; subsequently, the solution was passed through a membrane filter (pore size: 0.5 μm) to prepare a monomer solution.

Note that, for the amount of solvent, a total solvent amount was calculated such that “total mass of monomers” became 40 mass % of “total mass of monomers+total mass of solvents (total solvent amount)”; 20 mass % of the total solvent amount was separately added to a reaction vessel while 80 mass % of the total solvent amount was used for the monomer solution.

In the monomer solution obtained in the above-described manner, an initiator (dimethyl-2,2′-azobis(2-methylpropionate), 10 mol %) was dissolved; this monomer solution was added dropwise, over 4 hours, to the reaction vessel heated at 80° C. and including the solvent in an amount of 20 mass % of the total solvent amount. Subsequently, a reaction was caused for 2 hours at 80° C., and the solution was left to cool to stop the reaction. The obtained reaction solution was measured by ¹³C-NMR (nuclear magnetic resonance), to determine the monomer compositional ratio of the resin.

When the molar ratio of the repeating unit derived from Monomer S in the resin 1s 90% or more with respect to the molar ratio of Monomer S during charging, the polymerization was determined as allowable polymerization. When the polymerization was not determined as allowable polymerization, experiments were performed such that the monomer concentration of the reaction solution was reduced from 40 mass % by 5 mass % decrements and the concentration providing allowable polymerization (allowable polymerization concentration) was calculated.

The evaluation results will be described in Tables 1-1 to 1-5.

TABLE 1-1

| | | Monomer | | Monomer | | | | Solvent | Allowable |
|---|---|---|---|---|---|---|---|---|---|
| | | A-1 | | S | | | | ratio | polymerization |
| | | | Molar | | Molar | Solvent | Solvent | (mass | concentration |
| No. | Resin | Type | ratio | Type | ratio | A | B | ratio) | (mass %) |
| Example 1A | P-1A | A-1 | 95 | S-1 | 5 | SV-4 | SV-1 | 4/1 | >40 |
| Example 1B | P-1B | A-1 | 95 | S-2 | 5 | SV-4 | SV-1 | 4/1 | 35 |
| Example 1C | P-1C | A-1 | 95 | S-3 | 5 | SV-4 | SV-1 | 4/1 | >40 |
| Example 1D | P-1D | A-1 | 95 | S-4 | 5 | SV-4 | SV-1 | 4/1 | >40 |
| Example 1E | P-1E | A-1 | 95 | S-5 | 5 | SV-4 | SV-1 | 4/1 | 30 |
| Comparative | PC-1A | A-1 | 95 | SR-1 | 5 | SV-4 | SV-1 | 4/1 | 20 |
| Example 1A | | | | | | | | | |
| Comparative | PC-1B | A-1 | 95 | SR-2 | 5 | SV-4 | SV-1 | 4/1 | 25 |
| Example 1B | | | | | | | | | |
| Example 2A | P-2A | A-1 | 85 | S-1 | 15 | SV-5 | SV-1 | 4/1 | >40 |
| Example 2B | P-2B | A-1 | 85 | S-2 | 15 | SV-5 | SV-1 | 4/1 | 30 |
| Comparative | PC-2 | A-1 | 85 | SR-1 | 15 | SV-5 | SV-1 | 4/1 | <15 |
| Example 2 | | | | | | | | | |
| Example 3A | P-3A | A-2 | 97 | S-1 | 3 | SV-4 | SV-1 | 3/1 | >40 |
| Example 3B | P-3B | A-2 | 97 | S-2 | 3 | SV-4 | SV-1 | 3/1 | 35 |
| Comparative | PC-3 | A-2 | 97 | SR-1 | 3 | SV-4 | SV-1 | 3/1 | 20 |
| Example 3 | | | | | | | | | |

TABLE 1-2

| | | Monomer | | Monomer | | | | Solvent | Allowable |
|---|---|---|---|---|---|---|---|---|---|
| | | A-1 | | S | | | | ratio | polymerization |
| | | | Molar | | Molar | Solvent | Solvent | (mass | concentration |
| No. | Resin | Type | ratio | Type | ratio | A | B | ratio) | (mass %) |
| Example 4 | P-4 | A-2 | 95 | S-1 | 5 | SV-7 | SV-1 | 3/1 | >40 |
| Comparative | PC-4 | A-2 | 95 | SR-1 | 5 | SV-7 | SV-1 | 3/1 | <15 |
| Example 4 | | | | | | | | | |
| Example 5 | P-5 | A-2 | 95 | S-1 | 5 | SV-4 | — | — | 30 |
| Comparative | PC-5 | A-2 | 95 | SR-1 | 5 | SV-4 | — | — | <15 |
| Example 5 | | | | | | | | | |
| Example 6 | P-6 | A-2 | 95 | S-1 | 5 | SV-8 | SV-1 | 3/1 | 30 |
| Comparative | PC-6 | A-2 | 95 | SR-1 | 5 | SV-8 | SV-1 | 3/1 | <15 |
| Example 6 | | | | | | | | | |
| Example 7A | P-7A | A-3 | 97 | S-1 | 3 | SV-4 | SV-1 | 3/1 | >40 |
| Example 7B | P-7B | A-3 | 97 | S-1 | 3 | SV-4 | SV-1 | 3/1 | 35 |
| Comparative | PC-7 | A-3 | 97 | SR-1 | 3 | SV-4 | SV-1 | 3/1 | 20 |
| Example 7 | | | | | | | | | |

TABLE 1-3

| | | Monomer | | Monomer | | | | Solvent | Allowable |
|---|---|---|---|---|---|---|---|---|---|
| | | A-1 | | S | | | | ratio | polymerization |
| | | | Molar | | Molar | Solvent | Solvent | (mass | concentration |
| No. | Resin | Type | ratio | Type | ratio | A | B | ratio) | (mass %) |
| Example 8 | P-8 | A-3 | 97 | S-1 | 2 | SV-3 | — | — | 30 |
| Comparative | PC-8 | A-3 | 97 | SR-1 | 3 | SV-3 | — | — | <15 |
| Example 8 | | | | | | | | | |
| Example 9A | P-9A | A-4 | 95 | S-1 | 5 | SV-4 | SV-1 | 3/1 | >40 |
| Example 9B | P-9B | A-4 | 95 | S-2 | 5 | SV-4 | SV-1 | 3/1 | 30 |
| Example 9C | P-9C | A-4 | 95 | S-3 | 5 | SV-4 | SV-1 | 3/1 | 35 |
| Comparative | PC-9 | A-4 | 95 | SR-1 | 5 | SV-4 | SV-1 | 3/1 | 20 |
| Example 9 | | | | | | | | | |
| Example 10 | P-10 | A-4 | 95 | S-1 | 5 | SV-6 | SV-1 | 3/1 | 35 |
| Comparative | PC-10 | A-4 | 95 | SR-1 | 5 | SV-6 | SV-1 | 3/1 | <15 |
| Example 10 | | | | | | | | | |
| Example 11 | P-11 | A-5 | 95 | S-1 | 5 | SV-5 | SV-2 | 2/1 | >40 |
| Comparative | PC-11 | A-5 | 95 | SR-1 | 5 | SV-5 | SV-2 | 2/1 | 20 |
| Example 11 | | | | | | | | | |

TABLE 1-4

| | | Monomer | | Monomer | | Monomer | | | | Solvent | Allowable |
|---|---|---|---|---|---|---|---|---|---|---|---|
| | | A-1 | | A-2 | | S | | | | ratio | polymerization |
| | | | Molar | | Molar | | Molar | Solvent | Solvent | (mass | concentration |
| No. | Resin | Type | ratio | Type | ratio | Type | ratio | A | B | ratio) | (mass %) |
| Example 12A | P-12A | A-1 | 60 | A-5 | 35 | S-1 | 5 | SV-4 | SV-1 | 3/1 | >40 |
| Example 12B | P-12B | A-1 | 60 | A-5 | 35 | S-2 | 5 | SV-4 | SV-1 | 3/1 | 30 |
| Comparative | PC-12 | A-1 | 60 | A-5 | 35 | SR-1 | 5 | SV-4 | SV-1 | 3/1 | 20 |
| Example 12 | | | | | | | | | | | |
| Example 13 | P-13 | A-1 | 45 | A-6 | 50 | S-1 | 5 | SV-5 | — | — | 35 |
| Comparative | PC-13 | A-1 | 45 | A-6 | 50 | SR-1 | 5 | SV-5 | — | — | 15 |
| Example 13 | | | | | | | | | | | |
| Example 14 | P-14 | A-1 | 60 | A-2 | 35 | S-1 | 5 | SV-4 | SV-1 | 4/1 | >40 |
| Comparative | PC-14 | A-1 | 60 | A-2 | 35 | SR-1 | 5 | SV-4 | SV-1 | 4/1 | 20 |
| Example 14 | | | | | | | | | | | |

TABLE 1-5

| | | Monomer | | Monomer | | Monomer | | | | Solvent | Allowable |
|---|---|---|---|---|---|---|---|---|---|---|---|
| | | A-1 | | A-2 | | S | | | | ratio | polymerization |
| | | | Molar | | Molar | | Molar | Solvent | Solvent | (mass | concentration |
| No. | Resin | Type | ratio | Type | ratio | Type | ratio | A | B | ratio) | (mass %) |
| Example 15 | P-15 | A-1 | 60 | A-7 | 35 | S-1 | 5 | SV-4 | SV-1 | 4/1 | >40 |
| Comparative | PC-15 | A-1 | 60 | A-7 | 35 | SR-1 | 5 | SV-4 | SV-1 | 4/1 | 20 |
| Example 15 | | | | | | | | | | | |
| Example 16 | P-16 | A-1 | 35 | A-7 | 60 | S-1 | 5 | SV-4 | SV-1 | 4/1 | 35 |
| Comparative | PC-16 | A-1 | 35 | A-7 | 60 | SR-1 | 5 | SV-4 | SV-1 | 4/1 | 15 |
| Example 16 | | | | | | | | | | | |

In Tables 1-1 to 1-5, when “total mass of monomers” became 40 mass % of “total mass of monomers+total mass of solvents (total solvent amount)”, and the polymerization was determined as allowable polymerization, “>40” is described.

By contrast, when “total mass of monomers” was 15 mass % of “total mass of monomers+total mass of solvents (total solvent amount)”, and the polymerization was not determined as allowable polymerization, “<15” is described.

In Tables 1-1 to 1-5, Solvent ratio (mass ratio) refers to a ratio of “Solvent A/Solvent B”.

The following are the structures of Monomers S in Tables 1-1 to 1-5.

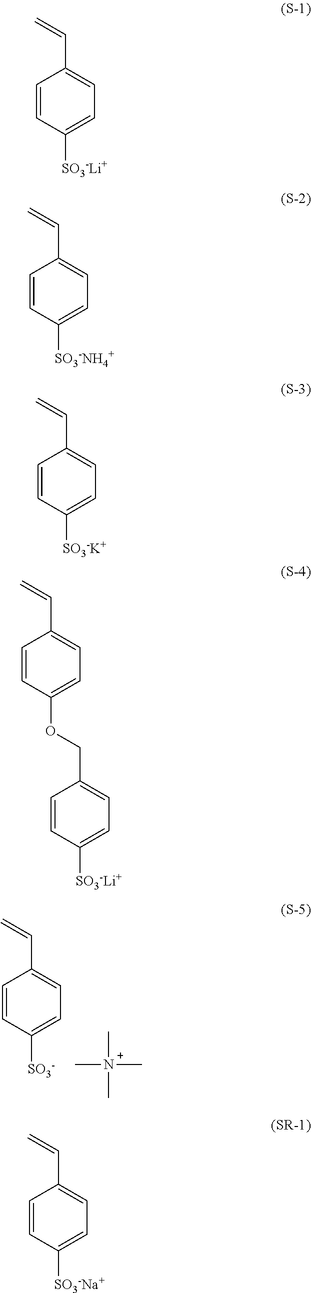

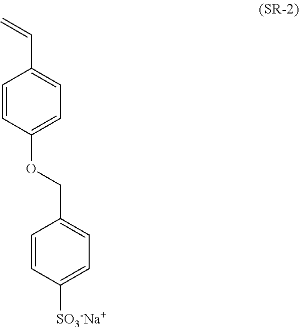

The following are the structures of Monomers A-1 and A-2 in Tables 1-1 to 1-5.

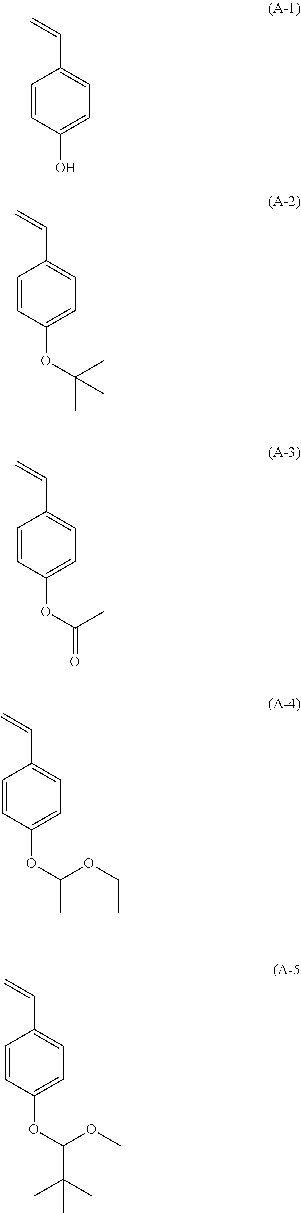

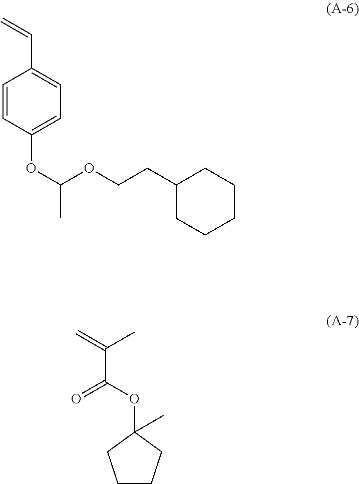 [SMILES: C=Cc1ccc(OC(C)OCCC2CCCCC2)cc1 ; C=C(C)C(=O)OC1(C)CCCC1]

The following are the solvents in Tables 1-1 to 1-5.

SV-1: methanol

SV-2: ethanol

SV-3: 2-propanol

SV-4: 1-methoxy-2-propanol (propylene glycol monomethyl ether)

SV-5: ethyl lactate

SV-6: butyl acetate

SV-7: propylene glycol monomethyl ether acetate

SV-8: 2-pentanone

As is clear from Tables 1-1 to 1-5, Examples 1A to 16 respectively have higher allowable polymerization concentrations than the corresponding Comparative Examples. This inferentially demonstrates, in the monomer solutions, high solubility of Monomers S, so that M⁺ in General formula (P-1) above enables reduction in the amount of solvent used in the polymerization step, which enables reduction in the production costs.

Therefore, it has been demonstrated that, in the copolymerization step, use of the compound represented by General formula (P-1) enables easy production of the resin.

### Examples A-1 to A-3 (Synthesis of Resins PP-1 to PP-3, and PI-1)

Resins PP-1 to PP-3 and PI-1 were synthesized in the following manner.

For obtained Resins PP-1 to PP-3 and PI-1, the compositional ratio of repeating units (mol % ratio; sequentially from the left), the weight-average molecular weight (Mw), and the dispersity (Mw/Mn) will be described.

Note that, for Resins PP-1 to PP-3 and PI-1, the weight-average molecular weight (Mw) and the dispersity (Mw/Mn) were measured by GPC (solvent: dimethylformamide (DMF)). For the resins, the compositional ratio (mol % ratio) was measured by ¹³C-NMR (nuclear magnetic resonance).

### Example A-1 (Synthesis of Resin PP-1)

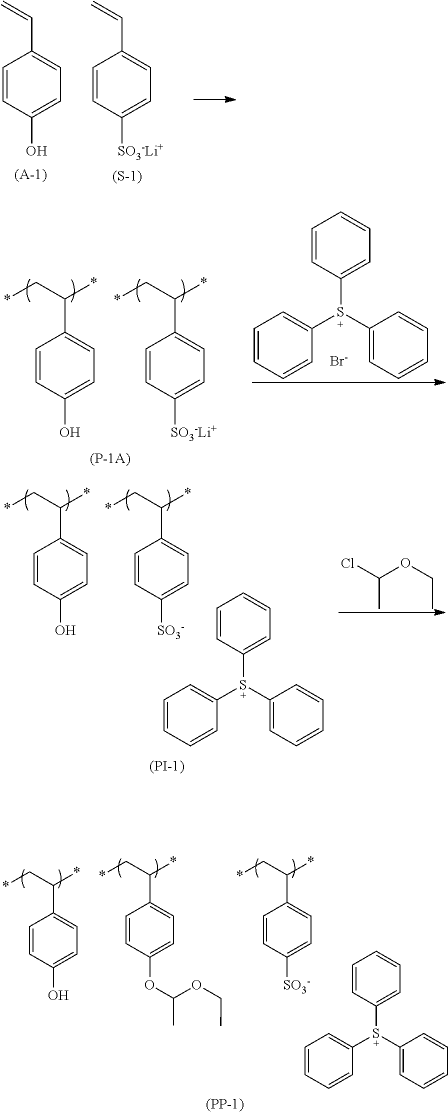

The reaction solution obtained in Example 1A (Resin P-1A) described in Table 1-1 was used to perform the following synthesis. To the obtained reaction solution, ethyl acetate (1000 mL), water (500 mL), and triphenylsulfonium bromide (6.94 g, 20.2 mmol) were added and stirred for 30 minutes at room temperature (23° C.). After the aqueous layer was removed, procedures of adding water (500 mL) to form separated layers and removing the aqueous layer were repeated three times to wash the organic layer. The obtained organic layer was concentrated, subsequently diluted by adding 200 g of ethyl acetate, subsequently added dropwise in 2000 g of hexane/ethyl acetate=8/2 (mass ratio) to precipitate a polymer, and filtered. The solid obtained by filtration was washed by pouring 100 g of hexane/ethyl acetate=8/2 (mass ratio). Subsequently, the washed solid was subjected to drying under a reduced pressure, to obtain 48.5 g of Resin (PI-1).

The obtained Resin (PI-1) (48.5 g) was dissolved in acetonitrile (450 mL), and triethylamine (15.1 g, 149 mmol) was added. To this, 1-chloro-1-ethoxyethane (14.1 g, 130 mmol) synthesized by standard procedures was added and caused to react at room temperature for 3 hours. To the obtained reaction solution, water (500 mL) and ethyl acetate (1000 mL) were added to form separated layers, and the aqueous layer was removed. The resultant organic layer was concentrated, subsequently diluted by adding 200 g of ethyl acetate, subsequently added dropwise in 2000 g of hexane/ethyl acetate=9/1 (mass ratio) to precipitate a polymer, and filtered. The solid obtained by filtration was washed by pouring 100 g of hexane/ethyl acetate=8/2 (mass ratio). Subsequently, the washed solid was subjected to drying under a reduced pressure, to obtain 47.0 g of Resin (PP-1). The obtained Resin (PP-1) was found to have a Mw of 8500, a dispersity of 1.80, and a compositional ratio (molar ratio) of the repeating units of (sequentially from the left) 60/35/5.

### Example A-2 (Synthesis of Resin PI-1)

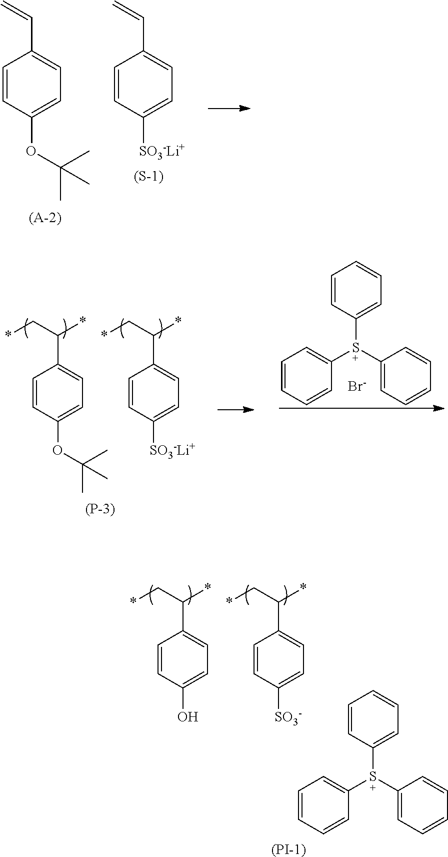

Compound (A-2) (47.3 g, 268 mmol) and Compound (S-1) (2.69 g, 14.1 mmol) were weighed; Solvent SV-4 (40.5 g) and Solvent SV-1 (13.5 g) were added and stirring was performed for 30 minutes to achieve dissolution; subsequently, the solution was passed through a membrane filter (pore size: 0.5 μm) to prepare a monomer solution. In the obtained monomer solution, dimethyl-2,2′-azobis(2-methylpropionate) (6.50 g, 28.3 mmol) was dissolved to prepare a dropwise-addition monomer solution. To a reaction vessel, Solvent SV-4 (15.8 g) and Solvent SV-1 (5.25 g) were added and heated to 80° C.; to this, the dropwise-addition monomer solution was added dropwise over 4 hours. Subsequently, a reaction was caused for 2 hours at 80° C., and the solution was left to cool to stop the reaction. To the obtained reaction solution, 5 N hydrochloric acid (11.3 mL, 56.5 mmol) was added, heated to 90° C. to cause a reaction for 3 hours, and subsequently left to cool to stop the reaction. To the obtained reaction solution, ethyl acetate (1000 mL), water (500 mL), sodium hydrogencarbonate (7.12 g, 84.8 mmol) and triphenylsulfonium bromide (4.84 g, 14.1 mmol) were added and stirred for 30 minutes at room temperature. After the aqueous layer was removed, procedures of adding water (500 mL) to form separated layers and removing the aqueous layer were repeated three times to wash the organic layer. The obtained organic layer was concentrated, subsequently diluted by adding 150 g of ethyl acetate, subsequently added dropwise into 1500 g of hexane/ethyl acetate=8/2 (mass ratio) to precipitate a polymer, and filtered. The solid obtained by filtration was washed by pouring 100 g of hexane/ethyl acetate=8/2 (mass ratio). Subsequently, the washed solid was subjected to drying under a reduced pressure, to obtain 32.1 g of Resin (PI-1). The obtained Resin (PI-1) was found to have a Mw of 8000, a dispersity of 1.80, and a compositional ratio (molar ratio) of the repeating units of (sequentially from the left) 95/5.

### Example A-3 (Synthesis of Resin PP-2)

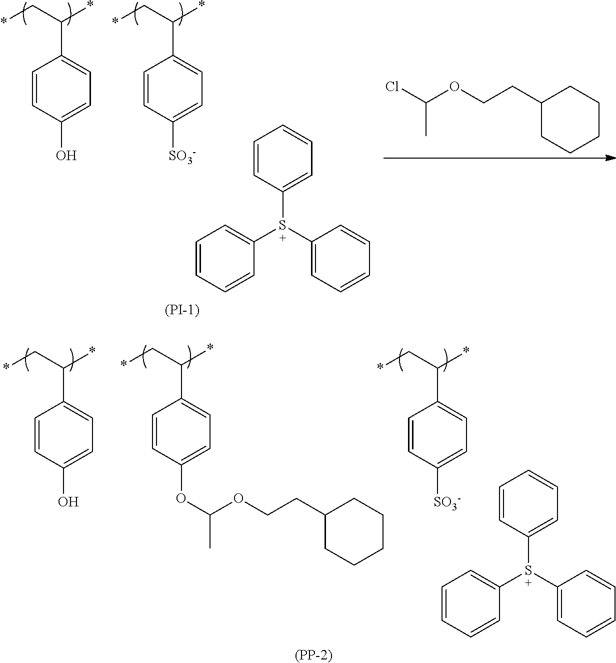

Resin (PP-2) was synthesized by the same synthesis method as Resin PP-1 except that Resin PI-1 synthesized by the same method as in the synthesis of Resin PP-1 was used, and 1-chloro-1-ethoxyethane in the synthesis of Resin PP-1 was changed to (2-(1-chloroethoxy)ethyl)cyclohexane. The obtained Resin (PP-2) was found to have a Mw of 8200, a dispersity of 1.82, and a compositional ratio (molar ratio) of the repeating units of (sequentially from the left) 60/35/5.

### Example A-4 (Synthesis of Resin PP-3)

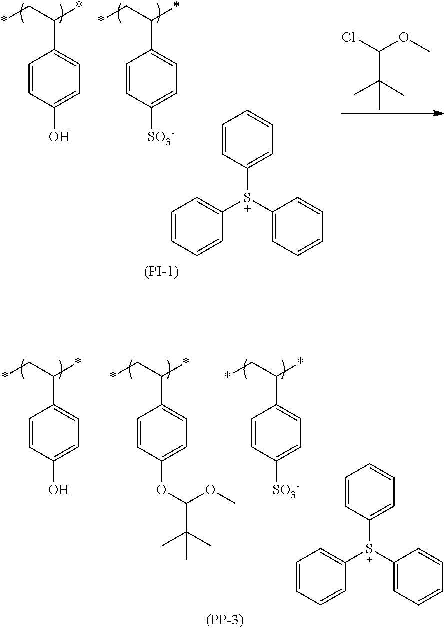

Resin (PP-3) was synthesized by the same synthesis method as Resin PP-1 except that Resin PI-1 synthesized by the same method as in the synthesis of Resin PP-1 was used, and 1-chloro-1-ethoxyethane in the synthesis of Resin PP-1 was changed to 1-chloro-1-methoxy-2,2-dimethylpropane. The obtained Resin (PP-3) was found to have a Mw of 7900, a dispersity of 1.79, and a compositional ratio (molar ratio) of the repeating units of (sequentially from the left) 61/34/5.

### Example 2-1 to Example 2-3 and Comparative Example 2C-1 to Comparative Example 2C-3 Variations in Reproduction

Resins (PP-1 to PP-3) and Resins (PP-1C to PP-3C) below were each repeatedly synthesized and evaluated in terms of variations in compositional-ratio reproduction ([variations in reproduction] in the following manner.

Each of the resins was synthesized five times in total by the above-described synthesis method; in each of the times, the content (mol %) of the repeating unit having an acid decomposable group with respect to all the repeating units of the resin was determined; and the average value of the contents of the five times was calculated. Cases where, in each of the times, the content (mol %) of the repeating unit having an acid decomposable group was within the average value ±2 mol % were evaluated as A, while cases where the content was not within ±2 mol % were evaluated as B. Note that A is practically preferred.

The evaluation results will be described in Table 2.

As Comparative resins (PP-1C to PP-3C), resins synthesized by the following method and respectively having the same compositions as Resins (PP-1 to PP-3) above were used.

### Synthesis of Resin PP-1C

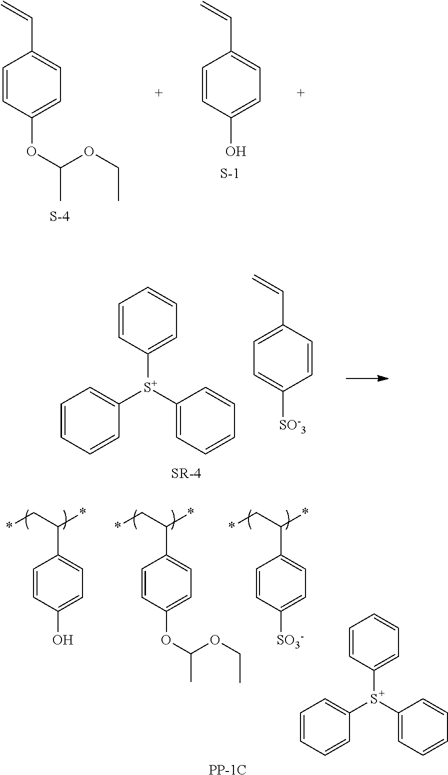

Compound (S-4)(20.2 g, 105 mmol), Compound (S-1)(21.6 g, 180 mmol), Compound (SR-4) (6.70 g, 15 mmol), a polymerization initiator, and dimethyl-2,2′-azobis(2-methylpropionate) (6.91 g, 30 mmol) were dissolved in a solvent (155 g) provided by mixing propylene glycol monomethyl ether and methanol in a mass ratio (3/1). Into a reaction vessel, the mixed solvent (38.8 g) was placed, and dropwise addition in a nitrogen gas atmosphere in the system at 80° C. was performed over 4 hours. The reaction solution was heated under stirring for 2 hours, and subsequently left to cool to room temperature.

The reaction solution was diluted by adding 250 g of ethyl acetate. The diluted solution was added dropwise to 4000 g of hexane/ethyl acetate=8/2 (mass ratio) to precipitate a polymer, and filtered. The solid obtained by filtration was washed by pouring 200 g of hexane/ethyl acetate=8/2 (mass ratio). Subsequently, the washed solid was subjected to drying under a reduced pressure, to obtain 35.5 g of Resin (PP-1C). The obtained Resin (PP-1C) was found to have a Mw of 8000, a dispersity of 1.75, and a compositional ratio (molar ratio) of the repeating units of (sequentially from the left) 60/35/5.

Resins PP-2C to PP-3C were individually synthesized as in Resin PP-1C. Note that, as described above, the compositional ratios of the repeating units of Resins PP-2C and PP-3C are respectively the same as the compositional ratios of the repeating units of Resins PP-2 and PP-3.

TABLE 2

| | | Variations in |
|---|---|---|
| | Resin | reproduction |
| Example 2-1 | PP-1 | A |
| Example 2-2 | PP-2 | A |
| Example 2-3 | PP-3 | A |
| Comparative | PP-1C | B |
| Example 2C-1 | | |
| Comparative | PP-2C | B |
| Example 2C-2 | | |
| Comparative | PP-3C | B |
| Example 2C-3 | | |

As is clear from Table 2, it has been demonstrated that Examples 2-1 to 2-3 enable more precise production of resins in Examples than their corresponding Comparative Examples.

### Examples 3-1 to 3-3 and Comparative Examples 3C-1 to 3C-2

### Preparation of Resist Compositions

Components described in Table 2 were dissolved in a solvent described in Table 3, and this was filtered through a polyethylene filter having a pore size of 0.02 μm; in this way, resist compositions were prepared.

In the table, values in parentheses are contents (parts by mass), and the abbreviations refer to the following.

D-1: tri-n-octylamine

E-1: salicylic acid

SA-1: γ-butyrolactone

SA-2: cyclohexanone

SA-3: propylene glycol monomethyl ether acetate

SA-4: propylene glycol monomethyl ether

For Resins PR-1 to PR-2, the compositional ratio of repeating units (mol % ratio; sequentially from the left), weight-average molecular weight (Mw), and dispersity (Mw/Mn) will also be described.

Note that, for Resins PR-1 to PR-2, the weight-average molecular weight (Mw) and the dispersity (Mw/Mn) were measured by GPC (solvent: dimethylformamide (DMF)). The resin compositional ratio (mol % ratio) was measured by ¹³C-NMR (nuclear magnetic resonance).

Resin PR-1 is a polymer compound illustrated below. PR-1 was produced in accordance with Example 1 in JP2013-1715A. PR-1 was found to have a Mw of 13400 and a dispersity of 1.57.

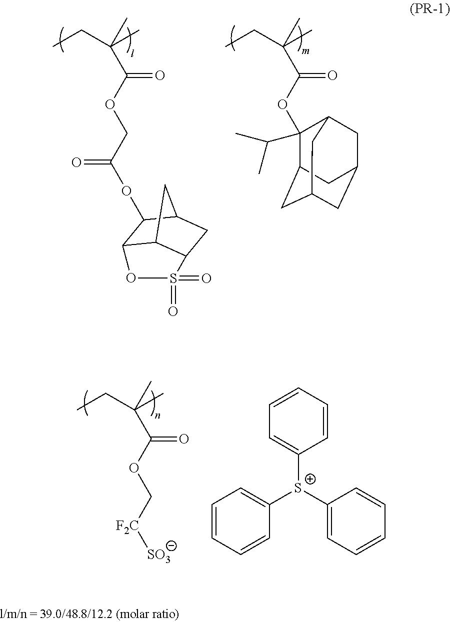

Resin PR-2 is a resin illustrated below. Resin PR-2 was produced in accordance with Example A-1. PR-2 was found to have a Mw of 8200 and a dispersity of 1.80.

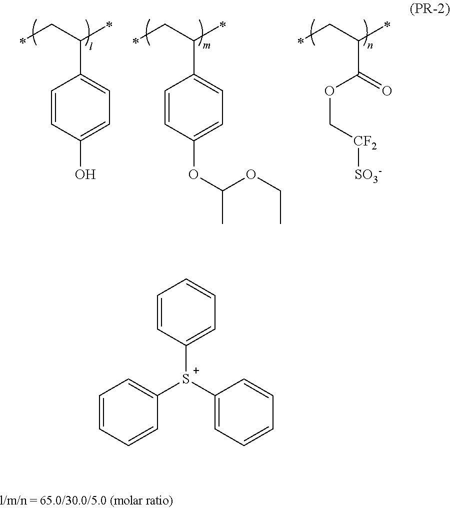

TABLE 3

| | | Acid | | | | | | | |
|---|---|---|---|---|---|---|---|---|---|
| | | diffusion | | | | | | Roughness | Etching |
| | | control | | | | | | performance | resistance |
| | Resin | agent | Additive | Solvent | | | | (nm) | performance |
| Example 3-1 | PP-1 | D-1 | E-1 | SA-1 | SA-2 | SA-3 | SA-4 | 6.8 | A |
| | (100) | (1.60) | (0.64) | (200) | (2080) | (1250) | (830) | | |
| Example 3-2 | PP-2 | D-1 | E-1 | SA-1 | SA-2 | SA-3 | SA-4 | 6.2 | A |
| | (100) | (1.60) | (0.64) | (200) | (2080) | (1250) | (830) | | |
| Example 3-3 | PP-3 | D-1 | E-1 | SA-1 | SA-2 | SA-3 | SA-4 | 5.8 | A |
| | (100) | (1.60) | (0.64) | (200) | (2080) | (1250) | (830) | | |
| Comparative | PR-1 | D-1 | E-1 | SA-1 | SA-2 | SA-3 | SA-4 | 8.9 | B |
| Example 3C-1 | (100) | (1.60) | (0.64) | (200) | (2080) | (1250) | (830) | | |
| Comparative | PR-2 | D-1 | E-1 | SA-1 | SA-2 | SA-3 | SA-4 | 9.6 | B |
| Example 3C-2 | (100) | (1.60) | (0.64) | (200) | (2080) | (1250) | (830) | | |

### Pattern Forming Method: EB Exposure, Alkali Development (Positive)

The resist composition was uniformly applied, using a spin coater, onto a silicon substrate subjected to hexamethyldisilazane treatment, and heat-dried at 120° C. for 90 seconds on a hot plate, to form a resist film having a film thickness of 100 nm.

The resist film was subjected to pattern exposure using an electron beam lithography apparatus (manufactured by Hitachi, Ltd., HL750, acceleration voltage: 50 keV). At this time, patterning was performed so as to form a 1:1 line and space pattern. Immediately after the electron beam patterning, the film was heated at 110° C. for 90 seconds on a hot plate, developed with a 2.38 mass % aqueous solution of tetramethylammonium hydroxide at 23° C. for 60 seconds, rinsed for 30 seconds with pure water, and subsequently dried to form a 1:1 line and space pattern having a line width of 50 nm; the obtained pattern was evaluated in the following manner.

### Evaluation of Performances

### Roughness Performance

For the obtained pattern, its profile was observed using a scanning electron microscope (manufactured by Hitachi, Ltd., S-9220). The exposure dose (electron beam irradiation dose) at which the 1:1 line and space resist pattern having a line width of 50 nm was resolved was defined as sensitivity (Eop).

For a 100 nm line pattern (1:1 line and space pattern having a line width of 50 nm) formed at the irradiation dose corresponding to the sensitivity, at randomly selected 30 points over a distance of 10 μm in the longitudinal direction, a scanning electron microscope (manufactured by Hitachi, Ltd., S-9220) was used to measure a distance of such a point from a reference line at which the edge should reside; the standard deviation was determined and 3a (nm) was calculated.

### Etching Resistance Performance

The resist composition was used to form, on a silicon wafer, a resist film having a film thickness of 200 nm; subsequently, a dry etching apparatus (manufactured by Hitachi, Ltd., HITACHI U-621) using an Ar/C₄F₆/O₂ gas (mixed gas having a volume ratio of 100/4/2) was used to subject the silicon wafer to dry etching treatment at a temperature condition of 23° C. for 60 seconds. A scanning electron microscope (manufactured by Hitachi, Ltd., S-4800) was used to observe the profile of each pattern, the residual amount of the film was determined, and the etching rate was calculated.

### Determination Criteria

A: in the case of an etching rate of less than 15 Å/sec

B: in the case of an etching rate of 15 Å/sec or more

Note that A is practically preferred.

The obtained evaluation results are described in Table 3.

As described in Table 3 above, it has been demonstrated that a resist composition including a resin obtained by the production method according to the present invention enables formation of a pattern having high roughness performance and high etching resistance performance.

By contrast, Comparative Examples were insufficient in terms of these performances.

What is claimed is:

1. A method for producing a resin having a repeating unit that is decomposed by irradiation with an actinic ray or a radiation to generate acid, the method comprising:
polymerizing a compound represented by the following General formula (P-1) and a copolymerizable monomer compound, 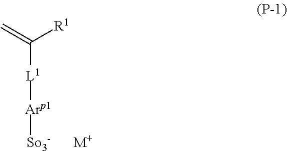
wherein, in the General formula (P-1),
R¹ represents a hydrogen atom, an alkyl group, an aryl group, or a halogen atom,
L¹ represents a single bond or a divalent linking group,
Ar^{p1} represents an aromatic ring group or an aromatic heterocyclic group, and
M⁺ represents a lithium cation, a potassium cation, or an ammonium cation.

2. The method for producing the resin according to claim 1, wherein
at least one of the copolymerizable monomer compound is a compound represented by the following General formula (A-1), 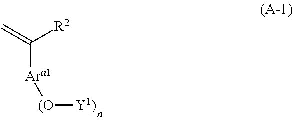
in the General formula (A-1),
R² represents a hydrogen atom, an alkyl group, an aryl group, or a halogen atom,
Ar^{a1} represents an (n+1) valent aromatic ring group or an (n+1) valent aromatic heterocyclic group,
n represents an integer of 1 to 4,
Y¹ represents a hydrogen atom or a substituent, and
a plurality of Y¹'s may be the same or different when n represents an integer of 2 to 4.

3. The method for producing the resin according to claim 1, wherein the compound represented by the General formula (P-1) is a compound represented by the following General formula (P-2), 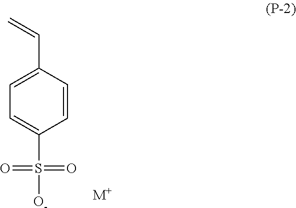
in the General formula (P-2),
M⁺ has the same definition as M⁺ in the General formula (P-1).

4. The method for producing the resin according to claim 1, wherein
a solvent is used in the polymerization, and
a content of an alcohol-based solvent is 20 mass % or more with respect to a total amount of the solvent.

5. The method for producing the resin according to claim 4, wherein
the content of the alcohol-based solvent is 50 mass % or more with respect to the total amount of the solvent.

6. The method for producing the resin according to claim 4, wherein
the alcohol-based solvent is at least one selected from the group consisting of methanol, ethanol, 1-propanol, 2-propanol, ethylene glycol, propylene glycol, 2-methoxyethanol, 1-methoxy-2-propanol, methyl lactate, ethyl lactate, and diacetone alcohol.

7. The method for producing the resin according to claim 1, wherein,
a solution containing the compound represented by the General formula (P-1 is passed through a filter having a pore size of 0.05 to 5 μm before the polymerization.

8. The method for producing the resin according to claim 1, the method comprising
after the polymerization, exchanging the cation M⁺ in a repeating unit derived from the compound represented by the General formula (P-1) for an organic cation.

9. The method for producing the resin according to claim 1, wherein
the resin further has a repeating unit having an acid decomposable group.

10. The method for producing the resin according to claim 2, wherein
Y¹ in the General formula (A-1) is a hydrogen atom or a group represented by any one of the following Formulas (AY-1) to (AY-3), 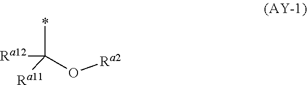
in the Formula (AY-1),
R^{a11} and R^{a12} each independently represent a hydrogen atom, an alkyl group, an aryl group, or a heteroaryl group,
R^{a2} represents an alkyl group, an aryl group, or a heteroaryl group, and
represents a bonding site, 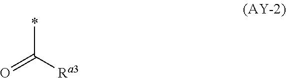
in the Formula (AY-2),
R^{a3} represents an alkyl group, an alkoxy group, an aryl group, an aryloxy group, or a heteroaryl group, and
* represents a bonding site, 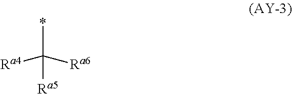
in the Formula (AY-3),
R^{a′}to R^{a6} each independently represent an alkyl group, an aryl group, or a heteroaryl group, and
* represents a bonding site.

11. The method for producing the resin according to claim 2, wherein
the compound represented by the General formula (A-1) is a compound represented by any one of the following Formulas (A-2) to (A-5), 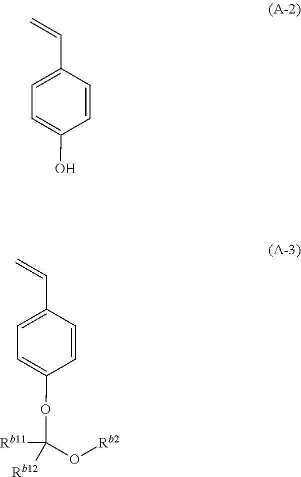
in the Formula (A-3),
R^{b11} and R^{b12} each independently represent a hydrogen atom, an alkyl group, an aryl group, or a heteroaryl group, and
R^{b2} represents an alkyl group, an aryl group, or a heteroaryl group, 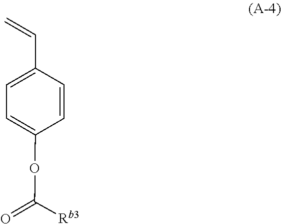
in the Formula (A-4),
R^{b3} represents an alkyl group, an alkoxy group, an aryl group, an aryloxy group, or a heteroaryl group, and 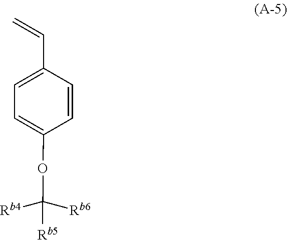
in the Formula (A-5),
R^{b4} to R^{b6} each independently represent an alkyl group, an aryl group, or a heteroaryl group.

12. The method for producing the resin according to claim 11, wherein
the compound represented by the General formula (A-1) is a compound represented by any one of the Formulas (A-3) to (A-5), and
the method comprises, after the polymerization, converting a repeating unit derived from the compound represented by the General formula (A-1) to a repeating unit represented by the following Formula (AP-1).

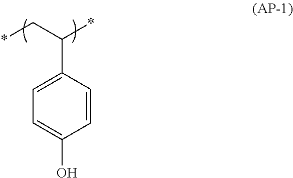

13. The method for producing the resin according to claim 12, the method comprising
converting at least partially the repeating unit represented by the Formula (AP-1) to a repeating unit represented by the following Formula (AP-2), 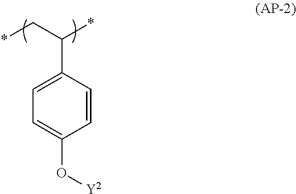
wherein, in the Formula (AP-2),
Y² represents a group that leaves due to an action of acid.

14. The method for producing the resin according to claim 11, wherein
the compound represented by the General formula (A-1) is the compound represented by the Formula (A-2), and
the method comprises, after the polymerization, converting at least partially a repeating unit derived from the compound represented by the formula (A-2) to a repeating unit represented by the following Formula (AP-2), 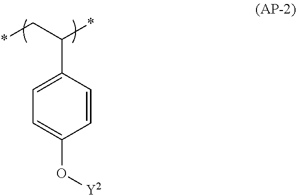
in the Formula (AP-2),
Y² represents a group that leaves due to an action of acid.

15. The method for producing the resin according to claim 13, wherein
in the Formula (AP-2), Y² is a group represented by the following Formula (AY-4), and 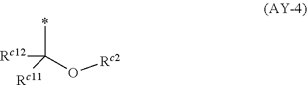
in the Formula (AY-4),
R^{c11} and R^{c12} each independently represent a hydrogen atom, an alkyl group, an aryl group, or a heteroaryl group,
R^{c2} represents an alkyl group, an aryl group, or a heteroaryl group, and
* represents a bonding site.

16. A method for producing an actinic ray-sensitive or radiation-sensitive resin composition,
the method comprising the method for producing the resin according to claim 1, and
the composition containing the resin.

17. A pattern forming method comprising:
producing a resin by the method for producing the resin according to claim 1;
forming an actinic ray-sensitive or radiation-sensitive film on a substrate by an actinic ray-sensitive or radiation-sensitive resin composition containing the resin;
exposing the actinic ray-sensitive or radiation-sensitive film; and
developing the exposed actinic ray-sensitive or radiation-sensitive film to form a pattern by a developer.

18. A resin comprising
a repeating unit derived from a compound represented by the following General formula (P-1), and
a repeating unit derived from a compound represented by any one of the following Formulas (A-2) to (A-5), 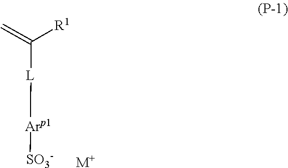
wherein, in the General formula (P-1),
R¹ represents a hydrogen atom, an alkyl group, an aryl group, or a halogen atom,
L¹ represents a single bond or a divalent linking group,
Ar^{p1} represents an aromatic ring group or an aromatic heterocyclic group, and
M⁺ represents a lithium cation, a potassium cation, or an ammonium cation, 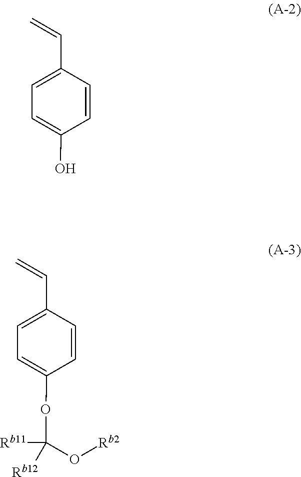
in the Formula (A-3),
R^{b11} and R^{b12} each independently represent a hydrogen atom, an alkyl group, an aryl group, or a heteroaryl group, and
R^{b2} represents an alkyl group, an aryl group, or a heteroaryl group, 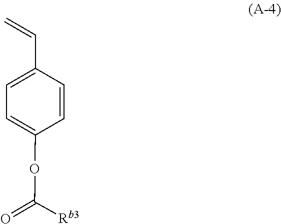
in the Formula (A-4),
R^{b3} represents an alkyl group, an alkoxy group, an aryl group, an aryloxy group, or a heteroaryl group, and 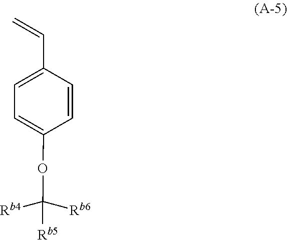
in the Formula (A-5),
R^{b4} to R^{b6} each independently represent an alkyl group, an aryl group, or a heteroaryl group.
